(19) United States
(12) Patent Application Publication
(10) Pub. No.: US 2026/0001189 A1
(43) Pub. Date: Jan. 1, 2026

(54) SUBSTRATE POLISHING APPARATUS, SUBSTRATE POLISHING METHOD, POLISHING APPARATUS, AND POLISHING METHOD

(71) Applicant: EBARA CORPORATION, Tokyo (JP)

(72) Inventors: Atsushi YOSHIDA, Tokyo (JP); Yu ISHII, Tokyo (JP); Masayuki NAKANISHI, Tokyo (JP)

(21) Appl. No.: 18/846,194

(22) PCT Filed: Mar. 8, 2023
(86) PCT No.: PCT/JP2023/008724

§ 371 Date: May 1, 2025

(30) Foreign Application Priority Data
Mar. 14, 2022 (JP) 2022-039240
Mar. 28, 2022 (JP) 2022-052168

(51) Int. Cl. B24B 37/04; B24B 7/22; H01L 21/306

(52) U.S. Cl. CPC B24B 37/04; B24B 7/228; H01L 21/30625

(57) ABSTRACT

A substrate polishing apparatus is a substrate polishing apparatus configured to perform polishing processing on a processing surface of a substrate and includes: a grinding module in which a first grinding member and a second grinding member with a maximum diameter larger than a maximum diameter of the first grinding member are disposed; a polishing module including a polishing member; and a control device configured to control the grinding module and the polishing module, and the control device controls the grinding module to perform first grinding on part of the processing surface by the first grinding member and second grinding on the processing surface by the second grinding member and controls the polishing module to perform polishing on the processing surface on which the first grinding and the second grinding have been performed.

### TECHNICAL FIELD

The present invention relates to a substrate polishing apparatus, a substrate polishing method, a polishing apparatus, and a polishing method.

### BACKGROUND ART

A substrate polishing apparatus that polishes a substrate such as a wafer has been known. In such a substrate polishing apparatus, a plurality of processes including polishing such as chemical mechanical polishing (CMP) are performed to improve accuracy. A CMP apparatus is one of apparatuses for manufacturing semiconductor devices. A typical CMP apparatus includes a polishing table to which a polishing pad is attached, and a polishing head to which a polishing target substrate is attached. In such a typical CMP apparatus, the substrate is polished by supplying polishing liquid to the polishing pad and rotating at least one of the polishing table and the polishing head in a state in which the polishing pad and the substrate are in contact.

In a substrate polishing method of PTL 1, a polishing pad having dimensions smaller than those of a processing target object is relatively moved in contact with the processing target object to perform polishing processing, and then a polishing pad having dimensions larger than those of the processing target object is relatively moved in contact with the processing target object to perform polishing processing. In a substrate processing apparatus of PTL 2, the same substrate is polished in two stages by using two polishers.

The polishing table is provided with a sensor for detecting the polishing state of a substrate. Polishing is controlled by using the measurement value of the sensor. PTL 3 discloses an exemplary method of specifying the measurement positions of a sensor.

### CITATION LIST

### Patent Literature

PTL 1: Japanese Patent Laid-Open No. 2017-163047

PTL 2: Japanese Patent Laid-Open No. 2020-19115

PTL 3: Japanese Patent No. 5340795

### SUMMARY OF INVENTION

### Technical Problem

In the substrate polishing method and the substrate processing apparatus described above, sufficient polishing conditions cannot be established before polishing processing, or processing over a long period may be necessary for establishing sufficient polishing conditions. It is desirable to accurately specify the measurement positions of a sensor provided at the polishing table.

The present invention has been made in view of the above-described circumstances and has been made to solve or reduce at least part of the above-described problem by, for example, providing a substrate with high precision through efficient processing.

### Solution to Problem

According to an embodiment of the present invention, a substrate polishing apparatus is a substrate polishing apparatus configured to perform polishing processing on a processing surface of a substrate and includes: a grinding module in which a first grinding member and a second grinding member with a maximum diameter larger than a maximum diameter of the first grinding member are disposed; a polishing module including a polishing member; and a control device configured to control the grinding module and the polishing module, and the control device controls the grinding module to perform first grinding on part of the processing surface by the first grinding member and second grinding on the processing surface by the second grinding member, and controls the polishing module to perform polishing on the processing surface on which the first grinding and the second grinding have been performed.

According to another embodiment of the present invention, a substrate polishing method is a substrate polishing method of performing polishing processing on a processing surface of a substrate and includes: performing first grinding on part of the processing surface by a first grinding member; performing second grinding on the processing surface by a second grinding member with a maximum diameter larger than a maximum diameter of the first grinding member; and performing polishing by a polishing member on the processing surface on which the first grinding and the second grinding have been performed.

According to another embodiment of the present invention, a polishing apparatus includes: a polishing table having a polishing surface; a polishing head for holding a polishing target object such that the polishing target object faces the polishing surface; a table rotation motor for rotating the polishing table; a head rotation motor for rotating the polishing head; a table angle sensor configured to sense a rotation angle of the polishing table; a head angle sensor configured to sense a rotation angle of the polishing head; a sensor provided on the polishing table and configured to measure a state of the polishing target object when the sensor passes by the polishing target object due to rotation of the polishing table and the polishing head; and a measurement position specifier configured to specify a measurement position of the sensor on the polishing target object based on the rotation angle of the polishing table and the rotation angle of the polishing head.

According to another embodiment of the present invention, a polishing method includes: a step of rotating a polishing table with a polishing surface; a step of rotating a polishing head for holding a polishing target object such that the polishing target object faces the polishing surface; a step of sensing a rotation angle of the polishing table; a step of sensing a rotation angle of the polishing head; a step of measuring, by using a sensor provided on the polishing table, a state of the polishing target object when the sensor passes by the polishing target object due to rotation of the polishing table and the polishing head; and a step of specifying a measurement position of the sensor on the polishing target object based on the rotation angle of the polishing table and the rotation angle of the polishing head.

### BRIEF DESCRIPTION OF DRAWINGS

FIG. 1 is a conceptual diagram illustrating a substrate polishing apparatus of a first embodiment.

FIG. 2 is a cross-sectional view schematically illustrating a loader according to the first embodiment.

FIG. 3 is a conceptual diagram illustrating a grinding module according to the first embodiment

FIG. 4A is a conceptual diagram illustrating a first grinding member according to the first embodiment.

FIG. 4B is a conceptual diagram illustrating the first grinding member according to the first embodiment.

FIG. 5A is a conceptual diagram illustrating a second grinding member according to the first embodiment.

FIG. 5B is a conceptual diagram illustrating the second grinding member according to the first embodiment.

FIG. 6 is a conceptual diagram for description of first grinding, second grinding, and the maximum diameter of a substrate.

FIG. 7 is a conceptual diagram illustrating a detector according to the first embodiment.

FIG. 8 is a conceptual diagram for description of setting of the range of the first grinding.

FIG. 9 is a conceptual diagram illustrating a second conveyer.

FIG. 10 is a perspective view schematically illustrating a polishing module.

FIG. 11 is a conceptual diagram illustrating a top ring.

FIG. 12 is a conceptual diagram illustrating the configuration of a control device.

FIG. 13 is a flowchart illustrating the process of a substrate polishing method according to the first embodiment.

FIG. 14 is a flowchart illustrating the process of a substrate polishing method according to Modification 1-1.

FIG. 15 is a flowchart illustrating the process of a substrate polishing method according to Modification 1-2.

FIG. 16 is a conceptual diagram illustrating a detector according to Modification 1-3.

FIG. 17A is a conceptual diagram illustrating a first grinding member according to Modification 1-4.

FIG. 17B is a conceptual diagram illustrating the first grinding member according to Modification 1-4.

FIG. 18 is a conceptual diagram for description of a substrate polishing apparatus of a second embodiment.

FIG. 19 is a conceptual diagram for description of a grinding module according to the second embodiment.

FIG. 20 is a flowchart illustrating the process of a substrate polishing method according to the second embodiment.

FIG. 21A is a conceptual diagram illustrating a top ring according to Modification 2-1 at grinding.

FIG. 21B is a conceptual diagram illustrating the top ring according to Modification 2-1 at polishing.

FIG. 22 is a conceptual diagram for description of a substrate polishing method according to Modification 2-2.

FIG. 23 is a conceptual diagram for description of the substrate polishing method according to Modification 2-2.

FIG. 24A is a conceptual diagram for description of grinding on a fixed abrasive lapping plate in the substrate polishing method according to Modification 2-2.

FIG. 24B is a conceptual diagram for description of the substrate polishing method according to Modification 2-2.

FIG. 25 is a perspective view schematically illustrating the configuration of a polishing apparatus according to an embodiment.

FIG. 26 is a schematic cross-sectional view of a top ring according to an embodiment that holds a substrate as a polishing target object and presses the substrate against a polishing surface on a polishing pad.

FIG. 27 is a diagram of the top ring according to an embodiment when viewed from a polishing table side.

FIG. 28A is a top view illustrating the structure of an elastic film (membrane) according to an embodiment.

FIG. 28B is a cross-sectional view taken along arrow B-B illustrated in FIG. 28A.

FIG. 28C is a cross-sectional view taken along arrow C-C illustrated in FIG. 28A.

FIG. 29 is a cross-sectional view schematically illustrating the internal structure of the polishing table.

FIG. 30 is a schematic diagram illustrating a detailed configuration of an optical sensor according to an embodiment.

FIG. 31 illustrates an example of the trajectory of a sensor that passes over the substrate held by the top ring.

FIG. 32 is a schematic configuration diagram of the polishing apparatus according to an embodiment that can specify measurement positions of each sensor.

FIG. 33 is a schematic configuration diagram of the polishing apparatus according to an embodiment that can specify measurement positions of each sensor.

FIG. 34 is a schematic configuration diagram of the polishing apparatus according to an embodiment that can specify measurement positions of each sensor.

FIG. 35 is a schematic diagram of a top ring including metal frames.

FIG. 36A is a conceptual diagram for description of a method of calculating the rotation angle of the top ring based on the timing of edge detection.

FIG. 36B is a conceptual diagram for description of the method of calculating the rotation angle of the top ring based on the timing of edge detection.

FIG. 36C is a conceptual diagram for description of the method of calculating the rotation angle of the top ring based on the timing of edge detection.

FIG. 37 is a diagram illustrating another embodiment of the top ring including a metal frame.

FIG. 38 illustrates an exemplary process of control of the polishing apparatus by the control device.

FIG. 39 is a diagram of the top ring according to an embodiment when viewed from the polishing table side.

FIG. 40 is a diagram of the top ring according to an embodiment when viewed from the polishing table side.

### DESCRIPTION OF EMBODIMENTS

Embodiments of the present invention will be described below with reference to the accompanying drawings. Identical or equivalent constituent components in the diagrams described below are denoted by the same reference sign and duplicate description thereof is omitted.

### First Embodiment

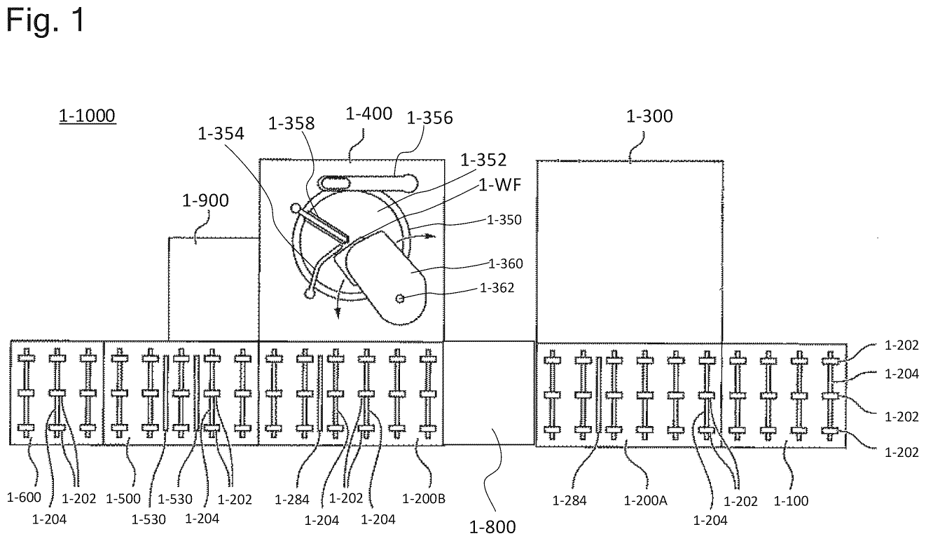

FIG. 1 is a plan view schematically illustrating the entire configuration of a substrate polishing apparatus 1-1000 according to a first embodiment. The substrate polishing apparatus 1-1000 illustrated in FIG. 1 includes a loader 1-100, a first conveyer 1-200A, a second conveyer 1-200B, a grinding module 1-300, a polishing module 1-400, a drying module 1-500, an unloader 1-600, an inverter 1-800, and a control device 1-900. Each constituent component of the substrate polishing apparatus 1-1000 is controlled by the control device 1-900.

### Loader

The loader 1-100 introduces, into the substrate polishing apparatus 1-1000, a substrate 1-WF on which processing such as grinding and polishing is yet to be performed.

The kind, size, and shape of the substrate 1-WF are not particularly limited. The substrate 1-WF may be a semiconductor substrate, and particularly, a disk-shaped substrate or a rectangular substrate. The substrate 1-WF is preferably a rectangular substrate. The dimensions of a circular semiconductor substrate are defined by standards such as SEMI standards, but the dimensions of a square rectangular substrate such as a copper clad laminate substrate (CCL substrate), a printed circuit board (PCB) substrate, a photomask substrate, and a display panel are not defined by standards or the like, and thus rectangular substrates with various dimensions may exist. A rectangular substrate may have large warping or thickness variance, requiring a large amount of grinding or polishing. Furthermore, demand for flatness in a rectangular substrate is increasing. Thus, there is an increasing need to provide a rectangular substrate with high precision through efficient processing, and such a rectangular substrate is preferably applied to the present embodiment. The following description will be made with an example in which the substrate 1-WF is a rectangular substrate.

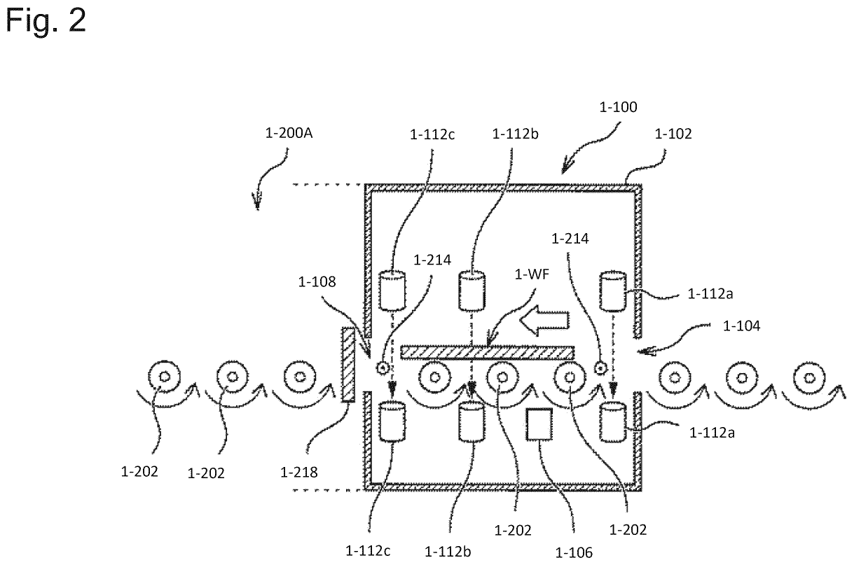

FIG. 2 is a cross-sectional view schematically illustrating the loader 1-100 according to the present embodiment. The loader 1-100 includes a housing 1-102. The housing 1-102 includes an entrance opening 1-104 on a side where the substrate 1-WF is received. In the embodiment illustrated in FIG. 2, the right side is the entrance side. The loader 1-100 receives the substrate 1-WF as a processing target through the entrance opening 1-104. A substrate processing apparatus in which processing processes are performed before processing of the substrate 1-WF by the substrate polishing apparatus 1-1000 is disposed on the upstream side (in FIG. 2, the right side) of the loader 1-100. The loader 1-100 includes an ID reader 1-106. The ID reader 1-106 reads ID of the substrate 1-WF received through the entrance opening 1-104. The substrate polishing apparatus 1-1000 performs various kinds of processing on the substrate 1-WF in accordance with the read ID. The ID reader 1-106 may be omitted. The loader 1-100 is preferably configured to comply with the SMEMA (Surface Mount Equipment Manufacturers Association) machine device interface standard (IPC-SMEMA-9851).

The loader 1-100 includes a plurality of conveyance rollers 1-202 for conveying the substrate 1-WF. The conveyance rollers 1-202 are attached to roller shafts 1-204 (FIG. 1) and rotated by drive of a non-illustrated motor through non-illustrated gears. The substrate 1-WF on the conveyance rollers 1-202 can be conveyed in a predetermined direction (in FIG. 2, the left direction) by rotating the conveyance rollers 1-202. The housing 1-102 of the loader 1-100 includes an exit opening 1-108 for the substrate 1-WF. The loader 1-100 includes sensors 1-112 for sensing existence of the substrate 1-WF at predetermined positions on the conveyance rollers 1-202. The sensors 1-112 may be sensors of an optional format and may be, for example, optical sensors. In the embodiment illustrated in FIG. 2, three sensors 1-112 are provided in the housing 1-102, namely, a sensor 1-112a provided near the entrance opening 1-104, a sensor 1-112b provided near the center of the loader 1-100, and a sensor 1-112c provided near the exit opening 1-108. Operation of the loader 1-100 can be controlled in accordance with sensing of the substrate 1-WF by the sensors 1-112. For example, when existence of the substrate 1-WF is sensed by the sensor 1-112a near the entrance opening 1-104, rotation of the conveyance rollers 1-202 in the loader 1-100 may be started or rotational speed of the conveyance rollers 1-202 may be changed. When existence of the substrate 1-WF is sensed by the sensor 1-112c near the exit opening 1-108, an entrance shutter 1-218 of the first conveyer 1-200A as the following device may be opened.

A conveyance mechanism of the loader 1-100 includes the plurality of conveyance rollers 1-202 and the plurality of roller shafts 1-204 to which the conveyance rollers 1-202 are attached. In the example illustrated in FIG. 1, three conveyance rollers 1-202 are attached to each roller shaft 1-204, but the present invention is not limited thereto. Attachment positions of the conveyance rollers 1-202 on each roller shaft 1-204 may be optional positions where the substrate WF can be reliably conveyed. However, since the conveyance rollers 1-202 contact the substrate 1-WF, the conveyance rollers 1-202 need to be disposed such that the conveyance rollers 1-202 contact regions of the substrate 1-WF as a processing target where the contact causes no problem. The conveyance rollers 1-202 of the loader 1-100 may be made of conductive polymer. The conveyance rollers 1-202 are electrically grounded through the roller shafts 1-204 and the like. This is to prevent the substrate 1-WF from electrically charging and damaging the substrate 1-WF. Alternatively, the loader 1-100 may be provided with an ionizer (not illustrated) to prevent electrical charging of the substrate 1-WF.

In the loader 1-100, auxiliary rollers 1-214 are provided near the entrance opening 1-104 and the exit opening 1-108. The auxiliary rollers 1-214 are disposed at a height approximately equal to that of the conveyance rollers 1-202. The auxiliary rollers 1-214 support the substrate 1-WF so that the substrate 1-WF does not fall between devices while being conveyed. The auxiliary rollers 1-214 is connected to no drive source and configured to be freely rotatable. Note that the configuration of the loader 1-100 is not particularly limited as long as first grinding, second grinding, and polishing by the polishing module 1-400, as will be described later, can be performed.

### First Conveyer

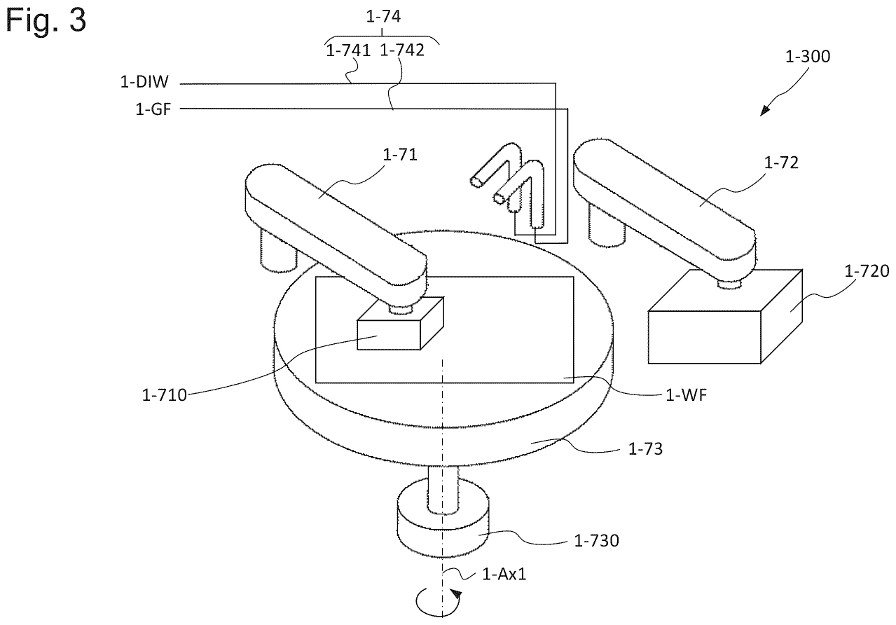

The first conveyer 1-200A conveys the substrate 1-WF unloaded from the loader 1-100 to the grinding module 1-300 and conveys the substrate 1-WF ground by the grinding module 1-300 to the inverter 1-800. The configuration of the first conveyer 1-200A is not particularly limited as long as these conveyances can be performed. In the example illustrated in FIG. 1, the first conveyer 1-200A includes the roller shafts 1-204, the conveyance rollers 1-202 attached to the roller shafts 1-204, and a cleaning nozzle 1-284. The conveyance rollers 1-202 are rotated by drive of a non-illustrated motor through non-illustrated gears. With the rotation of the conveyance rollers 1-202, the substrate 1-WF on the conveyance rollers are conveyed. The cleaning nozzle 1-284 supplies the substrate 1-WF with cleaning liquid for cleaning the substrate 1-WF ground by the grinding module 1-300. The first conveyer 1-200A may include a non-illustrated stopper or arm, and for example, can move the substrate 1-WF being stopped by the stopper onto a table 1-73 (FIG. 3) of the grinding module 1-300 with the arm. Moreover, with the arm, the substrate 1-WF ground by the grinding module 1-300 can be moved onto the conveyance rollers 1-202 of the first conveyer 1-200A.

### Grinding Module

FIG. 3 is a perspective view schematically illustrating the configuration of the grinding module 1-300. The grinding module 1-300 includes a first arm 1-71, a second arm 1-72, the table 1-73, a table drive mechanism 1-730, a first head 1-710 attached to the first arm 1-71, a second head 1-720 attached to the second arm 1-72, and a processing liquid supply system 1-74. In the illustrated example, the first head 1-710 and the second head 1-720 are schematically illustrated in rectangular parallelepiped shapes, but not limited thereto.

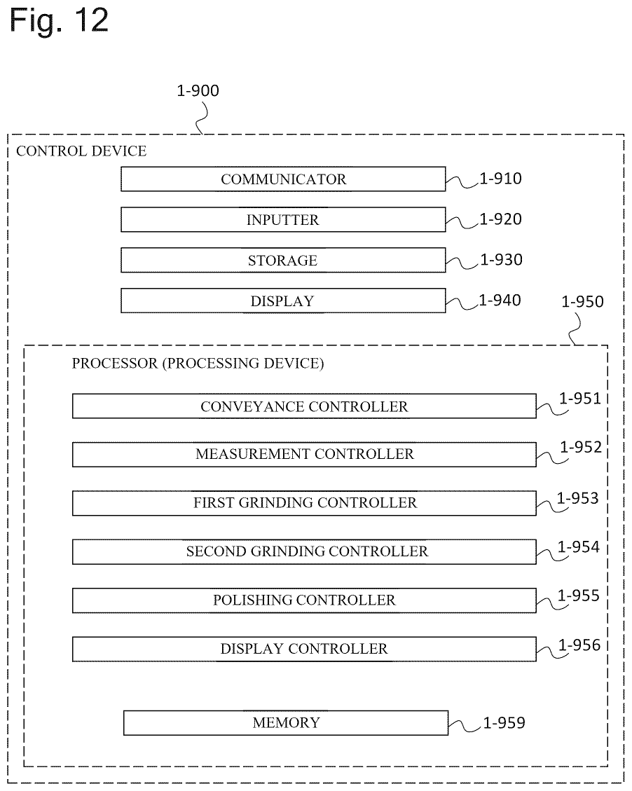

The first arm 1-71 and the second arm 1-72 support the first head 1-710 and the second head 1-720, respectively, so that the heads can swing along a processing surface of the substrate 1-WF. Operations of the first arm 1-71 and the second arm 1-72 are controlled by a first grinding controller 1-953 (FIG. 12) and a second grinding controller 1-954, respectively, which will be described later. The first arm 1-71 and the second arm 1-72 are each configured to be rotatable, without interference with movement of the other, to a retracted position where the first head 1-710 or the second head 1-720 is located at a position other than above the processing surface. In the illustrated example, the second arm 1-72 is retracted at the retracted position where the second head 1-720 is separated from the processing surface. A mechanism that moves the first head 1-710 and the second head 1-720 is not particularly limited as long as the mechanism can move the first head 1-710 and the second head 1-720 to desired positions on the processing surface and the retracted positions, and an XY stage or the like may be used as the mechanism. The first head 1-710 and the second head 1-720 may rotate about the central axes of a first pad surface 1-712 and a second pad surface 1-722, respectively, which will be described later. From the perspective of selectively grinding a narrower range, the first head 1-710 may rotate about an axis tilted relative to the central axis.

The table 1-73 functions as a substrate supporter that supports the substrate 1-WF. The substrate 1-WF is disposed on the table 1-73 with the processing surface facing upward in the vertical direction. In other words, grinding in the grinding module 1-300 is performed by a face-up scheme. With the face-up scheme, partial grinding is easy and a compact grinding module can be configured with a grinding member smaller than the substrate 1-WF. The surface of the table 1-73 preferably contains a porous material for sucking air and fixes the substrate 1-WF by adsorption. The table 1-73 can rotate about a rotational axis 1-Ax1 with the table drive mechanism 1-730. The table 1-73 may cause, with the table drive mechanism 1-730, the substrate 1-WF to perform angular rotational motion or scrolling motion or stop at an optional position on the table 1-73 after rotation. Through combination of this motion and swing motion of the first arm 1-71 and the second arm 1-72, the first head 1-710 and the second head 1-720 can move to optional positions on the substrate 1-WF.

The processing liquid supply system 1-74 includes a pure water pipe 1-741 for supplying pure water (1-DIW) to the processing surface of the substrate 1-WF. The pure water pipe 1-741 has a first end connected to a non-illustrated pure water supply source and has a second end disposed above the substrate 1-WF. The control device 1-900 controls pure water supply by controlling opening and closing of a non-illustrated on-off valve installed on the pure water pipe 1-741.

The processing liquid supply system 1-74 includes a grinding liquid pipe 1-742 for supplying pure water or grinding liquid (1-GF) such as drug solution to the processing surface of the substrate 1-WF. The grinding liquid pipe 1-742 has a first end connected to a non-illustrated grinding liquid supply source and has a second end disposed above the substrate 1-WF. The control device 1-900 controls grinding liquid supply by controlling opening and closing of a non-illustrated on-off valve installed on the grinding liquid pipe 1-742.

Note that, alternatively or additionally, at least one of the pure water pipe 1-741 and the grinding liquid pipe 1-742 may be disposed inside the first arm 1-71 and the second arm 1-72 or along their surfaces and may supply pure water or grinding liquid to the processing surface from the first head 1-710 and the second head 1-720. The method of liquid supply to the processing surface is not particularly limited.

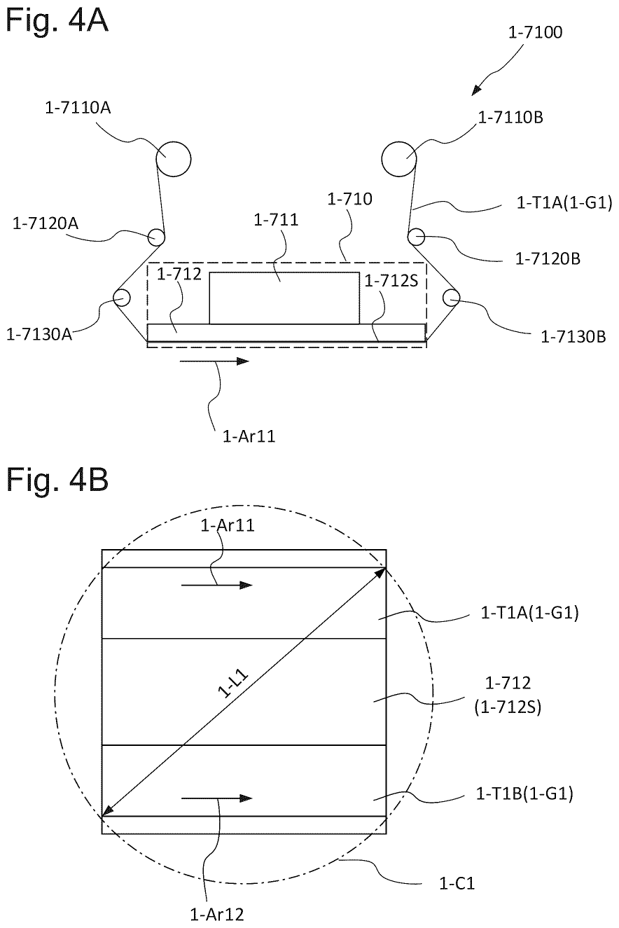

FIG. 4A is a conceptual diagram for description of a first grinding member 1-G1 disposed on the first head 1-710. The first head 1-710 includes a first pressing mechanism 1-711 and a first pressing pad 1-712. A polishing tape 1-T1A is slidably disposed along a first pad surface 1-712S of the first pressing pad 1-712 (arrow 1-Ar11). The polishing tape 1-T1A is the first grinding member 1-G1 that contacts and grinds the processing surface in the first grinding to be described later. The first pressing mechanism 1-711 is not particularly limited to an aspect as long as the first pressing mechanism 1-711 presses the first pressing pad 1-712. The polishing tape 1-T1A is pressed against the substrate 1-WF by pressing from the first pressing pad 1-712.

The polishing tape 1-T1A is fed by a first tape feeding mechanism 1-7100 and slides on the first pressing pad 1-712. The first tape feeding mechanism 1-7100 includes an unwind reel 1-7110A, support rods 1-7120A, 1-7130A, 1-7130B, and 1-7120B, and a wind reel 1-7110B. The unwind reel 1-7110A and the wind reel 1-7110B have cylindrical shapes with cylindrical surfaces around which the polishing tape 1-T1A is wound. The unwind reel 1-7110A and the wind reel 1-7110B can rotate about their cylindrical axes to unwind and wind, respectively, the polishing tape 1-T1A. The support rods 1-7120A, 1-7130A, 1-7130B, and 1-7120B are fixed to the first head 1-710 or the first arm 1-71 and support the polishing tape 1-T1A, and define a movement path for the polishing tape 1-T1A.

FIG. 4B is a conceptual diagram for description of a maximum diameter 1-L1 of the first grinding member 1-G1. FIG. 4B is a plan view schematically illustrating the first pad surface 1-712S of the first pressing pad 1-712. In the first head 1-710 of the present embodiment, polishing tapes 1-T1A and 1-T1B as the first grinding member 1-G1 are disposed on the first pad surface 1-712S. In the illustrated example, slide of the polishing tape 1-T1B on the first pad surface is schematically illustrated with arrow 1-Ar12. The polishing tape 1-T1B may be fed by the same tape feeding mechanism as that for the polishing tape 1-T1A.

The maximum diameter 1-L1 of the first grinding member 1-G1 is the longest distance between two points on the first grinding member (polishing tapes 1-T1A and 1-T1B) disposed on the first pad surface 1-712S of the first head 1-710. In the illustrated example, the distance is the length of a diagonal line of a rectangle surrounding the polishing tapes 1-T1A and 1-T1B arranged in parallel. In other words, the maximum diameter 1-L1 of the first grinding member 1-G1 corresponds to the diameter of a circumcircle 1-C1 of polishing tapes disposed on the first pad surface 1-712S.

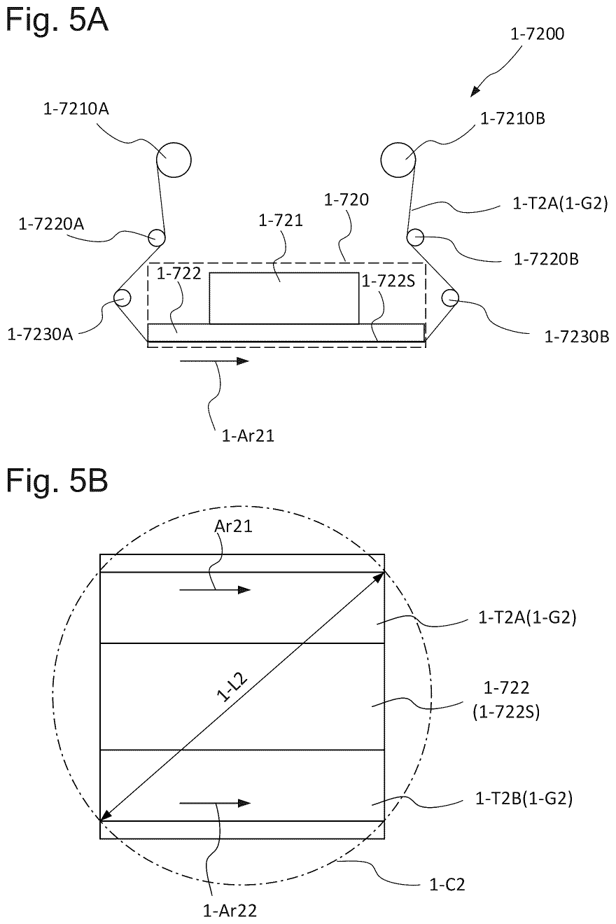

FIG. 5A is a conceptual diagram for description of a second grinding member 1-G2 disposed on the second head 1-720. The second head 1-720 includes a second pressing mechanism 1-721 and a second pressing pad 1-722. A polishing tape 1-T2A is slidably disposed along a second pad surface 1-722S of the second pressing pad 1-722 (arrow 1-Ar21). The polishing tape 1-T2A is the second grinding member 1-G2 that contacts and grinds the processing surface in the second grinding to be described later. The second pressing mechanism 1-721 is not particularly limited to an aspect as long as the second pressing mechanism 1-721 presses the second pressing pad 1-722. The polishing tape 1-T2A is pressed against the substrate 1-WF by pressing from the second pressing pad 1-722.

The polishing tape 1-T2A is fed by a second tape feeding mechanism 1-7200 and slides on the second pressing pad 1-722. The second tape feeding mechanism 1-7200 includes an unwind reel 1-7210A, support rods 1-7220A, 1-7230A, 1-7230B, and 1-7220B, and a wind reel 1-7210B. The unwind reel 1-7210A and the wind reel 1-7210B have cylindrical shapes with cylindrical surfaces around which the polishing tape 1-T2A is wound. The unwind reel 1-7210A and the wind reel 1-7210B are configured to be able to rotate about their cylindrical axes to unwind and wind, respectively, the polishing tape 1-T2A. The support rods 1-7220A, 1-7230A, 1-7230B, and 1-7220B are fixed to the second head 1-720 or the second arm 1-72 and support the polishing tape 1-T2A, and define a movement path for the polishing tape 1-T2A.

FIG. 5B is a conceptual diagram for description of a maximum diameter 1-L2 of the second grinding member 1-G2. FIG. 5B is a plan view schematically illustrating the second pad surface 1-722S of the second pressing pad 1-722. In the second head 1-720 of the present embodiment, polishing tapes 1-T2A and 1-T2B as the second grinding member 1-G2 are disposed on the second pad surface 1-722S. In the illustrated example, slide of the polishing tape 1-T2B on the second pad surface is schematically illustrated with arrow 1-Ar22. The polishing tape 1-T2B may be fed by the same tape feeding mechanism as that for the polishing tape 1-T2A.

The maximum diameter 1-L2 of the second grinding member 1-G2 is the longest distance between two points on the second grinding member (polishing tapes 1-T2A and 1-T2B) disposed on the second pad surface 1-722S of the second head 1-720. In the illustrated example, the distance is the length of a diagonal line of a rectangle surrounding the polishing tapes 1-T2A and 1-T2B arranged in parallel. In other words, the maximum diameter 1-L2 of the second grinding member 1-G2 corresponds to the diameter of a circumcircle 1-C2 of polishing tapes disposed on the second pad surface 1-722S.

The material of the first grinding member 1-G1 and the second grinding member 1-G2 is not particularly limited. From the perspective of performing fabrication at higher speed more efficiently than polishing by the polishing module 1-400 to be described later or from the perspective of performing rough cutting at high speed, the first grinding member 1-G1 and the second grinding member 1-G2 preferably contain a material with a higher stiffness or elastic modulus than a polishing member of the polishing module 1-400. For example, as described above, the first grinding member 1-G1 and the second grinding member 1-G2 may be polishing tapes formed by disposing abrasive particles made of the above-described material, for example, diamond abrasive particles on a base member. In this case, to prevent fall of the abrasive particles, the surfaces of the abrasive particles may be coated with resin or the abrasive particles may be attached to the base member by electrodeposition. Note that the material of the base member is, for example, at least one or combination of polyimide, rubber, PET, resin materials, composite materials impregnated with fibers in these materials, and metal foils.

Note that the number of polishing tapes disposed as the first grinding member 1-G1 or the second grinding member 1-G2 on the first pad surface 1-712S or the second pad surface 1-722S is not particularly limited but may be one or three or more. In a case where the width of a polishing tape is too large, sliding of the polishing tape and availability of the polishing tape may be difficult, and thus a plurality of polishing tapes are preferably disposed on one pad surface as in the illustrated example.

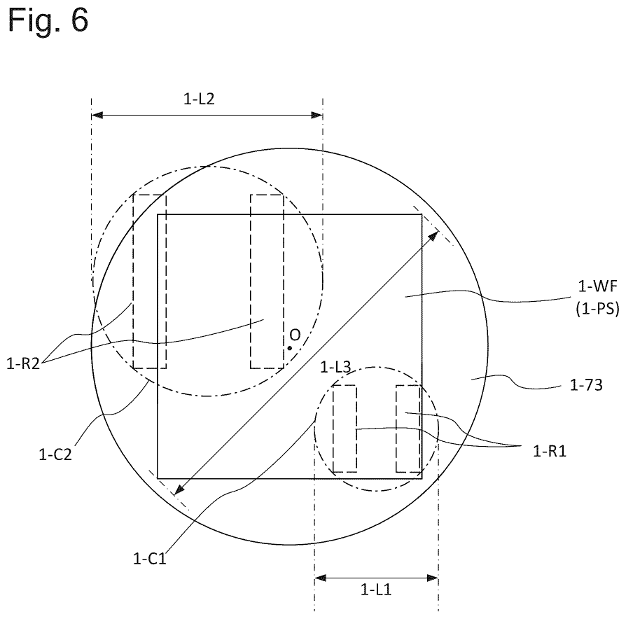

FIG. 6 is a conceptual diagram for description of the first grinding and the second grinding. In the following description, grinding that the first grinding member 1-G1 performs in contact with the substrate 1-WF is referred to as the first grinding, and grinding that the second grinding member 1-G2 performs in contact with the substrate 1-WF is referred to as the second grinding. A maximum diameter 1-L3 of a processing surface 1-PS of the substrate 1-WF is the longest distance along the processing surface 1-PS between two points on the processing surface 1-PS. In a case of the illustrated rectangular substrate, the maximum diameter 1-L3 corresponds to the length of a diagonal line of the rectangular processing surface 1-PS.

In FIG. 6, quadrilaterals 1-R1 (dashed line) represent first grinding surfaces that are parts of a polishing tape as the first grinding member 1-G1 contacting the substrate 1-WF. The maximum diameter 1-L1 of the first grinding member 1-G1 is the diameter of the circumcircle 1-C1 (dashed and single-dotted line) of the quadrilaterals 1-R1. Quadrilaterals 1-R2 (dashed line) represent second grinding surfaces that are parts of a polishing tape as the second grinding member 1-G2 contacting the substrate 1-WF. The maximum diameter 1-L2 of the second grinding member 1-G2 is the diameter of the circumcircle 1-C2 (dashed and single-dotted line) of the quadrilaterals 1-R2.

The maximum diameter 1-L2 of the second grinding member 1-G2 is larger than the maximum diameter 1-L1 of the first grinding member 1-G1. Accordingly, grinding can be more locally performed in the first grinding than in the second grinding. Moreover, the maximum diameter 1-L2 of the second grinding member 1-G2 is preferably larger than the half of the maximum diameter 1-L3 of the processing surface I-PS. Accordingly, entire surface grinding can be easily performed by using the rotating table 1-73 in the second grinding. The maximum diameter 1-L1 of the first grinding member 1-G1 is preferably smaller than the half of the maximum diameter 1-L3 of the processing surface 1-PS. Accordingly, partial grinding can be easily performed. The maximum diameter 1-L2 of the second grinding member 1-G2 is smaller than the maximum diameter 1-L3 of the processing surface 1-PS. Accordingly, the grinding module 1-300 can be compactly configured to a size slightly larger than the substrate 1-WF.

In first and second embodiments below, grinding means to provide slits to the processing surface 1-PS by motion of a grinding member and remove parts of the surface of the substrate 1-WF. Polishing means to remove parts of the surface of the substrate 1-WF as a pressed polishing member slides on the processing surface 1-PS. Grinding and polishing also include to remove parts of the surface of the substrate 1-WF directly through chemical reaction with grinding liquid or polishing liquid or by using the chemical reaction. Partial grinding of the processing surface 1-PS means grinding to grind only part of the processing surface 1-PS, and entire surface grinding means grinding to grind the entire processing surface 1-PS. In addition, partial polishing means polishing to polish only part of the processing surface 1-PS, and entire surface polishing means polishing to polish the entire processing surface 1-PS.

In the present embodiment, the second grinding is performed after the first grinding is performed. After convex parts and the like are ground in the first grinding, a wider range of the substrate 1-WF is ground in the second grinding to establish polishing conditions before polishing by the polishing module 1-400 so that high-precision polishing can be efficiently performed.

Note that, in the present embodiment, the first grinding member 1-G1 and the second grinding member 1-G2 are polishing tapes as grinding members of the same kind. However, the first grinding member 1-G1 and the second grinding member 1-G2 may be grinding members different from each other. Moreover, the first grinding and the second grinding may be performed in a plurality of identical or different grinding modules. For example, a grinding module of the face-up scheme may be additionally provided and perform the first grinding or the second grinding with a fixed abrasive lapping plate as a grinding member. The first grinding and the second grinding may be both performed with the fixed abrasive lapping plate.

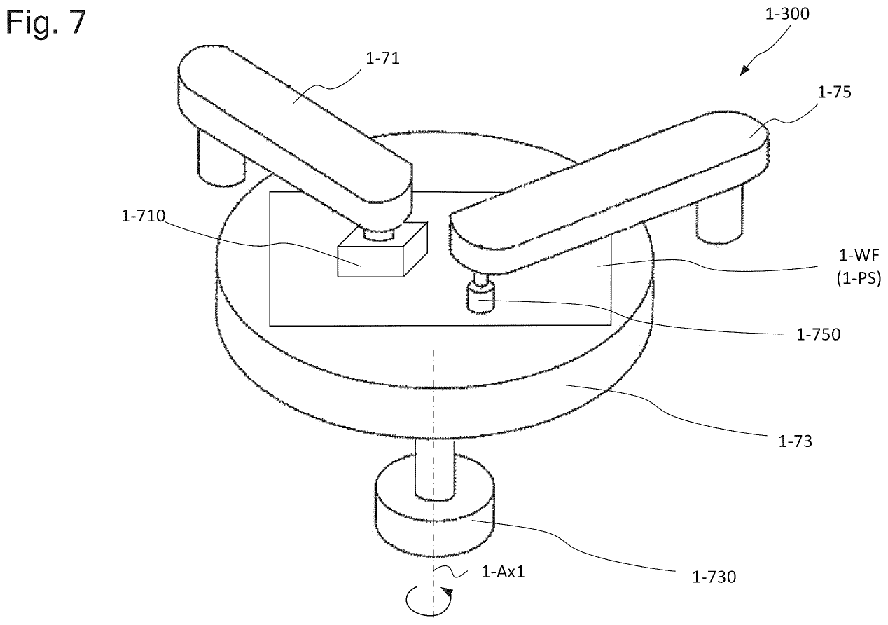

FIG. 7 is a conceptual diagram schematically illustrating a measurement device 1-750 according to the present embodiment. The grinding module 1-300 includes a third arm 1-75 and the measurement device 1-750 attached to the third arm 1-75. In FIG. 7, illustrations of the second arm 1-72 and the processing liquid supply system 1-74 are omitted.

The measurement device 1-750 measures the shape of the processing surface 1-PS of the substrate 1-WF. Hereinafter, shape measurement means measurement of the shape of the processing surface 1-PS. Shape data indicating the shape of the processing surface 1-PS measured by the measurement device 1-750 is output to the control device 1-900. Alternatively, the control device 1-900 may produce the shape data by processing a measurement signal detected by the measurement device 1-750. The measurement device 1-750 may be a Wet-ITM (in-line thickness monitor) as an example. The Wet-ITM has a detection head on a substrate in a non-contact state and can detect (measure) film thickness distribution (or distribution of information related to the film thickness) of a film formed on the substrate 1-WF by moving the entire surface of the substrate. For example, the detection head detects film thickness distribution on the rotating substrate 1-WF while moving on a locus passing through the center of the substrate 1-WF. The measurement device 1-750 does not necessarily need to be attached to the third arm 1-75 as long as film thickness distribution of a desired range of the processing surface 1-PS can be detected. For example, the measurement device 1-750 may be attached to the first arm 1-71 or the second arm 1-72 or may be moved by an XY stage. Note that, in a case where information of the shape of the processing surface 1-PS is obtained in advance, the substrate polishing apparatus 1-1000 does not necessarily need to include the measurement device 1-750 and a substrate polishing method does not necessarily need to include the shape measurement.

In the present embodiment, the shape measurement may be performed while the second grinding is performed as described later. In this case, the shape measurement may be continuously or intermittently performed while the second grinding is performed with the second arm 1-72 and the third arm 1-75 moving without contacting each other. The same applies in a case where the shape measurement is performed while the first grinding is performed in a modification to be described later.

Note that a measurement device of an optional detecting method other than a Wet-ITM may be used as the measurement device 1-750. Examples of applicable detecting methods include a detecting method of a non-contact scheme such as an eddy current scheme or an optical scheme, which is publicly known, and also include a detecting method of a contact scheme. The detecting method of a contact scheme is, for example, electric resistance detection of preparing a detection head including a probe that can be energized, bringing the probe into contact with the substrate 1-WF, and performing scanning in the surface of the substrate 1-WF in an energized state to detect film resistance distribution. Alternatively, the detecting method of another contact scheme may be a step detecting method of performing scanning in the surface of the substrate 1-WF with a probe in contact with the surface of the substrate 1-WF and monitoring upward and downward movement of the probe to detect irregularity distribution on the surface. In any of the detecting methods of a contact scheme and a non-contact scheme, film thickness or a signal corresponding to the film thickness is obtained. In optical detection, film thickness difference may be recognized based on difference in color tone on the surface of the substrate 1-WF in addition to the amount of reflected light from emitted light. In this manner, the control device 1-900 can acquire data of thickness distribution of a film formed on the substrate 1-WF based on analysis of measurement data obtained when the measurement device 1-750 emits light to the processing surface 1-PS and receives light, such as reflected light or infrared from the processing surface 1-PS, from the substrate 1-WF based on the emitted light. Accordingly, information of the shape of the processing surface 1-PS can be efficiently obtained in a non-contact manner, and grinding processing can be efficiently performed based on the information.

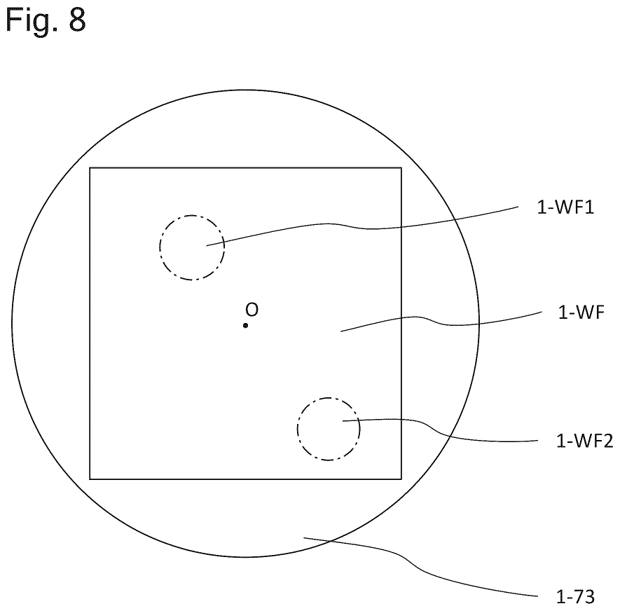

FIG. 8 is a conceptual diagram for description of setting of the range of the first grinding. For example, in a case where convex parts 1-WF1 and 1-WF2 of the substrate 1-WF are detected by the measurement device 1-750, the first arm 1-71 and the table drive mechanism 1-730 are controlled so that the convex parts 1-WF1 and 1-WF2 are included in the range of movement of the first head 1-710 caused by swing of the first arm 1-71.

### Inverter

In FIG. 1, the inverter 1-800 inverts the front and back sides of the substrate 1-WF. On the first conveyer 1-200A, the processing surface 1-PS of the substrate 1-WF faces upward in the vertical direction. The inverter 1-800 inverts the substrate 1-WF so that the processing surface 1-PS of the substrate 1-WF faces downward in the vertical direction. The kind of the inverter 1-800 is not particularly limited as long as the inverter 1-800 can invert the substrate 1-WF. The substrate 1-WF inverted by the inverter 1-800 is unloaded to the second conveyer 1-200B.

### Second Conveyer

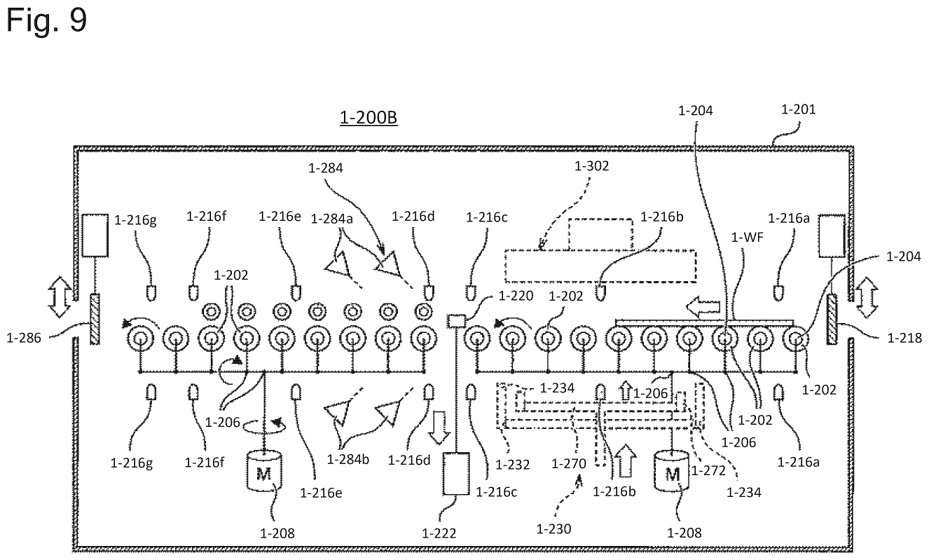

FIG. 9 is a cross-sectional view schematically illustrating the configuration of the second conveyer 1-200B. The second conveyer 1-200B unloads the substrate 1-WF inverted by the inverter 1-800 into the polishing module 1-400. The second conveyer 1-200B is disposed in a housing 1-201 and includes a plurality of conveyance rollers 1-202 for conveying the substrate 1-WF. The substrate 1-WF on the conveyance rollers 1-202 can be conveyed in a predetermined direction by rotating the conveyance rollers 1-202. The conveyance rollers 1-202 of the second conveyer 1-200B may be formed of conductive polymer or non-conductive polymer. The conveyance rollers 1-202 are attached to roller shafts 1-204 and driven by a motor 1-208 through gears 1-206. The motor 1-208 may be a servomotor. With the servomotor, rotational speed of the roller shafts 1-204 and the conveyance rollers 1-202, that is, conveyance speed of the substrate 1-WF can be controlled. The gears 1-206 may be magnet gears. Since the magnet gears are power transmission mechanisms of a non-contact scheme, fine particles due to abrasion are not generated unlike with gears of a contact scheme, and maintenance such as lubrication is unnecessary. In the illustrated example, the second conveyer 1-200B includes sensors 1-216 for sensing existence of the substrate 1-WF at predetermined positions on the conveyance rollers 1-202. The sensors 1-216 may be sensors of an optional format and may be, for example, optical sensors. In the illustrated example, seven sensors 1-216 (1-216a to 1-216g) are provided in the conveyer 1-200. The control device 1-900 (FIG. 1) can control operation of the second conveyer 1-200 in accordance with sensing of the substrate 1-WF by the sensors 1-216a to 1-216g. The second conveyer 1-200B includes an entrance shutter 1-218 that can be opened and closed to receive the substrate 1-WF into the second conveyer 1-200B. The second conveyer 1-200B includes an exit shutter 1-286 that can be opened and closed to unload the substrate 1-WF from the second conveyer 1-200B.

The second conveyer 1-200B includes a stopper 1-220. The stopper 1-220 is connected to a stopper movement mechanism 1-222 and can enter the conveyance path of the substrate 1-WF moving on the conveyance rollers 1-202. When the stopper 1-220 is positioned in the conveyance path of the substrate 1-WF, a side surface of the substrate 1-WF moving on the conveyance rollers 1-202 contacts the stopper 1-220, and thus the moving substrate 1-WF can be stopped at the position of the stopper 1-220. When the stopper 1-220 is at the position retracted from the conveyance path of the substrate 1-WF, the substrate 1-WF can move on the conveyance rollers 1-202. The position where the substrate 1-WF is stopped by the stopper 1-220 is a position (substrate transfer position) where a pusher 1-230 to be described later can receive the substrate 1-WF on the conveyance rollers 1-202.

The second conveyer 1-200B includes the pusher 1-230. The pusher 1-230 is configured to be able to lift up the substrate 1˜WF on the plurality of conveyance rollers 1-202 away from the plurality of conveyance rollers 1-202. The pusher 1-230 is also configured to be able to transfer the held substrate 1-WF to a top ring 1-302 of the polishing module 1-400.

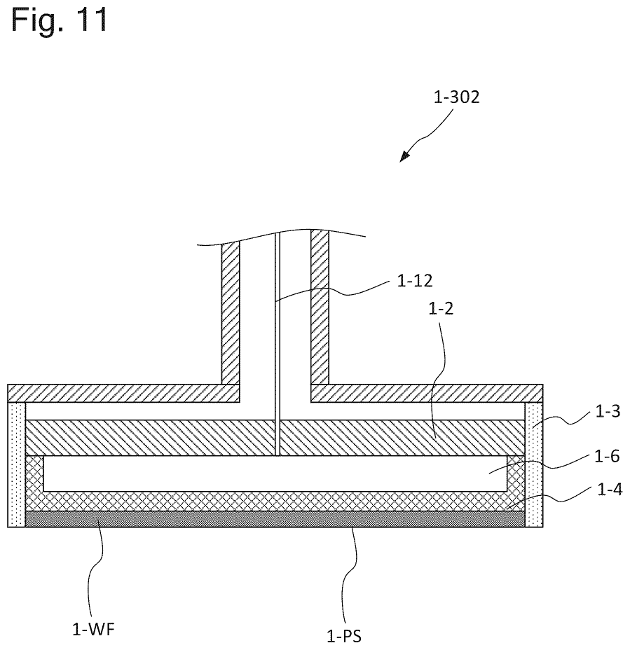

The pusher 1-230 includes a first stage 1-232 and a second stage 1-270. The first stage 1-232 is a stage for supporting a retainer member 1-3 (FIG. 11) of the top ring 1-302 when the substrate 1-WF is transferred from the pusher 1-230 to the top ring 1-302. The first stage 1-232 includes a plurality of support pillars 1-234 for supporting the retainer member 1-3 of the top ring 1-302. The second stage 1-270 is a stage for receiving the substrate 1-WF on the conveyance rollers 1-202. The second stage 1-270 includes a plurality of support pillars 1-272 for receiving the substrate 1-WF on the conveyance rollers 1-202. The first stage 1-232 and the second stage 1-270 can be moved in the height direction by a first elevation mechanism. The second stage 1-270 can be further moved in the height direction relative to the first stage 1-232 by a second elevation mechanism. When the first stage 1-232 and the second stage 1-270 are moved up by the first elevation mechanism and the second elevation mechanism, some of the support pillars 1-234 of the first stage 1-232 and the support pillars 1-272 of the second stage 1-270 pass between the conveyance rollers 1-202 and the roller shafts 1-204 and reach a position higher than the conveyance rollers 1-202. The substrate 1-WF conveyed on the conveyance rollers 1-202 is stopped at the substrate transfer position by the stopper 1-220. Thereafter, the first stage 1-232 and the second stage 1-270 are moved up by the first elevation mechanism to lift up the substrate 1-WF on the conveyance rollers 1-202 by the support pillars 1-272 of the second stage 1-270. Thereafter, the second stage 1-270 holding the substrate 1-WF is moved up by the second elevation mechanism while the retainer member 1-3 of the top ring 1-302 is supported by the support pillars 1-234 of the first stage 1-232. The substrate 1-WF on the second stage 1-270 is received and held by the top ring 1-302 by vacuum adsorption.

The second conveyer 1-200B includes a cleaner. The cleaner includes the cleaning nozzles 1-284. The cleaning nozzles 1-284 include upper cleaning nozzles 1-284a disposed on the upper side of the conveyance rollers 1-202, and lower cleaning nozzles 1-284b disposed on the lower side. The upper cleaning nozzles 1-284a and the lower cleaning nozzles 1-284b are connected to a non-illustrated supply source of cleaning liquid. The upper cleaning nozzles 1-284a are configured to supply the cleaning liquid to the upper surface of the substrate 1-WF conveyed on the conveyance rollers 1-202. The lower cleaning nozzles 1-284b are configured to supply the cleaning liquid to the lower surface of the substrate 1-WF conveyed on the conveyance rollers 1-202. The upper cleaning nozzles 1-284a and the lower cleaning nozzles 1-284b have widths approximately equal to or larger than the width of the substrate 1-WF conveyed on the conveyance rollers 1-202 and are configured so that the entire surface of the substrate 1-WF is cleaned as the substrate 1-WF is conveyed on the conveyance rollers 1-202. The cleaner is positioned on the downstream side of the substrate transfer position of the pusher 1-230.

The second conveyer 1-200B receives the substrate 1-WF polished by the polishing module 1-400 from the top ring 1-302, cleans the substrate 1-WF as appropriate, and then unloads the substrate 1-WF to the drying module 1-500. The configuration of the second conveyer 1-200B is not particularly limited as long as the second conveyer 1-200B can unload the substrate 1-WF to the polishing module 1-400, load the substrate 1-WF from the polishing module 1-400, and unload the substrate 1-WF to the drying module 1-500.

### Polishing Module

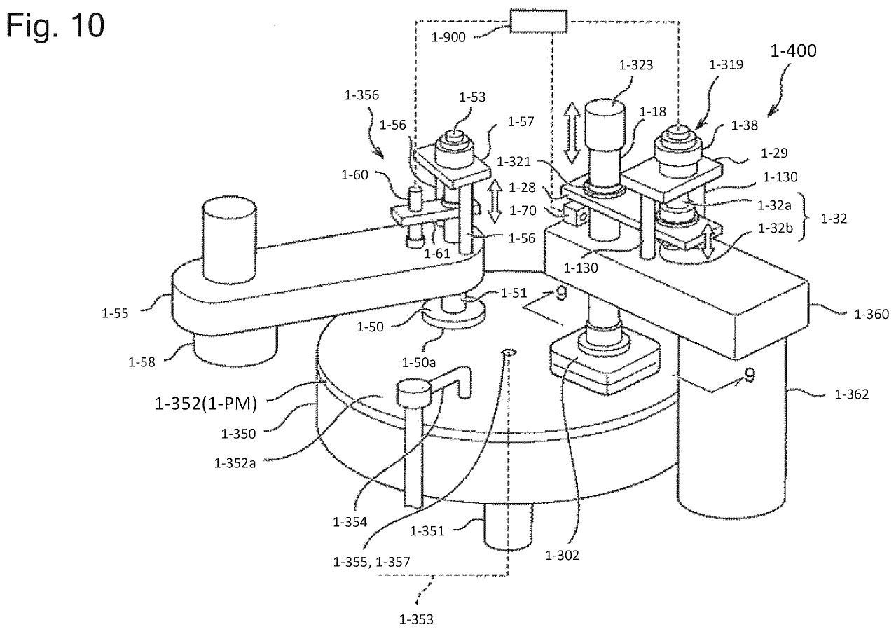

FIG. 10 is a perspective view schematically illustrating the configuration of the polishing module 1-400. The polishing module 1-400 performs polishing of the substrate 1-WF. The polishing is not particularly limited to an aspect but is preferably CMP polishing, and the entire surface polishing is preferably performed from the perspective of accurately fabricating or finishing the entire substrate 1-WF. In the substrate polishing method according to the present embodiment, thickness variance (with an indicator that is, for example, total thickness variation (TTV) as the difference between the maximum and minimum values of distance from a back-surface reference surface to be described later) of the entire substrate 1-WF can be solved at high speed by grinding with combination of the first grinding member 1-G1 and the second grinding member 1-G2 as described above. In addition, finishing polishing can be performed at low speed by the polishing member, and thus it is possible to perform high-precision fabrication with high processing performance (throughput) as compared to entire surface polishing only with a polishing member, which takes a long time for fabrication.

The polishing module 1-400 includes a polishing table 1-350, and the top ring 1-302 constituting a polishing head that holds the substrate 1-WF as a polishing target object and presses the substrate 1-WF against a polishing surface 1-352a on the polishing table 1-350. The polishing table 1-350 is coupled to a polishing table rotation motor (not illustrated) disposed below through a table shaft 1-351 and is rotatable about the table shaft 1-351. A polishing pad 1-352 is bonded to the upper surface of the polishing table 1-350, and the surface of the polishing pad 1-352 serves as the polishing surface 1-352a that polishes the substrate. The polishing pad 1-352 functions as a polishing member 1-PM that contacts and polishes the processing surface 1-PS. The speed of fabrication by the polishing member 1-PM sometimes becomes lower than the speed of fabrication by the grinding members in a case where the stiffness of the polishing member 1-PM is low and the granularity of abrasive particles is small. However, polishing by the polishing member 1-PM reduces surface roughness of a polishing target object and is unlikely to scratch the polishing target object, and thus is preferable for finishing fabrication. The polishing pad 1-352 may be bonded through a layer for facilitating peeling from the polishing table 1-350. Such a layer is, for example, a silicone layer or a fluororesin layer and may be, for example, a layer disclosed in Japanese Patent Laid-Open No. 2014-176950.

The kind of the polishing pad 1-352 is not particularly limited and may be as follows, for example. There are various kinds of polishing pads available on the market, such as SUBA800 (“SUBA” is a registered trademark), IC-1000, and IC-1000/SUBA400 (dual-layer cross) manufactured by Nitta Haas Co., and Surfin xxx-5 and Surfin 000 (“surfin” is a registered trademark) manufactured by Fujimi Incorporated. SUBA800, Surfin xxx-5, and Surfin 000 are non-woven fabrics where fibers are consolidated with urethane resin, and IC-1000 is a rigid foamed polyurethane (single layer). The foamed polyurethane is porous and has a large number of minute depressions or holes on its surface.

A polishing liquid supply nozzle 1-354 is installed above the polishing table 1-350, and polishing liquid is supplied onto the polishing pad 1-352 on the polishing table 1-350 by the polishing liquid supply nozzle 1-354. A path 1-353 for supplying the polishing liquid is provided through the polishing table 1-350 and the table shaft 1-351. The path 1-353 communicates with an opening part 1-355 through the surface of the polishing table 1-350. The polishing pad 1-352 is formed with a through-hole 1-357 at a position corresponding to the opening part 1-355 of the polishing table 1-350, and the polishing liquid passing through the path 1-353 is supplied to the surface of the polishing pad 1-352 through the opening part 1-355 of the polishing table 1-350 and the through-hole 1-357 of the polishing pad 1-352. The polishing liquid is slurry obtained by combining abrasive particles, a dispersant that separates the abrasive particles, and one or more chemical components such as predetermined drug solution or oxidant at a predetermined ratio in accordance with the kind of a polishing target object, in particular, a polishing accumulation film on the substrate 1-WF. The abrasive particles are selected to be those having a predetermined material, a predetermined granularity, and a predetermined particle size distribution as appropriate. The drug solution is selected to be acid, alkali, surfactant, or the like as appropriate. Note that the number of opening parts 1-355 of the polishing table 1-350 and the number of through-holes 1-357 of the polishing pad 1-352 may be each one or plural. Moreover, the opening part 1-355 of the polishing table 1-350 and the through-hole 1-357 of the polishing pad 1-352 may be disposed at optional positions, for example, near the center of the polishing table 1-350.

As in the example illustrated in FIG. 1, the polishing module 1-400 may include an atomizer 1-358 for spraying liquid or mixed fluid of liquid and gas toward the polishing pad 1-352. The liquid sprayed from the atomizer 1-358 is, for example, pure water, and the gas is, for example, nitrogen gas.

The top ring 1-302 is connected to a top ring shaft 1-18, and the top ring shaft 1-18 moves upward and downward relative to a swing arm 1-360 by an up-down movement mechanism 1-319. With the upward and downward movement of the top ring shaft 1-18. the entire top ring 1-302 is moved upward and downward and positioned relative to the swing arm 1-360. The top ring shaft 1-18 is rotated by drive of a non-illustrated top ring rotation motor. With the rotation of the top ring shaft 1-18, the top ring 1-302 rotates about the top ring shaft 1-18. Note that a rotary joint 1-323 is attached at the upper end of the top ring shaft 1-18.

The top ring 1-302 can hold the rectangular substrate 1-WF on its lower surface. The swing arm 1-360 is configured to be rotatable about a support shaft 1-362. With the rotation of the swing arm 1-360, the top ring 1-302 is movable between the above-described substrate transfer position of the second conveyer 1-200B and a position above the polishing table 1-350. By moving down the top ring shaft 1-18, the top ring 1-302 can be moved down to press the substrate against the surface (polishing surface 1-352a) of the polishing pad 1-352. Then, the top ring 1-302 and the polishing table 1-350 are each rotated and the polishing liquid is supplied onto the polishing pad 1-352 from the polishing liquid supply nozzle 1-354 provided above the polishing table 1-350 and/or from the opening part 1-355 provided through the polishing table 1-350. In this manner, the processing surface 1-PS of the substrate 1-WF can be polished with the substrate 1-WF pressed against the polishing surface 1-352a of the polishing pad 1-352. During the polishing of the substrate 1-WF, the swing arm 1-360 may be fixed or swung so that the top ring 1-302 passes through the center of the polishing pad 1-352 (covers the through-hole 1-357 of the polishing pad 1-352).

The up-down movement mechanism 1-319, which moves upward and downward the top ring shaft 1-18 and the top ring 1-302, includes a bridge 1-28 that rotatably supports the top ring shaft 1-18 through a bearing 1-321, a ball screw 1-32 attached to the bridge 1-28, a supporting table 1-29 supported by supports 1-130, and an AC servomotor 1-38 provided on the supporting table 1-29. The supporting table 1-29 supporting the servomotor 1-38 is fixed to the swing arm 1-360 through the supports 1-130.

The ball screw 1-32 includes a screw shaft 1-32a coupled to the servomotor 1-38, and a nut 1-32b into which the screw shaft 1-32a is screwed. The top ring shaft 1-18 moves upward and downward integrally with the bridge 1-28. Thus, when the servomotor 1-38 is driven, the bridge 1-28 moves upward and downward through the ball screw 1-32, and accordingly, the top ring shaft 1-18 and the top ring 1-302 move upward and downward. The polishing module 1-400 includes a distance measurement sensor 1-70 as a position detector that detects distance to the lower surface of the bridge 1-28, in other words, the position of the bridge 1-28. The position of the top ring 1-302 can be detected by detecting the position of the bridge 1-28 with the distance measurement sensor 1-70. The distance measurement sensor 1-70 constitutes the up-down movement mechanism 1-319 together with the ball screw 1-32 and the servomotor 1-38. Note that the distance measurement sensor 1-70 may be a laser sensor, an ultrasonic wave sensor, an overcurrent sensor, or a linear scale sensor. Instruments in the polishing module, such as the distance measurement sensor 1-70 and the servomotor 1-38 are configured to be controlled by the control device 1-900.

In the illustrated example, the polishing module 1-400 includes a dressing device 1-356 that dresses the polishing surface 1-352a of the polishing pad 1-352. The dressing device 1-356 includes a dresser 1-50 that is in sliding contact with the polishing surface 1-352a, a dresser shaft 1-51 to which the dresser 1-50 is coupled, an air cylinder 1-53 provided at the upper end of the dresser shaft 1-51, and a swing arm 1-55 that rotatably supports the dresser shaft 1-51. A lower part of the dresser 1-50 is constituted by a dressing member 1-50a, and needle-shaped diamond particles are attached to the lower surface of the dressing member 1-50a. The air cylinder 1-53 is disposed on a supporting table 1-57 supported by supports 1-56, and the supports 1-56 are fixed to the swing arm 1-55.

The swing arm 1-55 is configured to rotate about a support shaft 1-58 when driven by a non-illustrated motor. The dresser shaft 1-51 is rotated by drive of a non-illustrated motor, and the dresser 1-50 rotates about the dresser shaft 1-51 with the rotation of the dresser shaft 1-51. The air cylinder 1-53 moves upward and downward the dresser 1-50 through the dresser shaft 1-51 and presses the dresser 1-50 against the polishing surface 1-352a of the polishing pad 1-352 with predetermined pressing force.

Dressing of the polishing surface 1-352a of the polishing pad 1-352 is performed as follows. The dresser 1-50 is pressed against the polishing surface 1-352a by the air cylinder 1-53, and simultaneously, pure water is supplied to the polishing surface 1-352a from a non-illustrated pure water supply nozzle. In this state, the dresser 1-50 rotates about the dresser shaft 1-51 to bring the lower surface (diamond particles) of the dressing member 1-50a into sliding contact with the polishing surface 1-352a. In this manner, the polishing pad 1-352 is shaved off by the dresser 1-50, and the polishing surface 1-352a is dressed.

In the substrate polishing apparatus 1-1000 of the present embodiment, the amount of abrasion of the polishing pad 1-352 is measured by using the dresser 1-50. Specifically, the dressing device 1-356 includes a displacement sensor 1-60 that measures displacement of the dresser 1-50. The displacement sensor 1-60 constitutes an abrasion amount sensing mean that senses the amount of abrasion of the polishing pad 1-352 and is provided on the upper surface of the swing arm 1-55. A target plate 1-61 is fixed to the dresser shaft 1-51 so that the target plate 1-61 moves upward and downward together with upward and downward movement of the dresser 1-50. The displacement sensor 1-60 is disposed through the target plate 1-61 and measures displacement of the dresser 1-50 by measuring displacement of the target plate 1-61. Note that the displacement sensor 1-60 may be a sensor of any type such as a linear scale, a laser sensor, an ultrasonic wave sensor, or an eddy current sensor.

The amount of abrasion of the polishing pad 1-352 is measured as follows. First, the air cylinder 1-53 is driven to bring the dresser 1-50 into contact with the polishing surface 1-352a of the polishing pad 1-352 that is initially dressed. In this state, the displacement sensor 1-60 senses the initial position (height initial value) of the dresser 1-50 and stores the initial position (height initial value) in the control device 1-900. Then, after polishing processing of one or a plurality of substrates ends, the dresser 1-50 is again brought into contact with the polishing surface 1-352a, and the position of the dresser 1-50 is measured in this state. The position of the dresser 1-50 is displaced downward in accordance with the amount of abrasion of the polishing pad 1-352, and thus the control device 1-900 can determine the amount of abrasion of the polishing pad 1-352 by calculating the difference between the above-described initial position and the position of the dresser 1-50 after polishing. In this manner, the amount of abrasion of the polishing pad 1-352 is calculated based on the position of the dresser 1-50.

FIG. 11 is a cross-sectional view (9-9 section in FIG. 10) schematically illustrating the top ring 1-302. The top ring 1-302 includes a top ring body 1-2 that presses the substrate 1-WF against the polishing surface 1-352a, and the retainer member 1-3 that directly presses the polishing surface 1-352a. The top ring body 1-2 is made of a substantially rectangular flat plate member, and the retainer member 1-3 is attached to an outer peripheral part of the top ring body 1-2. The retainer member 1-3 may be a plate member. The top ring body 1-2 is formed of resin such as engineering plastic (for example, PEEK). An elastic film (membrane) 1-4 that contacts the back surface of the substrate is attached to the lower surface of the top ring body 1-2. The elastic film 1-4 may be formed of a rubber material with excellent strength and durability, such as ethylene propylene rubber (EPDM), polyurethane rubber, and silicon rubber. The elastic film 1-4 may be formed of a rubber material by using a mold.

A gas introduction chamber 1-6 is formed between the top ring body 1-2 and the elastic film 1-4. A flow path 1-12 communicates with the gas introduction chamber 1-6. The flow path 1-12 is connected to a pressure adjuster through a non-illustrated valve and pressure regulator. Pressure inside the gas introduction chamber 1-6 is adjustable by the pressure adjuster. The flow path 1-12 is connected to a vacuum source through a non-illustrated valve and can communicate with atmosphere through a non-illustrated valve. The top ring 1-302 may include a plurality of gas introduction chambers 1-6 and polish different parts of the substrate 1-WF under different pressures. The lower surface of the elastic film 1-4, on which the substrate 1-WF is disposed, is formed with a non-illustrated vacuum adsorption hole that is connected to a non-illustrated vacuum source and through which air is movable, and accordingly, the substrate 1-WF is vacuum-adsorbed.

At the top ring 1-302, the substrate 1-WF is held to the elastic film 1-4 by adsorption, and thus warping of the substrate 1-WF is corrected and front-surface reference polishing with reference to the surface (processing surface 1-PS) of the substrate 1-WF becomes possible. The top ring 1-302 may be, for example, a top ring disclosed in above-described Japanese Patent Laid-Open No. 2020-19115. Note that the top ring 1-302 may include a rigid adsorption plate and the substrate 1-WF may be vacuum-adsorbed to the adsorption plate and polished. In this case, the top ring 1-302 holds the back surface of the substrate 1-WF as flat, and thus, back-surface reference polishing with reference to the back surface of the substrate 1-WF is possible.

### Drying Module

In FIG. 1, the drying module 1-500 is a device for drying the substrate 1-WF. In the illustrated substrate polishing apparatus 1-1000, the drying module 1-500 dries the substrate 1-WF polished by the polishing module 1-400 and then cleaned by the cleaner of the second conveyer 1-200B. The drying module 1-500 is disposed on the downstream side of the second conveyer 1-200B.

The drying module 1-500 includes nozzles 1-530 for spraying gas toward the substrate 1-WF. The gas may be compressed air or nitrogen. In the drying module 1-500, the substrate 1-WF is conveyed by the conveyance rollers 1-202 attached to the roller shafts 1-204. During the conveyance, the gas is sprayed from the nozzles 1-530 toward the substrate 1-WF to dry the substrate 1-WF. The substrate 1-WF unloaded from the drying module 1-500 is loaded into the unloader 1-600. Note that the configuration of the drying module 1-500 is not particularly limited as long as the drying module 1-500 can dry the substrate 1-WF to a desired degree.

### Unloader

The unloader 1-600 is a device for unloading, from the substrate polishing apparatus 1-1000, the substrate 1-WF on which processing such as polishing and cleaning is performed. In the unloader 1-600, the substrate 1-WF is conveyed by the conveyance rollers 1-202 attached to the roller shafts 1-204. The unloader 1-600 may include a non-illustrated sensor and unload the substrate 1-WF out of the substrate polishing apparatus 1-1000 when having sensed the substrate 1-WF with the sensor. Note that the unloader 1-600 is not particularly limited to an aspect as long as the unloader 1-600 can unload the substrate 1-WF out of the substrate polishing apparatus 1-1000.

### Control Device

FIG. 12 is a conceptual diagram schematically illustrating the configuration of the control device 1-900. The control device 1-900 includes a communicator 1-910, an inputter 1-920, a storage 1-930, a display 1-940, and a processor 1-950. The processor 1-950 includes a conveyance controller 1-951, a measurement controller 1-952, the first grinding controller 1-953, the second grinding controller 1-954, a polishing controller 1-955, a display controller 1-956, and a memory 1-959.

The control device 1-900 includes an information processing device such as a typical computer or a dedicated computer, serves as an interface with a user as appropriate, and performs processing such as communication, storage, and calculation related to various kinds of data. Note that components of the control device 1-900 may be disposed in physically different devices. Moreover, at least part of data processed by the control device 1-900 may be stored in a remote server or the like.

The communicator 1-910 includes a communication device capable of communicating with at least the measurement device 1-750 through wireless or wired connection. The communicator 1-910 functions as a data acquirer that acquires the shape data from the measurement device 1-750.

The inputter 1-920 includes an input device such as a mouse, a keyboard, various buttons, or a touch panel. The inputter 1-920 receives inputs necessary for operation of the substrate polishing apparatus 1-1000 from a user.

The storage 1-930 includes a storage medium that is non-transitory or transitory. The storage 1-930 stores the shape data, first target data and second target data to be described later, and computer programs for the processor 1-950 to execute processing, and the like.

The display 1-940 includes a display device such as a liquid crystal monitor. The display 1-940 displays, for example, information obtained through processing by the processor 1-950.

The processor 1-950 includes a processing device including a processor such as a CPU. The processor 1-950 functions as a main entity for operation that controls the substrate polishing apparatus 1-1000. The processor 1-950 performs various kinds of processing by reading a computer program stored in the storage 1-930 or the like onto the memory 1-959 and executing the computer program. The computer program includes processing performed by the processor 1-950, which will be described below. The computer program may be acquired as that recorded in a recording medium such as a DVD-ROM or may be acquired through a network. Note that the physical configuration and the like of the processor 1-950 are not particularly limited as long as processing by the processor 1-950 is possible.

The conveyance controller 1-951 controls the loader 1-100 and the unloader 1-600 to load and unload the substrate 1-WF to and from the substrate polishing apparatus 1-1000. The conveyance controller 1-951 also controls the first conveyer 1-200A, the second conveyer 1-200B, and the like to control conveyance of the substrate 1-WF. The conveyance controller 1-951 controls the first conveyer 1-200A to move the substrate 1-WF to the grinding module 1-300 and move the substrate 1-WF subjected to the first grinding and the second grinding to the inverter 1-800. The conveyance controller 1-951 controls the inverter 1-800 to invert the substrate 1-WF. The conveyance controller 1-951 controls the second conveyer 1-200B to move the substrate 1-WF inverted by the inverter to a transfer position for the top ring 1-302 and move the substrate 1-WF polished by the polishing module 1-400 to the drying module 1-500.

The measurement controller 1-952 controls the measurement device 1-750 to measure the shape of the processing surface 1-PS. The measurement controller 1-952 transmits a signal that starts the shape measurement to the measurement device 1-750 based on inputting by the user of the substrate polishing apparatus 1-1000 (hereinafter simply referred to as the user) or a condition determined in advance. For example, when the substrate 1-WF is disposed on the table 1-73, the measurement controller 1-952 controls the measurement device 1-750 to perform the shape measurement before the first grinding is performed.

Note that the measurement controller 1-952 may perform the shape measurement before and after each of the first grinding, the second grinding, and polishing or while the first grinding or the second grinding is being performed. For example, the measurement controller 1-952 may perform the shape measurement before and after each process or all processes, thereby determining whether the processing surface 1-PS is fabricated in a desired shape. The result of the shape measurement or the result of the determination may be displayed on the display 1-940. In the display on the display 1-940, at least one of hue. saturation, and luminance may be illustrated differently based on height on the substrate 1-WF from a reference surface to facilitate understanding. In this case, hue, saturation, or luminance may be changed continuously or in stages based on threshold values as appropriate.

The first grinding controller 1-953 controls the grinding module 1-300 to perform the first grinding. In the following description, data indicating a shape targeted in the first grinding is referred to as first target data. The shape measurement performed before the first grinding is performed or while the first grinding is continuously or intermittently performed is referred to as first measurement. The shape data obtained by the first measurement is referred to as first shape data.

The first grinding controller 1-953 sets a range of the processing surface 1-PS where the first grinding is to be performed based on the first measurement. The first grinding controller 1-953 derives, from the first shape data and the first target data, a part of the processing surface 1-PS with a relatively large grinding amount necessary for achieving the processing surface 1-PS in the shape targeted in the first grinding. In the following description, this part of the processing surface 1-PS is referred to as a first part. The first part is, for example, the convex parts 1-WF1 and 1-WF2 in FIG. 8. For example, in the first shape data and the first target data, the height of the processing surface 1-PS from each position on the reference surface is described with three-dimensional coordinates. The first grinding controller 1-953 can calculate a necessary grinding amount based on the difference between the height in the first shape data and the height in the first target data at each position on the reference surface. The first grinding controller 1-953 can include, in the first part, any point where the difference is larger than a predetermined threshold value. The first grinding controller 1-953 sets a range of the processing surface 1-PS where the first grinding is to be performed and in which the first part is included. The first grinding controller 1-953 controls the grinding module 1-300 to perform the first grinding so that the range is ground. For example, the first grinding controller 1-953 controls the first arm 1-71 and the table drive mechanism 1-730 so that the first grinding member 1-GI passes through the range when the first arm 1-71 swings. Note that as long as parts targeted in the first grinding can be set, algorithms for this, the format of data used, and the like are not particularly limited.

The second grinding controller 1-954 controls the grinding module 1-300 to perform the second grinding. From the perspective of efficiently fabricating a part that is not ground in the first grinding, the second grinding controller 1-954 preferably controls the grinding module 1-300 to perform the entire surface grinding on the processing surface 1-PS but is not limited thereto. In the following description, data indicating a shape targeted in the second grinding is referred to as second target data. The shape measurement performed while the second grinding is continuously or intermittently performed is referred to as second measurement. The shape data obtained by the second measurement is referred to as second shape data.

The second grinding controller 1-954 functions as a determiner that determines whether to end the second grinding based on the second measurement. The second grinding controller 1-954 calculates, from the second shape data and the second target data, similarity between the shape of the processing surface 1-PS and the shape targeted in the second grinding. The second grinding controller 1-954 determines to end the second grinding in a case where the similarity is equal to or smaller than a predetermined threshold value, or determines not to end the second grinding otherwise. The method of similarity calculation is not particularly limited. For example, in the second shape data and the second target data, the height of the processing surface 1-PS from each position on the reference surface is described with three-dimensional coordinates. The second grinding controller 1-954 can calculate the similarity based on the minimum value of the difference between the height in the second shape data and the height in the second target data at each position on the reference surface. Note that as long as whether to end the second grinding can be determined in accordance with standards required for the substrate 1-WF, algorithms for this, the format of data used, and the like are not particularly limited.

The polishing controller 1-955 controls the polishing module 1-400 to perform polishing. The polishing controller 1-955 preferably performs the entire surface polishing on the substrate 1-WF.

The display controller 1-956 controls the display 1-940 to display information of the substrate polishing apparatus 1-1000 on the display device. The display controller 1-956 may display, for example, information indicating the progress of polishing by the substrate polishing apparatus 1-1000 or the result of the shape measurement.

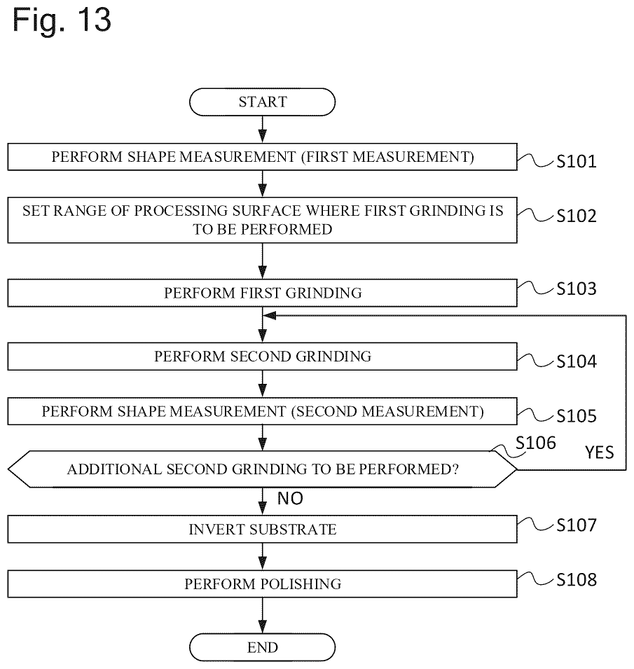

FIG. 13 is a flowchart illustrating the process of the substrate polishing method according to the present embodiment. The substrate polishing method is performed by the control device 1-900. Step S101 is performed after the conveyance controller 1-951 controls the loader 1-100 to load the substrate 1-WF into the substrate polishing apparatus 1-1000 and controls the first conveyer 1-200A to dispose the substrate 1-WF onto the table 1-73 of the grinding module 1-300.

At step S101, the measurement controller 1-952 controls the measurement device 1-750 to perform the shape measurement (first measurement). After step S101, step S102 is performed. At step S102, the first grinding controller 1-953 sets a range of the processing surface 1-PS where the first grinding is to be performed. The first grinding controller 1-953 performs the setting based on the first shape data obtained at step S101. After step S102, step S103 is performed.

At step S103, the first grinding controller 1-953 controls the grinding module 1-300 to perform the first grinding. Once step S103 is performed, step S104 is performed. At step S104, the second grinding controller 1-954 controls the grinding module 1-300 to perform the second grinding. After step S104, step S105 is performed.

At step S105, the measurement controller 1-952 controls the measurement device 1-750 to perform the shape measurement (second measurement). The shape measurement at step S105 may be performed after the second grinding at step S104 is stopped, or may be performed simultaneously in parallel with the second grinding at step S104. After step S105, step S106 is performed. At step S106, the second grinding controller 1-954 determines whether to additionally perform the second grinding. In a case where the second grinding is to be additionally performed, positive determination is made at step S106 and the processing returns to step S104. In a case where the second grinding is not to be performed, negative determination is made at step S106 and step S107 is performed.

At step S107, the conveyance controller 1-951 controls the inverter 1-800 to invert the substrate 1-WF. After step S107, step S108 is performed. At step S108, the polishing controller 1-955 controls the polishing module 1-400 to perform polishing. After the polishing, the substrate 1-WF is cleaned and dried as appropriate and unloaded from the substrate polishing apparatus 1-1000 by the conveyance controller 1-951. After step S108, the processing is ended.

The substrate polishing method according to the present embodiment includes performing the first grinding on part of the processing surface 1-PS by the first grinding member 1-G1, performing the second grinding on the processing surface 1-PS by the second grinding member 1-G2 with a maximum diameter larger than that of the first grinding member 1-G1, and performing polishing by the polishing member 1-PM on the processing surface 1-PS on which the first grinding and the second grinding have been performed. Accordingly, with the first grinding that is local and the second grinding with a range wider than that of the first grinding, the processing surface 1-PS can be ground at high speed in a shorter time while substrate thickness variance is suppressed, and thereafter, the processing surface 1-PS with high precision can be formed by polishing. Thus, the substrate 1-WF with high precision can be provided through efficient processing.

In the substrate polishing apparatus 1-1000 according to the present embodiment, the second grinding controller 1-954 performs the second grinding after the first grinding. Accordingly, since the second grinding with a wider range is performed after convex parts are ground by the first grinding that is local, it is possible to efficiently perform grinding in a wide range of the processing surface 1-PS and establish polishing conditions that polishing can be performed at high accuracy.

The substrate polishing apparatus 1-1000 according to the present embodiment includes the measurement device 1-750 that measures the shape of the processing surface 1-PS. Accordingly, processing is performed by using information of the shape of the processing surface 1-PS, and thus it is possible to further reliably provide the substrate 1-WF with high precision through efficient processing.

In the substrate polishing apparatus 1-1000 according to the present embodiment, the measurement controller 1-952 performs the first measurement of the shape of the processing surface 1-PS before the first grinding. Accordingly, it is possible to perform further efficient processing by appropriately setting parts targeted in the first grinding in advance.

In the substrate polishing apparatus 1-1000 according to the present embodiment, the first grinding controller 1-953 sets part of the processing surface 1-PS where the first grinding is to be performed based on the first measurement. Accordingly, it is possible to appropriately set a target to be locally ground, thereby more efficiently providing the substrate 1-WF with higher precision.

In the substrate polishing apparatus 1-1000 according to the present embodiment, the measurement controller 1-952 performs the second measurement of the shape of the processing surface 1-PS in the second grinding, and the second grinding controller 1-954 determines whether to end the second grinding based on the second measurement. Accordingly, it is possible to perform the second grinding while checking whether polishing conditions are established, thereby more efficiently providing the substrate with higher precision.

In the substrate polishing apparatus 1-1000 according to the present embodiment, the second grinding controller 1-954 determines whether to perform the second grinding based on the second shape data indicating the shape of the processing surface 1-PS obtained by the second measurement and the second target data indicating a shape targeted in the second grinding. Accordingly, it is possible to more accurately determine whether to perform the second grinding.

In the substrate polishing apparatus 1-1000 according to the present embodiment, the processing surface 1-PS is entirely ground in the second grinding. Accordingly, since the entire surface grinding is performed after the partial grinding, it is possible to efficiently perform grinding on the entire processing surface 1-PS and establish polishing conditions that polishing can be performed at high accuracy.

In the substrate polishing apparatus 1-1000 according to the present embodiment, the maximum diameter 1-L2 of the second grinding member 1-G2 is smaller than the maximum diameter 1-L3 of the processing surface 1-PS. Accordingly, the grinding module 1-300 can be compactly configured.

In the substrate polishing apparatus 1-1000 according to the present embodiment, the first grinding member 1-G1 and the second grinding member 1-G2 are grinding members of the same kind. Accordingly, it is possible to prevent complication of the configuration of the grinding module 1-300 as appropriate and efficiently perform processing by omitting conveyance work.

In the substrate polishing apparatus 1-1000 according to the present embodiment, the first grinding member 1-G1 and the second grinding member 1-G2 are polishing tapes. Accordingly, the partial grinding can be accurately performed and the grinding module 1-300 can be more compactly configured.

Modifications as follows are included in the range of the present invention and may be combined with the above-described embodiment or other modifications. In the modifications below, parts or the like having the same structures or functions as in the above-described embodiment are denoted by the same reference signs and description thereof is omitted as appropriate.

### Modification 1-1

In the above-described embodiment, the first measurement may be performed while the first grinding is continuously or intermittently performed. The measurement controller 1-952 controls the measurement device 1-750 to perform shape measurement of the processing surface 1-PS while the first grinding is being performed. Accordingly, based on information obtained by the shape measurement, it is possible to more efficiently perform the first grinding and perform the second grinding under favorable conditions.

The first grinding controller 1-953 functions as a determiner that determines whether to end the first grinding based on the first measurement. The first grinding controller 1-953 calculates, from the first shape data and the first target data, the similarity between the shape of the processing surface 1-PS and a shape targeted in the first grinding. The first grinding controller 1-953 determines to end the first grinding in a case where the similarity is equal to or smaller than a predetermined threshold value, or determines not to end the first grinding otherwise. The method of similarity calculation is not particularly limited. For example, as described above, in the first shape data and the first target data, the height of the processing surface 1-PS from each position on the reference surface is described with three-dimensional coordinates. The first grinding controller 1-953 can calculate the similarity based on the minimum value of the difference between the height in the first shape data and the height in the first target data at parts of the processing surface 1-PS targeted in the first grinding. Note that as long as whether to end the first grinding can be determined in accordance with standards required for the substrate 1-WF, algorithms for this, the format of data used, and the like are not particularly limited.

In the substrate polishing apparatus 1-1000 of the present modification, the first grinding controller 1-953 determines whether to perform the first grinding based on the first shape data indicating the shape of the processing surface 1-PS obtained by the first measurement and the first target data indicating the shape targeted in the first grinding. Accordingly, it is possible to more accurately determine whether to perform the first grinding.

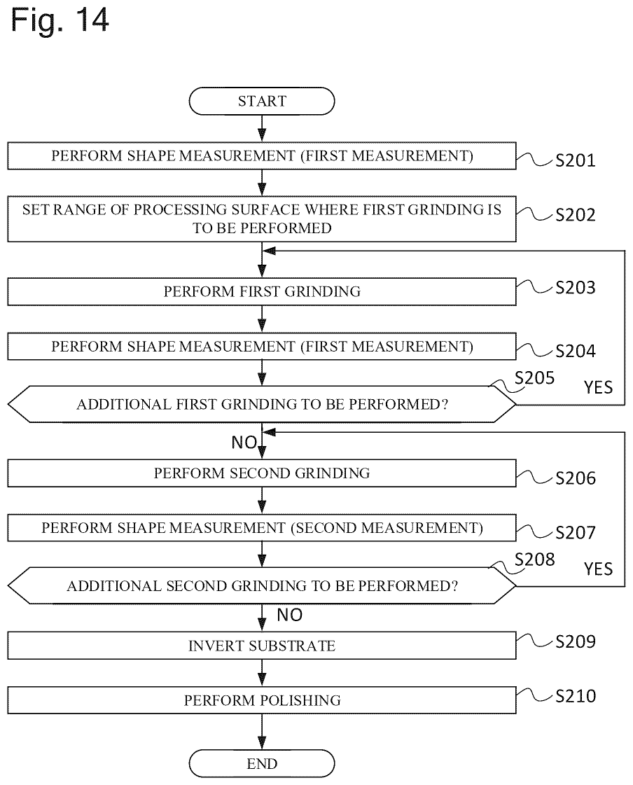

FIG. 14 is a flowchart illustrating the process of a substrate polishing method according to the present modification. The substrate polishing method is performed by the control device 1-900. Steps S201 to S203 are the same as steps S101 to S103 in the flowchart of FIG. 13, and thus description thereof is omitted. After step S203, step S204 is performed.

At step S204, the measurement controller 1-952 controls the measurement device 1-750 to perform the shape measurement (first measurement). The shape measurement at step S204 may be performed after the first grinding at step S203 is stopped, or may be performing simultaneously in parallel with the first grinding at step S203. After step S204, step S205 is performed. At step S205, the first grinding controller 1-953 determines whether to additionally perform the first grinding. In a case where the first grinding is to be additionally performed, positive determination is made at step S205 and the processing returns to step S203. In a case where the first grinding is not to be performed, negative determination is made at step S205 and step S206 is performed.

Steps S206 to S210 are the same as steps S104 to S108 in the flowchart of FIG. 13, and thus description thereof is omitted. After step S210, the processing is ended.

### Modification 1-2

In the above-described embodiment, the control device 1-900 may perform the first grinding and the second grinding simultaneously in parallel or alternately in repetition. In a case where the first grinding and the second grinding are performed simultaneously in parallel, the first grinding controller 1-953 and the second grinding controller 1-954 control the first arm 1-71, the first head 1-710, the second arm 1-72, and the second head 1-720 to avoid contact between the arms or the heads.

After having controlled the measurement device 1-750 to perform the shape measurement, the measurement controller 1-952 may set whether to perform the first grinding and the second grinding. The measurement controller 1-952 may perform the above-described setting based on the shape data indicating the shape of the processing surface obtained by the shape measurement and target data indicating the shape of the processing surface 1-PS targeted in grinding or polishing. In the shape data and the target data, the height of the processing surface 1-PS from each position on the reference surface is described with three-dimensional coordinates. For example, the measurement controller 1-952 may determine a convex part based on difference in the height of the processing surface 1-PS between the shape data and the target data, perform the second grinding in a case where the area of the convex part is equal to or larger than a predetermined threshold value, and perform the first grinding in a case where the area is smaller than the threshold value. In this manner, since the control device 1-900 performs either of the first grinding and the second grinding based on the first measurement, it is possible to perform grinding by, among the first grinding and the second grinding, a method that is efficient in accordance with the shape of the processing surface 1-PS, and thus it is possible to provide the substrate 1-WF that is more efficiently polished.

The measurement controller 1-952 may set whether simultaneously perform the first grinding and the second grinding. For example, in a case where a part requiring the first grinding exists at the center of the substrate 1-WF in the shape data, the measurement controller 1-952 may set not to simultaneously perform the first grinding and the second grinding because contact would be likely to occur if the first grinding and the second grinding are simultaneously performed. In this manner, from the perspective of efficiently performing grinding, the measurement controller 1-952 may set whether to simultaneously perform the first grinding and the second grinding based on the shape measurement.

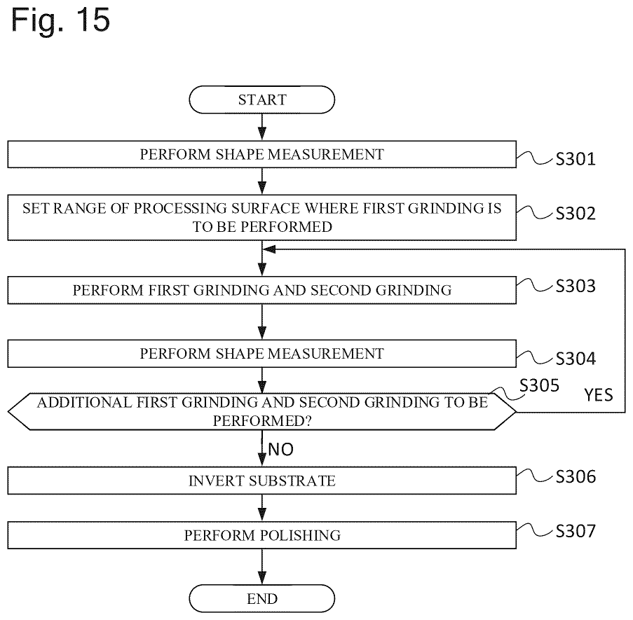

FIG. 15 is a flowchart illustrating the substrate polishing method of the present modification. The substrate polishing method is performed by the control device 1-900. Steps S301 and S302 are the same as steps S101 and S102, respectively, in the flowchart of FIG. 13, and thus description thereof is omitted. After step S302, step S303 is performed.

At step S303, the first grinding controller 1-953 and the second grinding controller 1-954 perform the first grinding and the second grinding. The first grinding and the second grinding may be repeated an optional number of times in an optional order and may be simultaneously performed. After step S303, step S304 is performed. At step S304, the measurement controller 1-952 controls the measurement device 1-750 to perform shape measurement of the processing surface 1-PS. The measurement controller 1-952 may perform the shape measurement at an optional timing. After step S304, step S305 is performed.

At step S305, the measurement controller 1-952 determines whether to additionally perform the first grinding and the second grinding. In a case where the first grinding and the second grinding are to be performed, positive determination is made at step S305 and the processing returns to step S303. In a case where the first grinding and the second grinding are not to be performed, negative determination is made at step S305 and step S306 is performed. Note that, in a case where grinding is performed again, the measurement controller 1-952 may set whether to perform the first grinding or the second grinding or simultaneously perform both. Based on the setting, at least one of the first grinding and the second grinding is performed.

Steps S306 and S307 are the same as steps S107 and S108, respectively, and thus description thereof is omitted. After step S307, the processing is ended.

### Modification 1-3

In the above-described embodiment, plate thickness at each position on the processing surface 1-PS may be measured by a measurement device, the shape of the processing surface 1-PS may be expressed with the plate thickness, and the shape of the processing surface 1-PS may be analyzed based on the plate thickness.

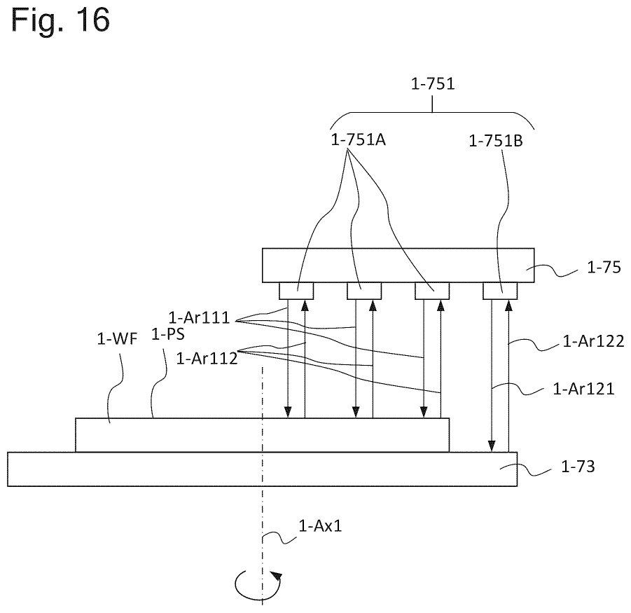

FIG. 16 is a conceptual diagram for description of a measurement device 1-751 according to the present modification. The measurement device 1-751 includes a plurality of first detection heads 1-751A and a second detection head 1-751B. The first detection heads 1-751A and the second detection head 1-751B are installed on the third arm 1-75 extending in the radial direction of rotation of the rotational axis 1-Ax1 of the table 1-73. The plurality of first detection heads 1-751A are disposed alongside in the radial direction and each configured to be able to perform detection at optional positions on the circumference as the table 1-73 rotates.

Each first detection head 1-751A emits light to a detection position corresponding to the first detection bead 1-751 on the processing surface 1-PS (arrow 1-Ar111) and receives reflected light from the processing surface 1-PS (arrow 1-Ar112). The second detection head 1-751B emits light to the table 1-73 (arrow 1-Ar121) and receives reflected light from the table 1-73 (arrow 1-Ar122). The measurement device 1-751 or the measurement controller 1-952 calculates plate thickness at each detection position by analyzing data obtained through the light reception by each first detection head 1-751A and data obtained through the light reception by the second detection head 1-751B. For example, the first detection heads 1-751A and the second detection head 1-751B may be laser displacement sensors and may calculate plate thickness at each detection position by subtracting the distance between each first detection head 1-751A and each detection position from the distance between the second detection head 1-751B and the table 1-73. Alternatively, the first detection heads 1-751A and the second detection head 1-751B may be charge coupled device (CCD) image sensors or complementary metal-oxide-semiconductor (CMOS) image sensors and may perform distance measurement by exploiting image capturing.

In the substrate polishing apparatus 1-1000 according to the present modification, the measurement device 1-751 emits light to the processing surface 1-PS, and the measurement device 1-751 or the measurement controller 1-952 calculates thickness distribution of the substrate 1-WF based on analysis of measurement data obtained by receiving light from the substrate 1-WF based on the above light. Accordingly, the shape of the processing surface 1-PS can be accurately measured with reference to plate thickness.

### Modification 1-4

In the above-described embodiment, the polishing tapes 1-T1A and 1-T1B are fed by two tape feeding mechanisms, respectively, in the first head 1-710. However, one polishing tape may be fed by one tape feeding mechanism and supplied to a plurality of places on a pad surface.

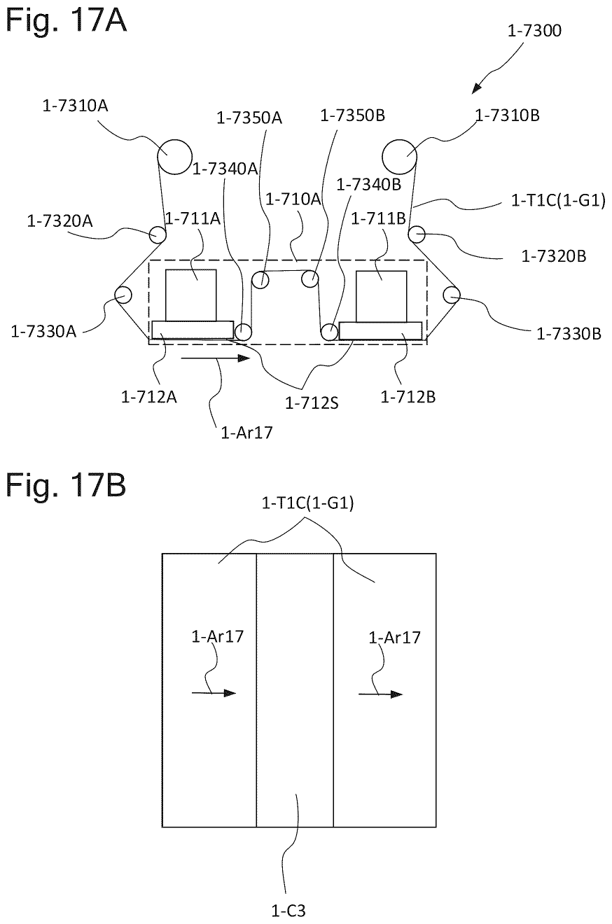

FIG. 17A is a side view schematically illustrating a first head 1-710A of the present modification, and FIG. 17B is a bottom view schematically illustrating disposition of a polishing tape 1-T1C on first pad surfaces 1-712S of the first head 1-710A. The first head 1-710A includes first pressing mechanisms 1-711A and 1-711B, and first pressing pads 1-712A and 1-712B that are pressed by the first pressing mechanisms 1-711A and 1-711B, respectively. At the first pressing pads 1-712A and 1-712B, the polishing tape 1-T1C is slidably disposed along the first pad surfaces 1-712S (arrow 1-Ar17). The polishing tape 1-T1C is the first grinding member 1-G1 that grinds in contact with the processing surface in the first grinding.

The polishing tape 1-T1C is fed by a first tape feeding mechanism 1-7300 and slides on the first pressing pads 1-712A and 1-712B. The first tape feeding mechanism 1-7300 includes an unwind reel 1-7310A, support rods 1-7320A, 1-7330A, 1-7340A, 1-7350A, 1-7350B, 1-7340B, 1-7330B, and 1-7320B, and a wind reel 1-7310B. The unwind reel 1-7310A and the wind reel 1-7310B have cylindrical shapes with cylindrical surfaces around which the polishing tape 1-T1C is wound. The unwind reel 1-7310A and the wind reel 1-7310B are configured to be able to rotate about their cylindrical axes to unwind and wind, respectively, the polishing tape 1-T1C. The support rods 1-7320A, 1-7330A, 1-7340A, 1-7350A, 1-7350B, 1-7340B, 1-7330B, and 1-7320B are fixed to the first head 1-710A or the first arm 1-71 and support the polishing tape 1-T1C, and define a movement path for the polishing tape 1-T1C.

In the present modification, the support rods 1-7350A and 1-7350B are disposed from the first pad surfaces 1-712S in a direction perpendicular to the first pad surfaces 1-712S and departing from the substrate 1-WF. Accordingly, the polishing tape 1-T1C slides on the first pad surface 1-712S facing the first pressing pad 1-712A and then temporarily separates from the first pad surface 1-712S, and thereafter, slides on the first pad surface 1-712S facing the first pressing pad 1-712B. As illustrated in FIG. 17B, a gap 1-C3 is formed between the first pressing mechanism 1-711A and the first pressing mechanism 1-711B and between the first pressing pad 1-712A and the first pressing pad 1-712B. In the present modification, the polishing tape 1-T1C passes through the gap 1-C3.

With the tape feeding mechanism 1-7300 according to the present modification, a polishing tape can be disposed at a plurality of desired positions on the first pad surfaces 1-712S without necessity for increasing the number of tape feeding mechanisms. Thus, the aspect of polishing can be more flexibly adjusted. Note that the tape feeding mechanism according to the present modification may be applied to the second head.

### Second Embodiment

A substrate polishing apparatus 1-1001 of the second embodiment is different from the substrate polishing apparatus 1-1000 of the first embodiment in that, for example, a grinding module 1-300A is included in place of the grinding module 1-300 in the above-described first embodiment. The substrate polishing apparatus 1-1001 needs no inverter.

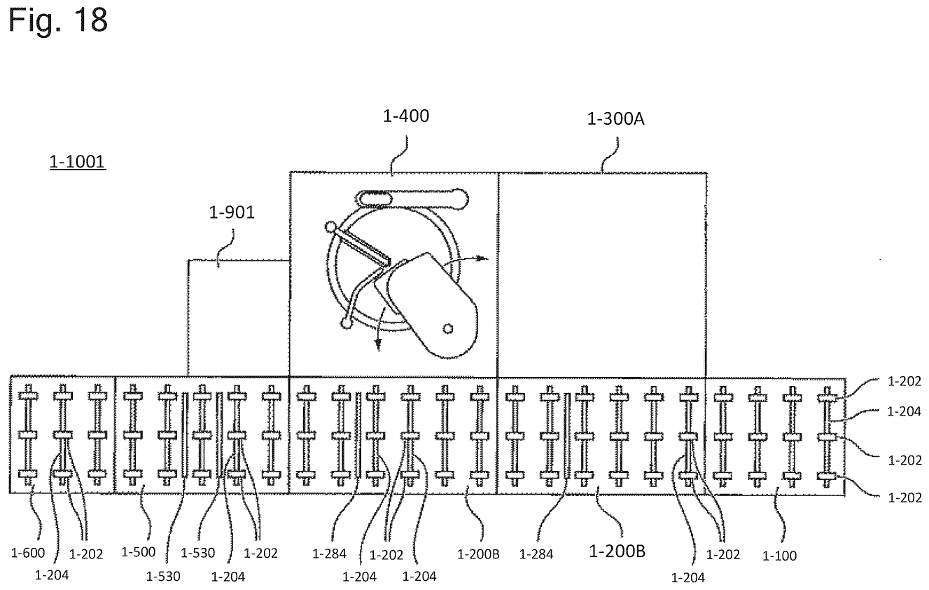

FIG. 18 is a conceptual diagram schematically illustrating the configuration of the substrate polishing apparatus 1-1001 of the second embodiment. The substrate polishing apparatus 1-1001 includes a loader 1-100, two second conveyers 1-200B, the grinding module 1-300A, a polishing module 1-400, a drying module 1-500, an unloader 1-600, and a control device 1-901. The loader 1-100, the second conveyers 1-200B, the polishing module 1-400, the drying module 1-500, and the unloader 1-600 are the same as in the above-described embodiment, and thus description thereof is omitted.

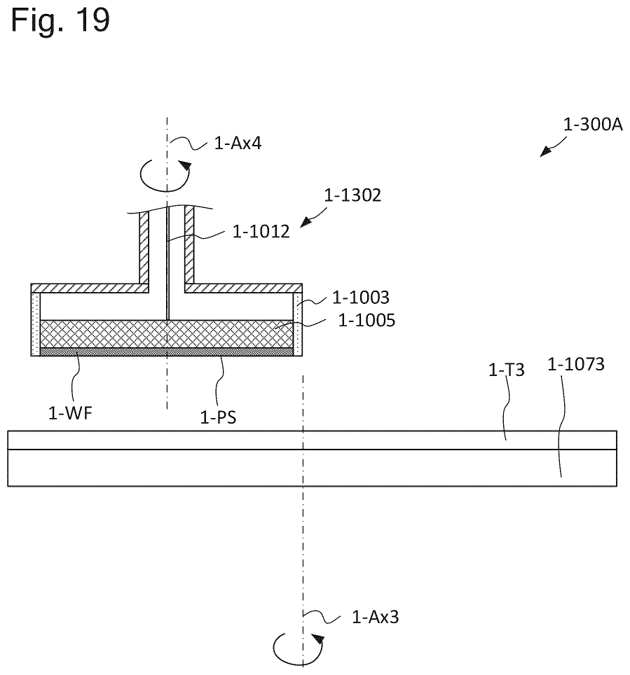

FIG. 19 is a conceptual diagram schematically illustrating the configuration of the grinding module 1-300A. The grinding module 1-300A includes a top ring 1-1302 and a table 1-1073. The table 1-1073 is configured to be rotatable about a rotational axis 1-Ax3 when driven by a non-illustrated table drive mechanism. A polishing tape 1-T3 as a grinding member is disposed on the upper surface of the table 1-1073. The polishing tape 1-T3 is movable by a non-illustrated tape feeding mechanism. The top ring 1-1302 includes a retainer member 1-1003 and an adsorption plate 1-1005 with stiffness. The lower surface of the adsorption plate 1-1005 is provided with a non-illustrated vacuum adsorption hole communicating with a flow path 1-1012 that is connected to a non-illustrated vacuum source and through which air is movable, and accordingly, the substrate 1-WF can be vacuum-adsorbed. The top ring 1-1302 is rotatable about a rotational axis 1-Ax4 as the central axis. With the top ring 1-1302, grinding is performed by a face-down scheme in which the processing surface 1-PS of the substrate 1-WF faces downward in the vertical direction.

The material of the polishing tape as a grinding member is not particularly limited. From the perspective of performing fabrication at higher speed more efficiently than polishing with the polishing module 1-400 or from the perspective of performing rough cutting at high speed, the grinding member of the grinding module 1-300A preferably contains a material with a higher stiffness or clastic modulus than the polishing member of the polishing module 1-400. For example, the grinding member may be a polishing tape formed by disposing abrasive particles made of the above-described material on a base member. In this case, to prevent fall of the abrasive particles, the surfaces of the abrasive particles may be coated with resin or the abrasive particles may be attached to the base member by electrodeposition. Note that the material of the base member is, for example, at least one or combination of polyimide, rubber, PET, resin materials, composite materials impregnated with fibers in these materials, and metal foils. Note that the grinding member may be fixed abrasive particles instead of a polishing tape, and in this case, a fixed abrasive lapping plate may be installed in place of the table 1-1073 in the grinding module 1-300A.

The control device 1-901 may be a typical computer or dedicated computer including an input-output device, an arithmetic device, and a storage device. The control device 1-901 controls operation of each component of the substrate polishing apparatus 1-1001. The control device 1-901 controls the grinding module 1-300A to adsorb the substrate 1-WF to the top ring 1-1302 at the second conveyer 1-200B on the upstream side and then move the top ring 1-1302 to above the table 1-1073. The control device 1-901 controls the grinding module 1-300A to bring the processing surface 1-PS of the substrate 1-WF adsorbed to the lower surface of the top ring 1-1302 into contact with the surface of the polishing tape 1-T3 while rotating the table 1-1073 and the top ring 1-1302, thereby grinding the substrate 1-WF.

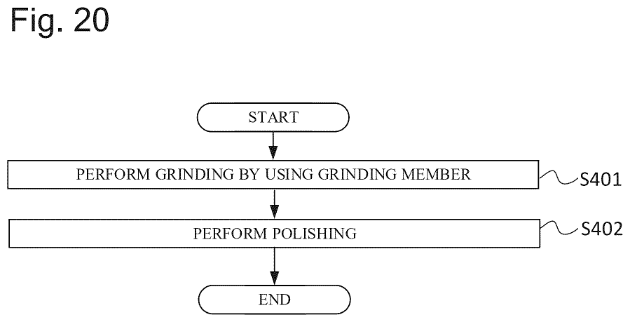

FIG. 20 is a flowchart illustrating the process of a substrate polishing method of the present embodiment. Under control by the control device 1-901, the substrate 1-WF is loaded into the loader 1-100 and then conveyed to the substrate transfer position of the second conveyer 1-200B on the upstream side. Thereafter, at step S401, the control device 1-901 controls the grinding module 1-300A to perform grinding by using the grinding member (polishing tape). After step S401, step S402 is performed. At step S402, after the substrate 1-WF is conveyed to the substrate transfer position of the second conveyer on the downstream side, the control device 1-901 controls the polishing module 1-400 to polish the substrate 1-WF. After the polishing, the substrate 1-WF is dried and cleaned as appropriate and unloaded from the substrate polishing apparatus 1-1001. After step S402, the processing is ended. Note that, in the polishing module 1-400, the substrate 1-WF may be vacuum-adsorbed to a rigid adsorption plate and back-surface reference polishing may be performed.

Modifications as follows are included in the range of the present invention and may be combined with the above-described embodiment or other modifications. In the modifications below, parts or the like having the same structures or functions as in the above-described embodiment are denoted by the same reference signs and description thereof is omitted as appropriate.

### Modification 2-1

In the above-described embodiment, one top ring may be shared between the grinding module 1-300A and the polishing module 1-400.

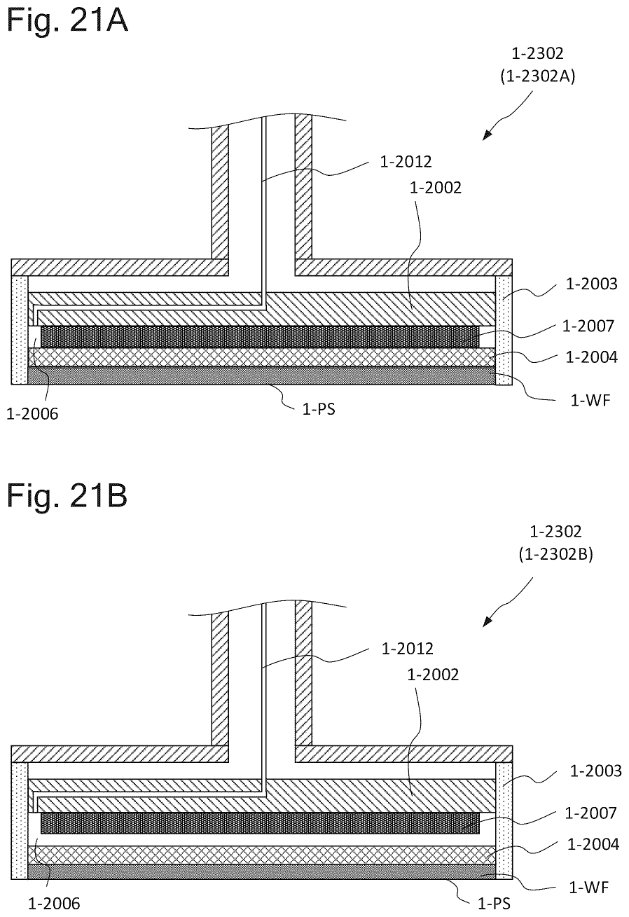

FIG. 21A is a conceptual diagram schematically illustrating a top ring 1-2302 according to the present modification when grinding is performed in the grinding module 1-300A. The top ring 1-2302 includes a top ring body 1-2002, a retainer member 1-2003, an elastic film (membrane) 1-2004, and a rigid body plate 1-2007. The lower surface of the elastic film 1-2004 is formed with a non-illustrated vacuum adsorption hole communicating with a vacuum source, and accordingly, the substrate 1-WF can be vacuum-adsorbed. A gas introduction chamber 1-2006 communicating with a flow path 1-2012 connected to a pressure adjuster is formed between the top ring body 1-2002 and the elastic film 1-2004. When grinding is performed in the grinding module 1-300A, the pressure of the gas introduction chamber 1-2006 is controlled to be sufficiently low to achieve a state in which the rigid body plate 1-2007 presses the elastic film 1-2004. Thus, back-surface reference polishing is possible by the shape of the rigid body plate 1-2007 pressing the substrate 1-WF from the back surface. The top ring 1-2302 in this state is referred to with reference sign 1-2302A as appropriate.

FIG. 21B is a conceptual diagram schematically illustrating the top ring 1-2302 according to the present modification when polishing is performed in the polishing module 1-400. In this case, gas is introduced into the gas introduction chamber 1-2006, and the pressure of the gas achieves a state in which the rigid body plate 1-2007 does not sufficiently press the elastic film 1-2004. Accordingly, the substrate 1-WF is held to the elastic film 1-2004 by adsorption, and thus warping of the substrate 1-WF is corrected and front-surface reference polishing with reference to the surface (processing surface 1-PS) of the substrate 1-WF becomes possible. The top ring 1-2302 in this state is referred to with reference sign 1-2302B as appropriate.

In the substrate polishing apparatus 1-1001 and the substrate polishing method according to the present modification, the control device 1-901 performs back-surface reference grinding in the grinding module 1-300A and front-surface reference polishing in the polishing module 1-400 without necessity for desorption of the substrate 1-WF from the top ring 1-2302. Accordingly, it is possible to perform polishing such as CMP, which prefers front-surface reference, after performing back-surface reference grinding for preventing substrate thickness variance (TTV). Thus, it is possible to provide the substrate 1-WF with high precision by performing further efficient processing.

### Modification 2-2

In Modification 2-1 described above, grinding and polishing may be performed on one table.

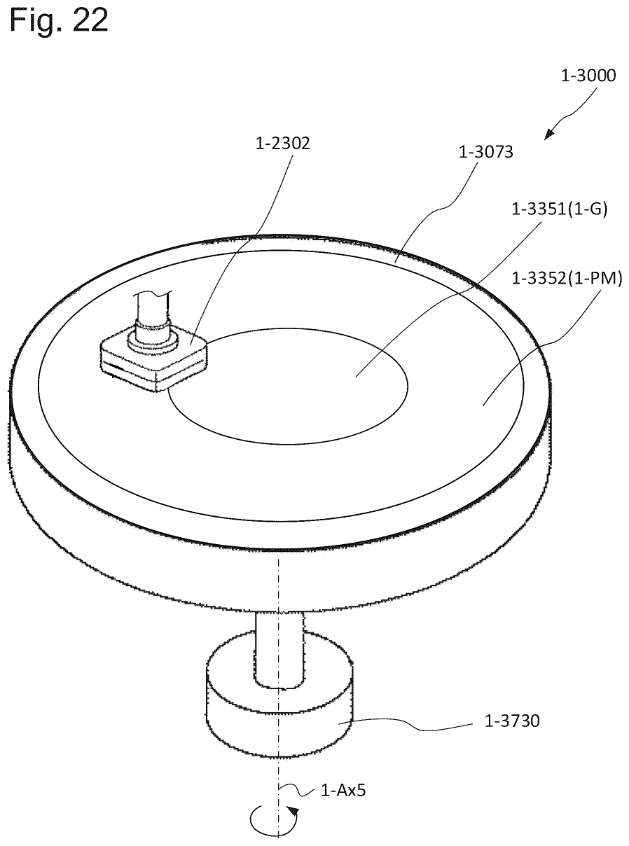

FIG. 22 is a perspective view schematically illustrating a grinding-polishing module 1-3000 of the present modification. The grinding-polishing module 1-3000 includes a table 1-3073, a table drive mechanism 1-3730, a fixed abrasive lapping plate 1-3351 as a grinding member 1-G, a polishing pad 1-3352 as the polishing member 1-PM, and the above-described top ring 1-2302.

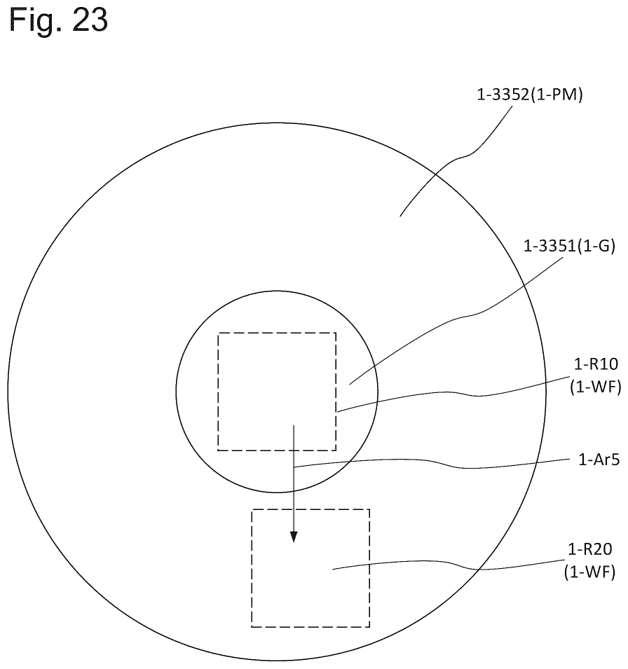

FIG. 23 is a top view schematically illustrating disposition of the fixed abrasive lapping plate 1-3351 and the polishing pad 1-3352. The fixed abrasive lapping plate 1-3351 with a circular shape centered at a rotational axis 1-Ax5 of the table 1-3073 is disposed on the table 1-3073, and a polishing member 1-3352 with a circular annular shape is disposed around a grinding member 1-3351. A polishing tape may be used in place of the fixed abrasive lapping plate 1-3351 as a grinding member. Note that the grinding member 1-G with a circular annular shape may be disposed around the polishing member 1-PM with a circular shape. A quadrilateral 1-R10 illustrates the position of the substrate 1-WF at grinding, and a quadrilateral 1-R20 illustrates the position of the substrate 1-WF at polishing. The control device 1-901 moves the top ring 1-2302 along the table 1-3073 (arrow 1-Ar5) and performs grinding on the fixed abrasive lapping plate 1-3351 and polishing on the polishing pad 1-3352.

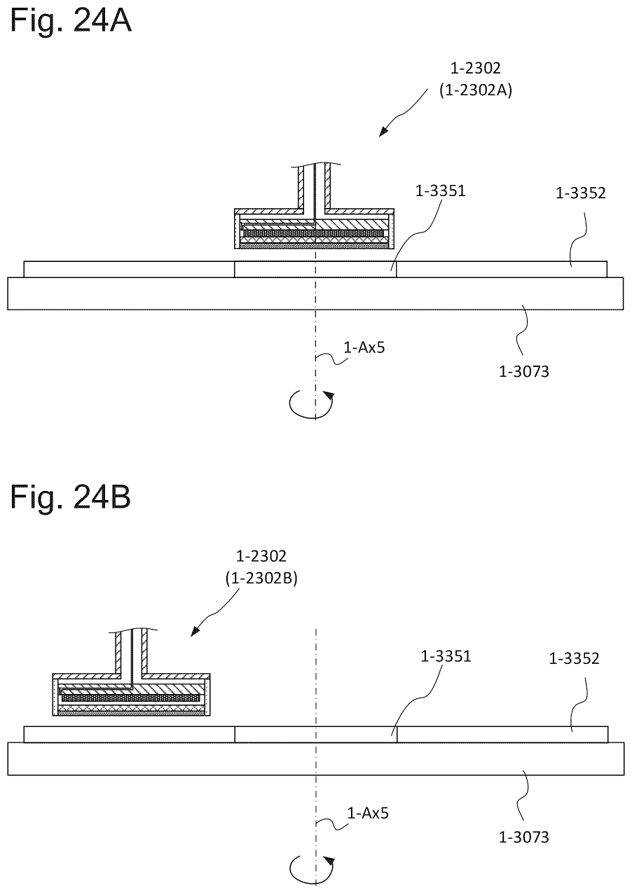

FIG. 24A is a diagram schematically illustrating grinding on the fixed abrasive lapping plate 1-3351. The control device 1-901 sufficiently lowers the pressure of the gas introduction chamber 1-2006 (FIG. 21A) of the top ring 1-2302 to achieve a state (top ring 1-2302A) in which back-surface reference polishing is possible, brings the substrate 1-WF held to the top ring 1-2302 by adsorption into contact with the fixed abrasive lapping plate 1-3351, and performs grinding. During the grinding, the top ring 1-2302 is swung as appropriate.

FIG. 24B is a diagram schematically illustrating polishing on the polishing pad 1-3352. The control device 1-901 introduces gas into the gas introduction chamber 1-2006 of the top ring 1-2302 to achieve a state (top ring 1-2302B) in which front-surface reference polishing is possible, brings the substrate 1-WF held to the top ring 1-2302 by adsorption into contact with the polishing pad 1-3352, and performs polishing. During the polishing, the top ring 1-2302 is swung as appropriate.

In the substrate polishing apparatus 1-1001 of the present modification, the control device 1-901 performs back-surface reference grinding using the grinding member 1-G and front-surface reference polishing using the polishing member 1-PM without necessity for desorption of the substrate 1-WF from the top ring 1-2302 nor movement from above the table 1-3073. Accordingly, it is possible to provide a compact substrate polishing apparatus that can perform polishing such as CMP, which prefers front-surface reference after performing back-surface reference grinding.

The present embodiment described above can be written in Aspects below.

[Aspect 1-1] According to Aspect 1-1, a substrate polishing apparatus configured to perform polishing processing on a processing surface of a substrate is disclosed, the substrate polishing apparatus includes: a grinding module in which a first grinding member and a second grinding member with a maximum diameter larger than a maximum diameter of the first grinding member are disposed; a polishing module including a polishing member; and a control device configured to control the grinding module and the polishing module, and the control device controls the grinding module to perform first grinding on part of the processing surface by the first grinding member and second grinding on the processing surface by the second grinding member and controls the polishing module to perform polishing on the processing surface on which the first grinding and the second grinding are performed. According to Aspect 1-1, it is possible to provide a substrate with high precision through efficient processing.

[Aspect 1-2] According to Aspect 1-2, in Aspect 1-1, the control device performs the second grinding simultaneously with or after the first grinding. According to Aspect 1-2, since the first grinding that is local is performed to grind convex parts and the second grinding with a range wider is performed, it is possible to efficiently perform grinding in a wide range of the processing surface and establish polishing conditions that polishing can be performed at high accuracy.

[Aspect 1-3] According to Aspect 1-3, in Aspect 1-1 or Aspect 1-2, the substrate polishing apparatus further includes a measurement device configured to perform measurement of the shape of the processing surface. According to Aspect 1-3, since processing is performed by using information of the shape of the processing surface, it is possible to further reliably provide a substrate with high precision through efficient processing.

[Aspect 1-4] According to Aspect 1-4, in Aspect 1-3, the measurement device performs first measurement of the shape of the processing surface before the first grinding or while the first grinding is being performed. According to Aspect 1-4, since parts targeted in the first grinding are appropriately set, it is possible to perform further efficient processing.

[Aspect 1-5] According to Aspect 1-5, in Aspect 1-4, in the first measurement, at least one of thickness distribution of the substrate and thickness distribution of a film formed on the processing surface is obtained based on analysis of measurement data obtained by receiving light from the substrate, the light from the substrate being based on light that the measurement device emits to the processing surface. According to Aspect 1-5, it is possible to efficiently obtain information of the shape of the processing surface in a non-contact manner and efficiently perform grinding processing based on the information.

[Aspect 1-6] According to Aspect 1-6, in Aspect 1-4 or 1-5, the control device sets the part of the processing surface on which the first grinding is to be performed based on the first measurement. According to Aspect 1-6, it is possible to appropriately set a target to be locally ground and more efficiently provide a substrate with higher precision.

[Aspect 1-7] According to Aspect 1-7, in Aspects 1-4 to 1-6, the control device determines whether to perform the first grinding based on first shape data and first target data, the first shape data indicating the shape of the processing surface obtained by the first measurement, the first target data indicating a shape targeted in the first grinding. According to Aspect 1-7, it is possible to more accurately determine whether to perform the first grinding.

[Aspect 1-8] According to Aspect 1-8, in Aspects 1-4 to 1-7, the control device sets whether to perform the first grinding or the second grinding based on the first measurement. According to Aspect 1-8, since grinding can be performed by, among the first grinding and the second grinding, a method that is efficient in accordance with the shape of the processing surface, it is possible to provide a more efficiently polished substrate.

[Aspect 1-9] According to Aspect 1-9, in Aspects 1-3 to 1-8, the measurement device performs second measurement of the shape of the processing surface in the second grinding, and the control device determines whether to end the second grinding based on the second measurement. According to Aspect 1-9, it is possible to perform the second grinding while checking whether polishing conditions are established, and it is possible to more efficiently provide a substrate with higher precision.

[Aspect 1-10] According to Aspect 1-10, in Aspect 1-9, the control device determines whether to end the second grinding based on the second shape data and the second target data, the second shape data indicating the shape of the processing surface obtained by the second measurement, the second target data indicating a shape targeted in the second grinding. According to Aspect 1-10, it is possible to more accurately determine whether to perform the second grinding.

[Aspect 1-11] According to Aspect 1-11, in Aspects 1-1 to 1-10, the processing surface is entirely ground in the second grinding. According to Aspect 1-11, since the entire surface grinding is performed after the partial grinding, it is possible to efficiently perform grinding on the entire processing surface and establish polishing conditions that polishing can be performed at high accuracy.

[Aspect 1-12] According to Aspect 1-12, in Aspects 1-1 to 1-11, the maximum diameter of the second grinding member is smaller than a maximum diameter of the processing surface. According to Aspect 1-12, it is possible to compactly configure the grinding module.

[Aspect 1-13] According to Aspect 1-13, in Aspects 1-1 to 1-12, the first grinding member and the second grinding member are grinding members of the same kind. According to Aspect 1-13, it is possible to compactly configure the grinding module and efficiently perform processing by omitting conveyance work.

[Aspect 1-14] According to Aspect 1-14, in Aspect 1-13, the first grinding member and the second grinding member are polishing tapes. According to Aspect 1-14, it is possible to accurately perform the partial grinding and more compactly configure the grinding module.

[Aspect 1-15] According to Aspect 1-15, in Aspects 1-1 to 1-14, the polishing member is a polishing pad, and the polishing is CMP polishing. According to Aspect 1-15, it is possible to perform high-precision polishing.

[Aspect 1-16] According to Aspect 1-16, in Aspects 1-1 to 1-15, the grinding module includes a substrate supporter configured to support the substrate in the first grinding and the second grinding such that the substrate is disposed with the processing surface facing upward in the vertical direction. According to Aspect 1-16, it is possible to easily perform the partial grinding and compactly configure the grinding module.

[Aspect 1-17] According to Aspect 1-17, in Aspects 1-1 to 1-16, the substrate polishing apparatus further includes an inverter, and the control device controls the inverter to invert the substrate before the polishing after the first grinding or the second grinding ends. According to Aspect 1-17, it is possible to efficiently invert the substrate.

[Aspect 1-18] According to Aspect 1-18, in Aspects 1-1 to 1-17, the substrate is a rectangular substrate. A rectangular substrate may have large warping or thickness variance, requiring a large amount of grinding or polishing. Furthermore, demand for flatness in a rectangular substrate is increasing. Thus, there is an increasing need to provide a rectangular substrate with high precision through efficient processing, and such a rectangular substrate is preferably applied to the present invention.

[Aspect 1-19] According to Aspect 1-19, a substrate polishing method of performing polishing processing on a processing surface of a substrate is disclosed, and the substrate polishing method includes: performing first grinding on part of the processing surface by a first grinding member; performing second grinding on the processing surface by a second grinding member with a maximum diameter larger than a maximum diameter of the first grinding member; and performing polishing by a polishing member on the processing surface on which the first grinding and the second grinding are performed. According to Aspect 1-19, it is possible to provide a substrate with high precision through efficient processing.

A third embodiment of the present invention will be described below with reference to the accompanying drawings. Identical or equivalent constituent components in the diagrams described below are denoted by the same reference sign and duplicate description thereof is omitted.

### Third Embodiment

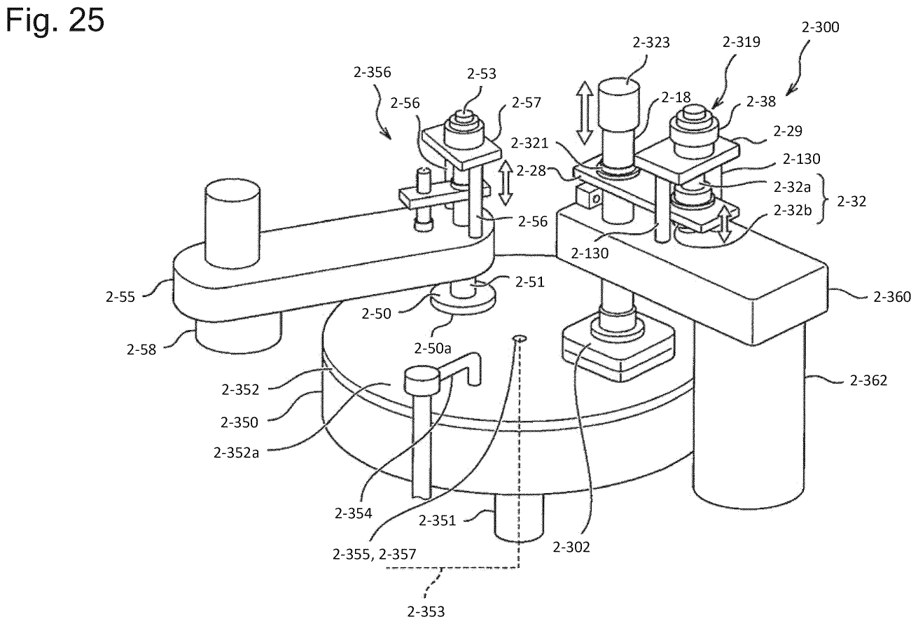

FIG. 25 is a perspective view schematically illustrating the configuration of a polishing apparatus 2-300 according to an embodiment. As illustrated in FIG. 25, the polishing apparatus 2-300 includes a polishing table 2-350, and a top ring 2-302 constituting a polishing head that holds a substrate as a polishing target object and presses the substrate against a polishing surface on the polishing table 2-350. The polishing table 2-350 is coupled to a polishing table rotation motor (not illustrated) disposed below through a table shaft 2-351 and is rotatable about the table shaft 2-351. A polishing pad 2-352 is bonded to the upper surface of the polishing table 2-350, and a surface 2-352a of the polishing pad 2-352 serves a polishing surface that polishes the substrate. In an embodiment, the polishing pad 2-352 may be bonded through a layer for facilitating peeling from the polishing table 2-350. Such a layer is, for example, a silicone layer or a fluororesin layer and may be, for example, a layer disclosed in Japanese Patent Laid-Open No. 2014-176950. Another polishing means may be used in place of the polishing pad. For example, fixed abrasive particles that are polishing particles fixed with a resin binding agent, a polishing tape, or any other well-known grinding means may be provided on the polishing table 2-350.

A polishing liquid supply nozzle 2-354 is installed above the polishing table 2-350, and polishing liquid is supplied onto the polishing pad 2-352 on the polishing table 2-350 by the polishing liquid supply nozzle 2-354. As illustrated in FIG. 25, a path 2-353 for supplying the polishing liquid is provided through the polishing table 2-350 and the table shaft 2-351. The path 2-353 communicates with an opening part 2-355 through the surface of the polishing table 2-350. The polishing pad 2-352 is formed with a through-hole 2-357 at a position corresponding to the opening part 2-355 of the polishing table 2-350, and the polishing liquid passing through the path 2-353 is supplied to the surface of the polishing pad 2-352 through the opening part 2-355 of the polishing table 2-350 and the through-hole 2-357 of the polishing pad 2-352. Note that the number of opening parts 2-355 of the polishing table 2-350 and the number of through-holes 2-357 of the polishing pad 2-352 may be one or plural. Moreover, the opening part 2-355 of the polishing table 2-350 and the through-hole 2-357 of the polishing pad 2-352 may be disposed at optional positions but are disposed near the center of the polishing table 2-350 in an embodiment.

Although not illustrated in FIG. 25, in an embodiment, the polishing apparatus 2-300 may include an atomizer for spraying liquid or mixed fluid of liquid and gas toward the polishing pad 2-352. The liquid sprayed from the atomizer may be, for example, pure water, and the gas may be, for example, nitrogen gas.

The top ring 2-302 is connected to a top ring shaft 2-18, and the top ring shaft 2-18 moves upward and downward relative to a swing arm 2-360 by an up-down movement mechanism 2-319. With the upward and downward movement of the top ring shaft 2-18, the entire top ring 2-302 is move upward and downward and positioned relative to the swing arm 2-360. The top ring shaft 2-18 is rotated by drive of a non-illustrated top ring rotation motor. With the rotation of the top ring shaft 2-18, the top ring 2-302 rotates about the top ring shaft 2-18. Note that a rotary joint 2-323 is attached at the upper end of the top ring shaft 2-18.

Note that there are various kinds of polishing pads available on the market, such as SUBA800 (“SUBA” is a registered trademark), IC-1000, and IC-1000/SUBA400 (dual-layer cross) manufactured by Nitta Haas Co., and Surfin xxx-5 and Surfin 000 (“surfin” is a registered trademark) manufactured by Fujimi Incorporated. SUBA800, Surfin xxx-5, and Surfin 000 are non-woven fabrics where fibers are consolidated with urethane resin, and IC-1000 is a rigid foamed polyurethane (single layer). The foamed polyurethane is porous and has a large number of minute depressions or holes on its surface.

The top ring 2-302 can hold a rectangular substrate on its lower surface. The swing arm 2-360 is configured to be rotatable about a support shaft 2-362. With the rotation of the swing arm 2-360, the top ring 2-302 is movable between the substrate transfer position of a non-illustrated conveyer and a position above the polishing table 2-350. By moving down the top ring shaft 2-18, the top ring 2-302 can be moved down to press the substrate against the surface (polishing surface) 2-352a of the polishing pad 2-352. Then, the top ring 2-302 and the polishing table 2-350 are each rotated and the polishing liquid is supplied onto the polishing pad 2-352 from the polishing liquid supply nozzle 2-354 provided above the polishing table 2-350 and/or from the opening part 2-355 provided on the polishing table 2-350. In this manner, the surface of the substrate can be polished with the substrate pressed against the polishing surface 2-352a of the polishing pad 2-352. During the polishing of the substrate, the arm 2-360 may be fixed so that the top ring 2-302 covers the through-hole 2-357 of the polishing pad 2-352 or the arm 2-360 may be swung so that the top ring 2-302 passes through the center of the polishing pad 2-352.

The up-down movement mechanism 2-319, which moves upward and downward the top ring shaft 2-18 and the top ring 2-302, includes a bridge 2-28 that rotatably supports the top ring shaft 2-18 through a bearing 2-321, a ball screw 2-32 attached to the bridge 2-28, a supporting table 2-29 supported by supports 2-130, and an AC servomotor 2-38 provided on the supporting table 2-29. The supporting table 2-29 supporting the servomotor 2-38 is fixed to the swing arm 2-360 through the supports 2-130.

The ball screw 2-32 includes a screw shaft 2-32a coupled to the servomotor 2-38, and a nut 2-32b into which the screw shaft 2-32a is screwed. The top ring shaft 2-18 moves upward and downward integrally with the bridge 2-28. Thus, when the servomotor 2-38 is driven, the bridge 2-28 moves upward and downward through the ball screw 2-32, and accordingly, the top ring shaft 2-18 and the top ring 2-302 move upward and downward.

The polishing apparatus 2-300 according to an embodiment includes a dressing device 2-356 that dresses the polishing surface 2-352a of the polishing pad 2-352. The dressing device 2-356 includes a dresser 2-50 that is in sliding contact with the polishing surface 2-352a, a dresser shaft 2-51 to which the dresser 2-50 is coupled, an air cylinder 2-53 provided at the upper end of the dresser shaft 2-51, and a swing arm 2-55 that rotatably supports the dresser shaft 2-51. A lower part of the dresser 2-50 is constituted by a dressing member 2-50a, and needle-shaped diamond particles are attached to the lower surface of the dressing member 2-50a. The air cylinder 2-53 is disposed on a supporting table 2-57 supported by supports 2-56, and the supports 2-56 are fixed to the swing arm 2-55.

The swing arm 2-55 is configured to rotate about a support shaft 2-58 when driven by a non-illustrated motor. The dresser shaft 2-51 is rotated by drive of a non-illustrated motor, and the dresser 2-50 rotates about the dresser shaft 2-51 with the rotation of the dresser shaft 2-51. The air cylinder 2-53 moves upward and downward the dresser 2-50 through the dresser shaft 2-51 and presses the dresser 2-50 against the polishing surface 2-352a of the polishing pad 2-352 with predetermined pressing force.

Dressing of the polishing surface 2-352a of the polishing pad 2-352 is performed as follows. The dresser 2-50 is pressed against the polishing surface 2-352a by the air cylinder 2-53, and simultaneously, pure water is supplied to the polishing surface 2-352a from a non-illustrated pure water supply nozzle. In this state, the dresser 2-50 rotates about the dresser shaft 2-51 to bring the lower surface (diamond particles) of the dressing member 2-50a into sliding contact with the rotating polishing surface 2-352a and swing the swing arm 2-55 on the polishing surface 2-352a. In this manner, the polishing pad 2-352 is shaved off by the dresser 2-50, and the polishing surface 2-352a is dressed.

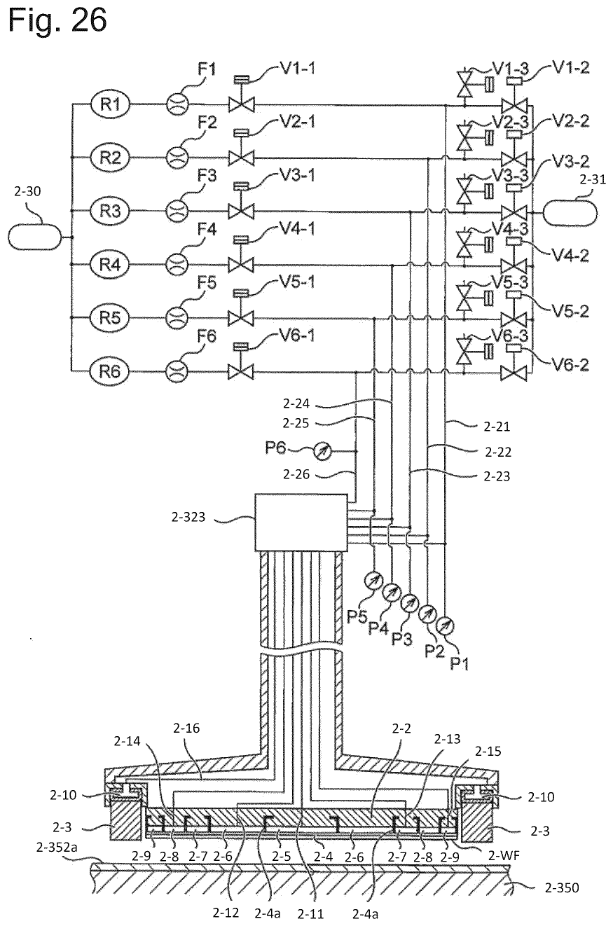

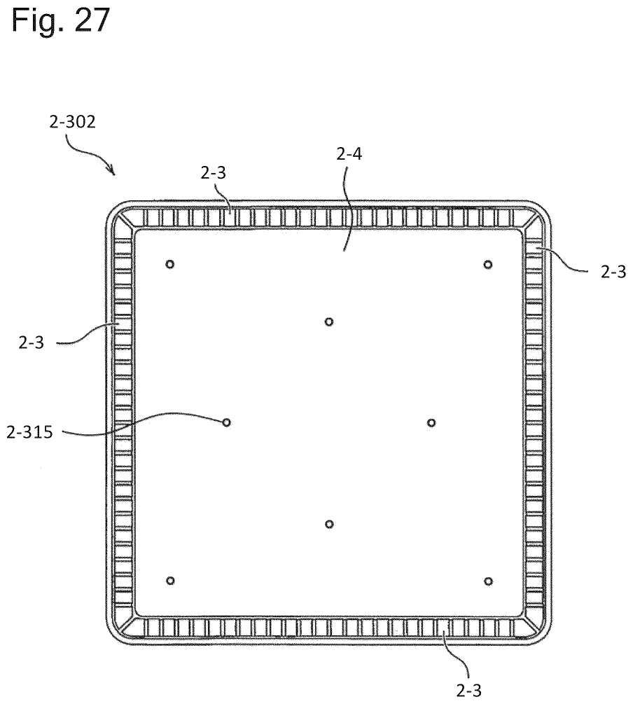

The top ring 2-302 in the polishing apparatus 2-300 according to an embodiment will be described below. FIG. 26 is a schematic cross-sectional view of the top ring 2-302 according to an embodiment, which holds a substrate as a polishing target object and presses the substrate against the polishing surface on the polishing pad. In FIG. 26, only main constituent components constituting the top ring 2-302 are schematically illustrated. FIG. 27 is a diagram of the top ring 2-302 according to an embodiment when viewed from the polishing table 2-350 side.

As illustrated in FIG. 26, the top ring 2-302 includes a top ring body 2-2 that presses a substrate 2-WF against the polishing surface 2-352a, and retainer members 2-3 that directly press the polishing surface 2-352a. The top ring body 2-2 is made of a substantially rectangular flat plate member, and the retainer members 2-3 are attached to an outer peripheral part of the top ring body 2-2. In an embodiment, each retainer member 2-3 is an elongated rectangular plate member as illustrated in FIG. 27. In the embodiment illustrated in FIG. 27, the retainer members 2-3 are four plate members provided outside the respective sides of the rectangular top ring body 2-2. Each retainer member 2-3 illustrated in FIG. 27 has an elongated shape with fan-shaped end parts. Thus, by combining the four retainer members 2-3 as illustrated in FIG. 27, it is possible to substantially entirely surround the top ring body 2-2, including its corners, with the retainer members 2-3. The top ring body 2-2 is formed of resin such as engineering plastic (for example, PEEK). An elastic film (membrane) 2-4 that contacts the back surface of the substrate is attached to the lower surface of the top ring body 2-2. In an embodiment, the elastic film (membrane) 2-4 is formed of a rubber material with excellent strength and durability, such as ethylene propylene rubber (EPDM), polyurethane rubber, and silicon rubber. In an embodiment, the elastic film (membrane) 2-4 may be formed of a rubber material by using a mold.

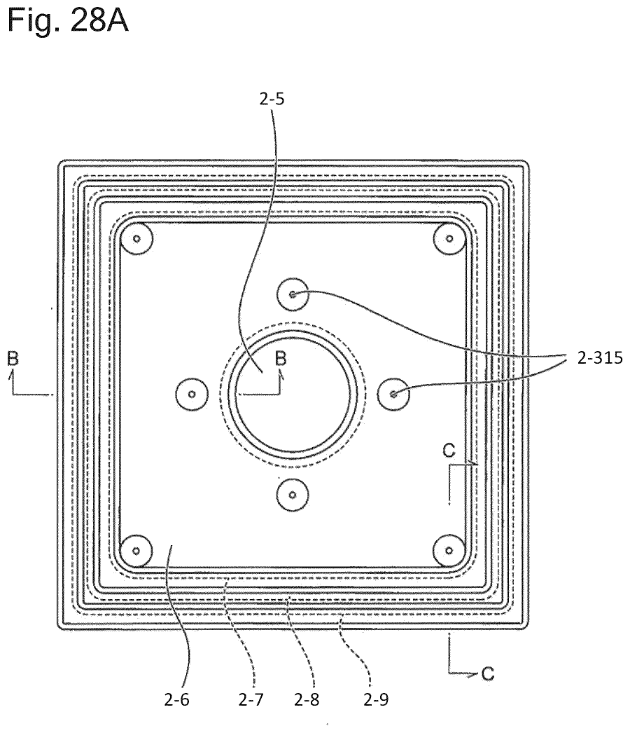

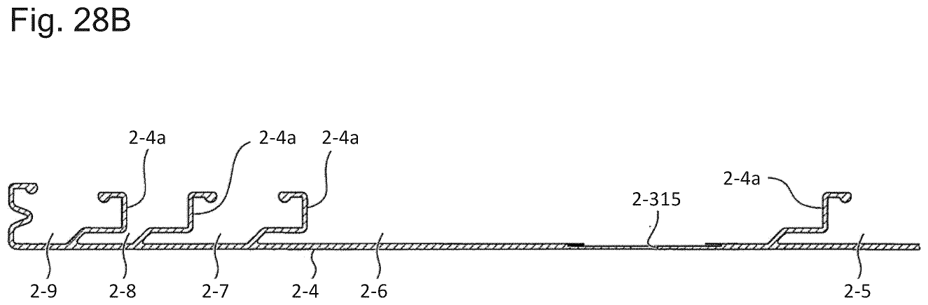

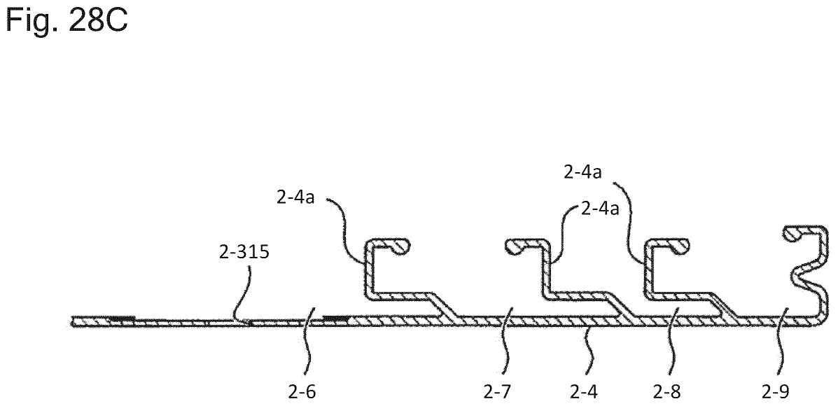

As illustrated in FIG. 26, the elastic film (membrane) 2-4 includes a plurality of concentric partitions 2-4a, and the partitions 2-4a form a circular center chamber 2-5 between the upper surface of the elastic film 2-4 and the lower surface of the top ring body 2-2, a rectangular annular ripple chamber 2-6 enclosing the center chamber 2-5, a rectangular annular middle chamber 2-7 enclosing the ripple chamber 2-6, a rectangular annular outer chamber 2-8 enclosing the middle chamber 2-7, and a rectangular annular edge chamber 2-9 enclosing the outer chamber 2-8. In other words, the center chamber 2-5 is formed at a central part of the top ring body 2-2, and the ripple chamber 2-6, the middle chamber 2-7, the outer chamber 2-8, and the edge chamber 2-9 are formed concentrically and sequentially from the center toward the outer periphery. FIG. 28A is a top view illustrating the structure of the elastic film (membrane) 2-4 according to an embodiment. FIG. 28B is a cross-sectional view taken along arrow B-B illustrated in FIG. 28A. FIG. 28C is a cross-sectional view taken along arrow C-C illustrated in FIG. 28A. As illustrated in FIG. 26, a flow path 2-11 communicating with the center chamber 2-5, a flow path 2-12 communicating with the ripple chamber 2-6, a flow path 2-13 communicating with the middle chamber 2-7, a flow path 2-14 communicating with the outer chamber 2-8, and a flow path 2-15 communicating with the edge chamber 2-9 are formed in the top ring body 2-2. The flow path 2-11 communicating with the center chamber 2-5, the flow path 2-12 communicating with the ripple chamber 2-6, the flow path 2-13 communicating with the middle chamber 2-7, the flow path 2-14 communicating with the outer chamber 2-8, and the flow path 2-15 communicating with the edge chamber 2-9 are connected to flow paths 2-21, 2-22, 2-23, 2-24, and 2-25, respectively, through the rotary joint 2-323. The flow paths 2-21, 2-22, 2-23, 2-24, and 2-25 are connected to a pressure adjuster 2-30 through valves V1-1, V2-1, V3-1, V4-1, and V5-1 and pressure regulators R1, R2, R3, R4, and R5, respectively. The flow paths 2-21, 2-22, 2-23, 2-24, and 2-25 are also connected to a vacuum source 2-31 through valves V1-2, V2-2, V3-2, V4-2, and V5-2, respectively, and can communicate with atmosphere through valves V1-3, V2-3, V3-3, V4-3, and V5-3.

As illustrated in FIGS. 27 and 28A to 28C, the elastic film 2-4 is formed with a plurality of vacuum adsorption holes 2-315 communicating with the ripple chamber 2-6 for vacuum-adsorbing the substrate 2-WF to the top ring 2-302. As an embodiment, eight vacuum adsorption holes 2-315 are provided as illustrated in FIGS. 27 and 28A. The vacuum adsorption holes 2-315 communicate with a non-illustrated path and are coupled to a vacuum source. The substrate 2-WF can be vacuum-adsorbed to the elastic film 2-4 on the top ring 2-302 through the vacuum adsorption holes 2-315.

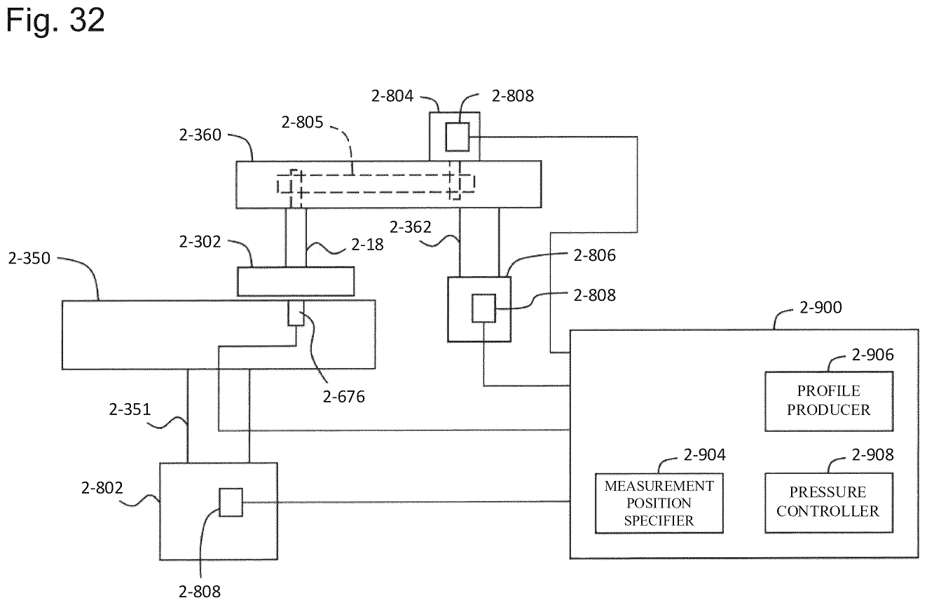

As illustrated in FIG. 26, a retainer member pressurization chamber 2-10 made of an elastic film is formed on the retainer members 2-3 and connected to a flow path 2-26 through a flow path 2-16 formed in the top ring body 2-2 and the rotary joint 2-323. The flow path 2-26 is connected to the pressure adjuster 2-30 through a valve V6-1 and a pressure regulator R6. The flow path 2-26 is also connected to the vacuum source 2-31 through a valve V6-2 and can communicate with atmosphere through a valve V6-3. The pressure regulators R1, R2, R3, R4, R5, and R6 have pressure adjustment functions to adjust the pressure of pressurized fluid supplied from the pressure adjuster 2-30 to the center chamber 2-5, the ripple chamber 2-6, the middle chamber 2-7, the outer chamber 2-8, the edge chamber 2-9, and the retainer member pressurization chamber 2-10, respectively. The pressure regulators R1, R2, R3, R4, R5, and R6 and the valves VI-1 to V1-3, V2-1 to V2-3, V3-1 to V3-3, V4-1 to V4-3, V5-1 to V5-3, and V6-1 to V6-3 are connected to a control device 2-900 (refer to FIGS. 32, 33, and 34) so that their actuation is controlled. In addition, pressure sensors P1, P2, P3, P4, P5, and P6 and flow rate sensors F1, F2, F3, F4, F5, and F6 are installed on the flow paths 2-21, 2-22, 2-23, 2-24, 2-25, and 2-26, respectively.

In the top ring 2-302 configured as illustrated in FIG. 26, as described above, the center chamber 2-5 is formed at the central part of the top ring body 2-2, the ripple chamber 2-6, the middle chamber 2-7, the outer chamber 2-8, and the edge chamber 2-9 are concentrically formed sequentially from the center toward the outer periphery, and the pressure of fluid supplied to the center chamber 2-5, the ripple chamber 2-6, the middle chamber 2-7, the outer chamber 2-8, the edge chamber 2-9, and the retainer member pressurization chamber 2-10 can be independently adjusted by the pressure adjuster 2-30 and the pressure regulators R1, R2, R3, R4, R5, and R6, respectively. With such a structure, pressing force that presses the substrate 2-WF against the polishing pad 2-352 can be adjusted in each region of the substrate 2-WF, and pressing force with which the retainer members 2-3 presses the polishing pad 2-352 can be adjusted.

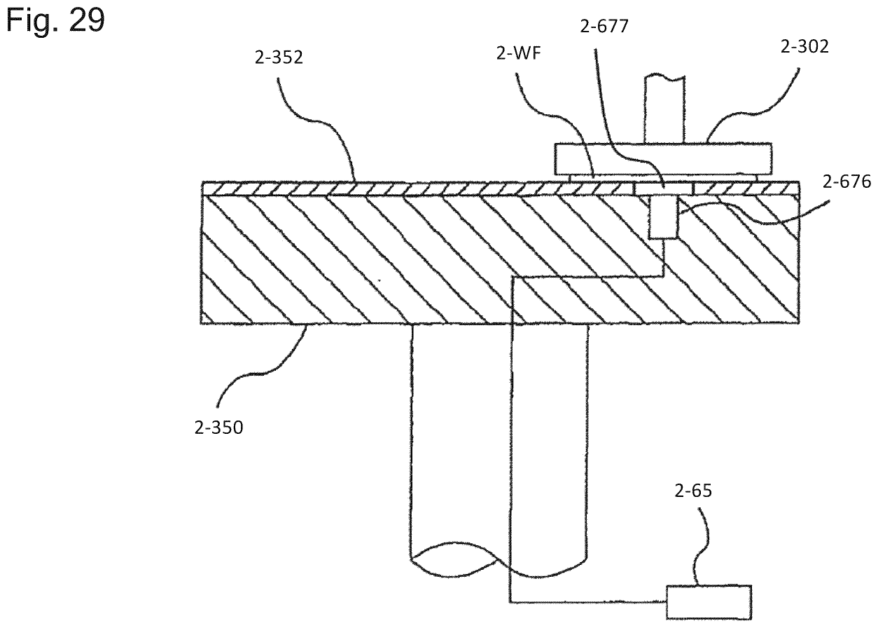

FIG. 29 is a cross-sectional view schematically illustrating the internal structure of the polishing table 2-350. As illustrated in FIG. 29, a sensor 2-676 that senses the state of the substrate 2-WF as a polishing target object is buried inside the polishing table 2-350. The sensor 2-676 may be, for example, an optical sensor. The optical sensor 2-676 emits light to the substrate 2-WF and senses the state (such as film thickness) of a film on the substrate 2-WF based on the intensity (reflection intensity or reflectance) of reflected light from the substrate 2-WF.

A light transmission part 2-677 for transmitting light from the optical sensor 2-676 is attached to the polishing pad 2-352. The light transmission part 2-677 is formed of a high transmittance material and formed of, for example, non-foamed polyurethane. Alternatively, the light transmission part 2-677 may be configured by providing a through-hole to the polishing pad 2-352 and flowing transparent liquid from below while the through-hole is blocked by the substrate 2-WF with rotation of the polishing table 2-350. The light transmission part 2-677 is disposed at a position passing through the center of the substrate 2-WF held by the top ring 2-302.

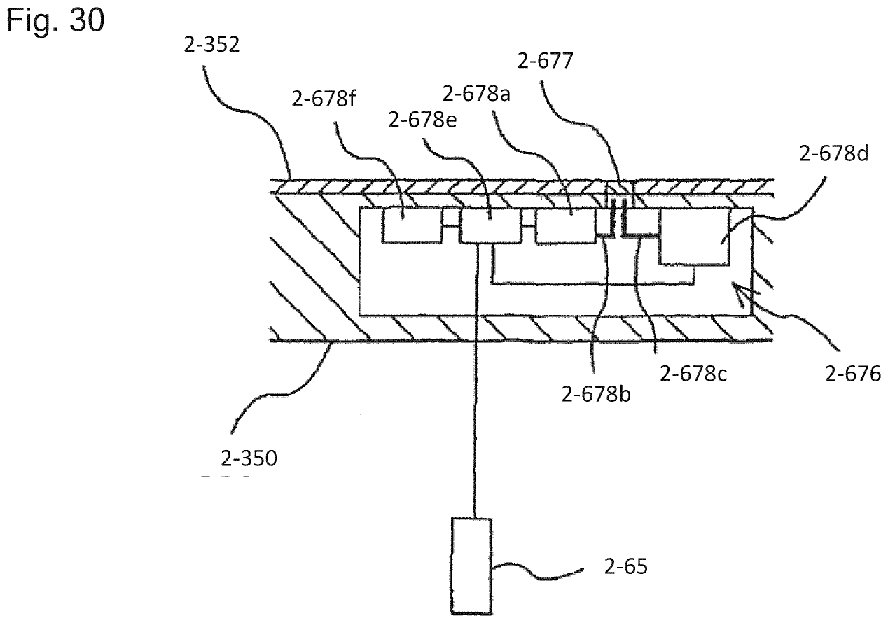

FIG. 30 is a schematic diagram illustrating a detailed configuration of the optical sensor 2-676 according to an embodiment. As illustrated in FIG. 30, the optical sensor 2-676 includes a light source 2-678a, an emitting optical fiber 2-678b as a light emitter that irradiates the polishing surface of the substrate 2-WF with light from the light source 2-678a, a receiving optical fiber 2-678c as a light receiver that receives reflected light from the polishing surface, a spectrometer 2-678d including inside an optical spectrometer that disperses light received by the receiving optical fiber 2-678c and a plurality of light reception elements that accumulate light dispersed by the optical spectrometer as electric information, an operation controller 2-678e that controls turning on-off of the light source 2-678a, start timing of reading by the light reception elements in the spectrometer 2-678d, and the like, and a power source 2-678f that supplies electric power to the operation controller 2-678e. Note that the light source 2-678a and the spectrometer 2-678d are supplied with electric power through the operation controller 2-678e.

A light emission end of the emitting optical fiber 2-678b and a light reception end of the receiving optical fiber 2-678c are configured to be substantially perpendicular to the polishing surface of the substrate 2-WF. For example, a 128-element photodiode array may be used as the light reception elements in the spectrometer 2-678d. The spectrometer 2-678d is connected to the operation controller 2-678e. Information from the light reception elements in the spectrometer 2-678d is transferred to the operation controller 2-678e, and spectrum data of reflected light is generated based on the information. In other words, the operation controller 2-678e reads electric information accumulated in the light reception elements and generates spectrum data of reflected light. The spectrum data indicates the intensity of reflected light decomposed in accordance with wavelength and changes with the film thickness of the substrate 2-WF.

The operation controller 2-678e is connected to a controller 2-65. Thus, the spectrum data generated by the operation controller 2-678e is transmitted to the controller 2-65. The controller 2-65 is configured to calculate the film thickness of the substrate 2-WF based on the spectrum data received from the operation controller 2-678e.

The polishing table 2-350 may include a sensor of another scheme in place of the above-described optical sensor as the sensor 2-676 that senses the state of the substrate 2-WF. For example, the sensor 2-676 may be a sensor of an optional type, such as an eddy current sensor, an acoustic sensor, or an ultrasonic wave sensor, which is capable of sensing the state of the substrate 2-WF. The eddy current sensor is configured to induce eddy current in a conductive film on the surface of the substrate 2-WF and detect the thickness of the conductive film on the surface of the substrate 2-WF from impedance change attributable to a magnetic field generated by the eddy current. The acoustic sensor and the ultrasonic wave sensor are configured to be able to sense polishing sound generated from the substrate 2-WF. The polishing table 2-350 may include a plurality of sensors 2-676 of the same scheme or different schemes, for example, both an optical sensor and an eddy current sensor. The plurality of sensors 2-676 may be disposed in proximity in the polishing table 2-350 or at equal angles around the rotation center of the polishing table 2-350 (for example, four sensors at 90° intervals).

The sensors 2-676 thus installed in the polishing table 2-350 sense the state of the substrate 2-WF (polishing target object) being held by the top ring 2-302 and polished. The state of the substrate 2-WF includes, for example, the film thickness of the substrate 2-WF and polishing sound of the substrate 2-WF. A polishing end point of the substrate 2-WF being polished can be detected based on the film thickness and polishing sound of the substrate 2-WF. In addition, polishing anomaly (for example, cracking of the substrate 2-WF) can be detected based on abnormal noise from the substrate 2-WF. Moreover, an in-substrate surface profile related to the state (for example, film thickness) of the substrate 2-WF can be obtained based on measurement values of the sensors 2-676 at each point on the substrate 2-WF.

During polishing of the substrate 2-WF, the relative positional relation between each sensor 2-676 in the polishing table 2-350 and the substrate 2-WF held by the top ring 2-302 changes from time to time as the polishing table 2-350 and the top ring 2-302 rotate. More specifically, along with rotation of the polishing table 2-350 and the top ring 2-302, each sensor 2-676 moves on a trajectory in the surface of the substrate 2-WF (or the top ring 2-302) when viewed in the substrate 2-WF (or the top ring 2-302).

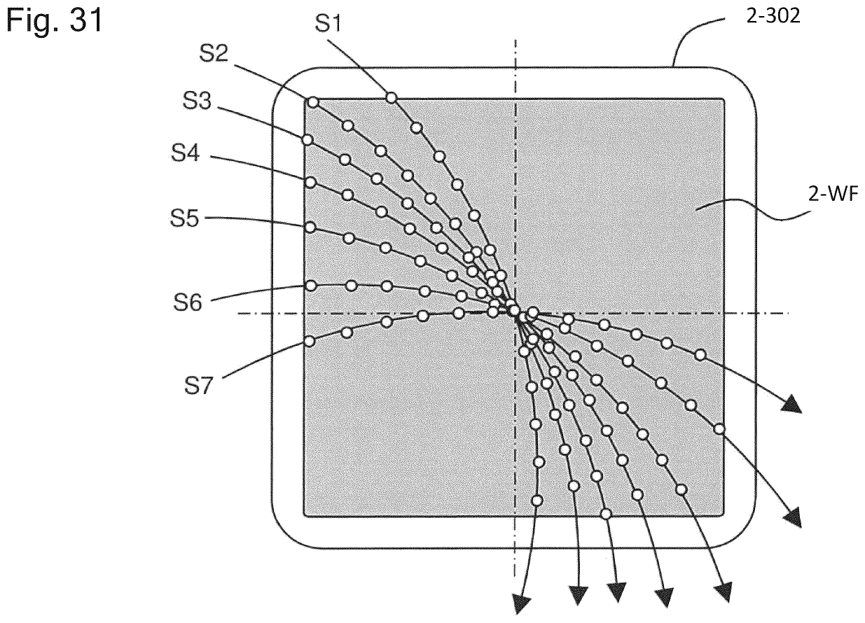

FIG. 31 illustrates an example of the trajectory of a sensor 2-676 passing on the substrate 2-WF held by the top ring 2-302. As illustrated in FIG. 31, the sensor 2-676 passes on a trajectory S1 at some point. The trajectory S1 traces a curve (for example, an arc illustrated in FIG. 31) in accordance with the attachment position of the sensor 2-676 (in other words, rotation radius of the sensor 2-676) in the polishing table 2-350, the size of the substrate 2-WF, the rotation speeds of the polishing table 2-350 and the top ring 2-302, and the like. While passing on the trajectory S1, the sensor 2-676 measures the state (for example, film thickness) of the substrate 2-WF in a predetermined period. Measurement positions of the sensor 2-676 are illustrated with a plurality of small circles on the trajectory S1. When the polishing table 2-350 rotates once after the sensor 2-676 completes passing on the trajectory S1, the sensor 2-676 passes on a trajectory S2 shifted from the trajectory S1 by an angle this time. Thereafter, the sensor 2-676 sequentially passes on trajectories S3, S4, . . . each time the polishing table 2-350 rotates once. Note that, in FIG. 31, trajectories up to a trajectory S7 are illustrated but subsequent trajectories are omitted. In this manner, the sensor 2-676 moves along a trajectory on the substrate 2-WF, and thus it is important to correctly know measurement positions (for example, positions of the plurality of small circles illustrated in FIG. 31) of the sensor 2-676.

FIG. 32 is a schematic configuration diagram of the polishing apparatus 2-300 according to an embodiment that can specify the measurement positions of the sensor. The polishing apparatus 2-300 includes the control device 2-900. The control device 2-900 may be configured by a typical computer including an input-output device, an arithmetic device, and a storage device. For example, the control device 2-900 is configured to implement functions of a measurement position specifier 2-904, a profile producer 2-906, and a pressure controller 2-908 as the arithmetic device (for example, processor) reads and executes a computer program stored in the storage device.

In FIG. 32, a table rotation motor 2-802 rotates the polishing table 2-350 about the table shaft 2-351. A head rotation motor 2-804 integrally rotates the top ring shaft 2-18 and the top ring 2-302 about the top ring shaft 2-18 through pulleys and a belt 2-805. A swing motor 2-806 swings (in other words, periodically and repetitively rotates) the swing arm 2-360 and the top ring 2-302 coupled to the swing arm 2-360 about the support shaft 2-362.

Encoders 2-808 that sense rotation of motors are attached to the respective motors 2-802, 2-804, and 2-806. Along with rotation of the respective motors 2-802, 2-804, and 2-806, the encoders 2-808 output signals in accordance with the rotation speeds of the motors. For example, the encoders 2-808 may be configured to output pulse signals each time the motors 2-802, 2-804, and 2-806 rotate by predetermined angles (for example, a predetermined number of times during one rotation). The measurement position specifier 2-904 can detect the rotation angle of the polishing table 2-350, the rotation angle of the top ring 2-302, and the swing angle of the top ring 2-302 based on signals from the encoders 2-808 (for example, by counting the numbers of pulse signals received per unit time). Note that the rotation angle of the polishing table 2-350 is an angle by which the polishing table 2-350 rotates about the table shaft 2-351, the rotation angle of the top ring 2-302 is an angle by which the top ring 2-302 rotates about the top ring shaft 2-18, and the swing angle of the top ring 2-302 is an angle by which the top ring 2-302 rotates about the support shaft 2-362. When the rotation angle of the polishing table 2-350, the rotation angle of the top ring 2-302, and the swing angle of the top ring 2-302 are determined, the relative positions of the polishing table 2-350 and the substrate 2-WF held by the top ring 2-302 are uniquely determined, and accordingly, the measurement positions of the sensor 2-676 provided in the polishing table 2-350 are specified. Note that, in a case where swing of the top ring 2-302 is not performed, the measurement positions of the sensor 2-676 can be specified based on the two rotation angles of the polishing table 2-350 and the top ring 2-302.

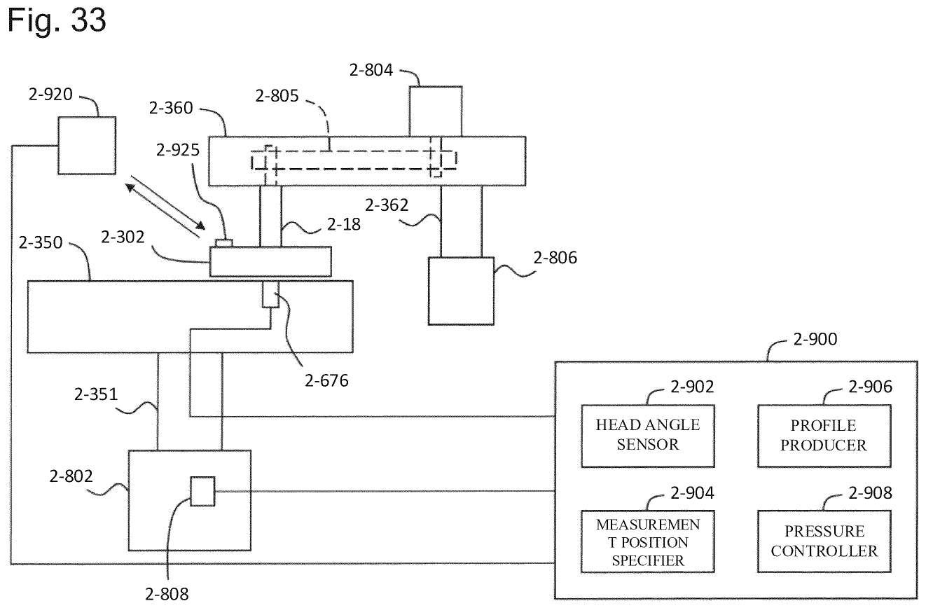

FIG. 33 is a schematic configuration diagram of the polishing apparatus 2-300 according to another embodiment that can specify the measurement positions of the sensor. The polishing apparatus 2-300 includes a laser measurement device 2-920 in addition to the control device 2-900 and the encoders 2-808. The encoders 2-808 corresponding to the head rotation motor 2-804 and the swing motor 2-806 may be omitted. The laser measurement device 2-920 may be installed inside the polishing apparatus 2-300 as illustrated in FIG. 33 or may be installed outside the polishing apparatus 2-300 as long as no obstacle that disturbs a laser beam exists between the laser measurement device 2-920 and the top ring 2-302.

The laser measurement device 2-920 radiates a laser beam toward the top ring 2-302. A marker 2-925 that reflects the laser beam from the laser measurement device 2-920 is installed on the top ring 2-302. The marker 2-925 may be, for example, a reflection mirror. The marker 2-925 rotates (and swings) together with the top ring 2-302. The laser measurement device 2-920 measures reflected light from the marker 2-925 and identifies the three-dimensional position of the marker 2-925 based on the distance and direction to the marker 2-925. A head angle sensor 2-902 of the control device 2-900 calculates the rotation angle (and swing angle) of the top ring 2-302 based on the three-dimensional position of the marker 2-925 obtained by the laser measurement device 2-920. The measurement position specifier 2-904 specifies the measurement positions of each sensor 2-676 based on the rotation angle (and swing angle) of the top ring 2-302 calculated in this manner and the rotation angle of the polishing table 2-350 specified by a signal from the encoder 2-808 corresponding to the table rotation motor 2-802. The measurement position specifier 2-904 may specify the measurement positions of the sensor 2-676 by directly using the three-dimensional position of the marker 2-925 acquired from the laser measurement device 2-920 (in place of the rotation angle (and swing angle) of the top ring 2-302 calculated by the head angle sensor 2-902 as described above).

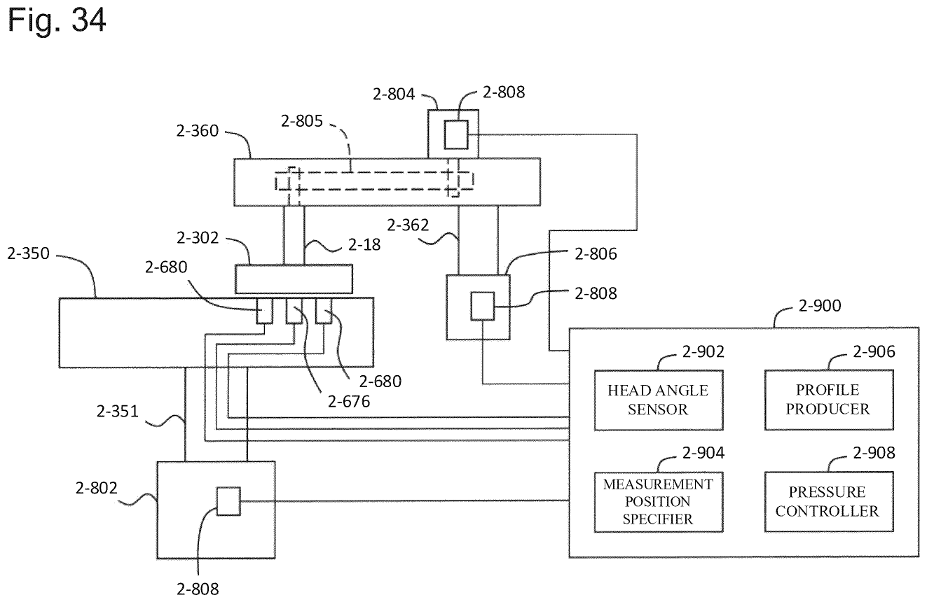

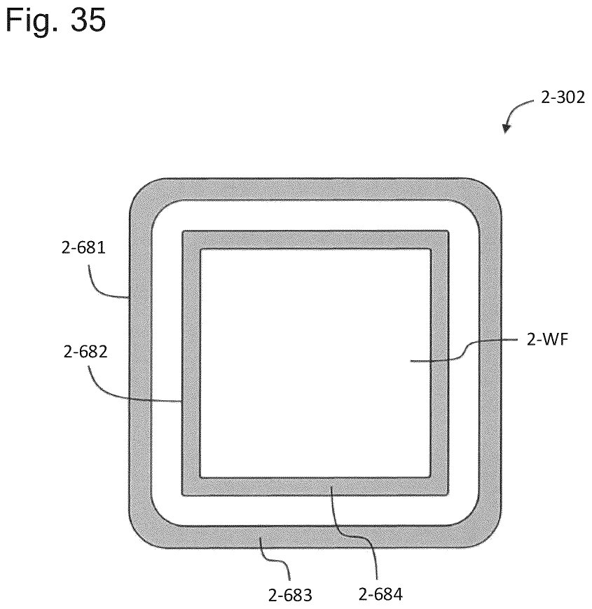

FIG. 34 is a schematic configuration diagram of the polishing apparatus 2-300 according to another embodiment that can specify the measurement positions of the sensor. In this embodiment, in addition to the sensors 2-676 that sense the state of the substrate 2-WF, at least two edge detection sensors 2-680 are buried inside the polishing table 2-350. The edge detection sensors 2-680 are configured to detect an edge 2-681 of the top ring 2-302 or an edge 2-682 of the substrate 2-WF held by the top ring 2-302. In an embodiment, the top ring 2-302 includes metal frames 2-683 and 2-684 disposed along its outer periphery or the outer periphery of the substrate 2-WF as illustrated in FIG. 35. The edge detection sensors 2-680 may be eddy current sensors. Near the metal frames 2-683 and 2-684, the eddy current sensors 2-680 induce eddy current in the metal frames 2-683 and 2-684 and output signals in accordance with impedance change attributable to a magnetic field generated by the eddy current. The edge 2-681 of the top ring 2-302 and the edge 2-682 of the substrate 2-WF held by the top ring 2-302 can be detected based on the signals.

As illustrated in FIG. 34, the control device 2-900 has functions of the head angle sensor 2-902, the measurement position specifier 2-904, the profile producer 2-906, and the pressure controller 2-908. As described above, these functions are implemented as the arithmetic device (for example, processor) reads and executes a computer program stored in the storage device. The head angle sensor 2-902 specifies the timing of detection of an edge (the edge 2-681 or 2-682) by each sensor 2-680 based on the signals from the at least two edge detection sensors 2-680. Then, the head angle sensor 2-902 calculates the rotation angle of the top ring 2-302 based on the time difference between the timing of edge detection by the first edge detection sensor 2-680 and the timing of edge detection by the second edge detection sensor 2-680.

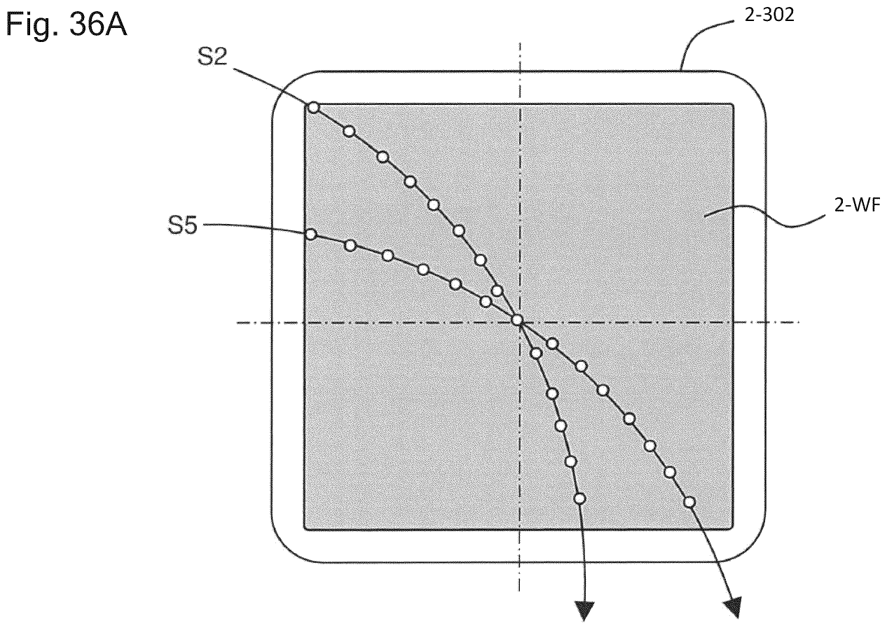

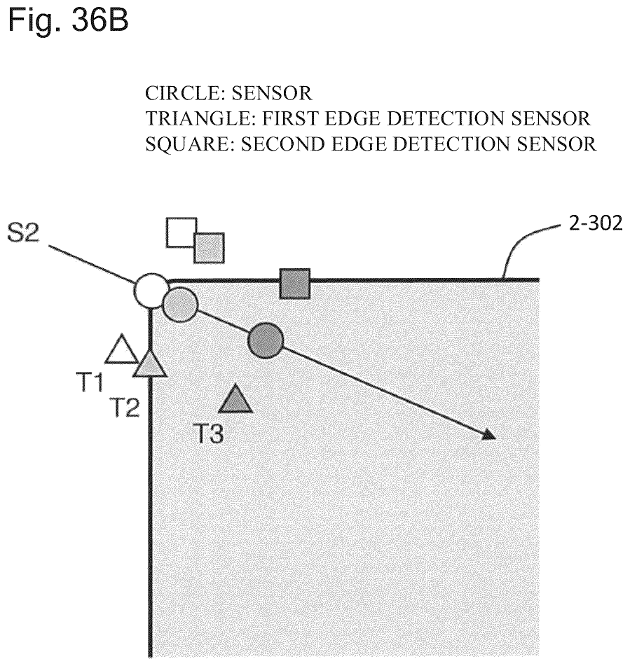

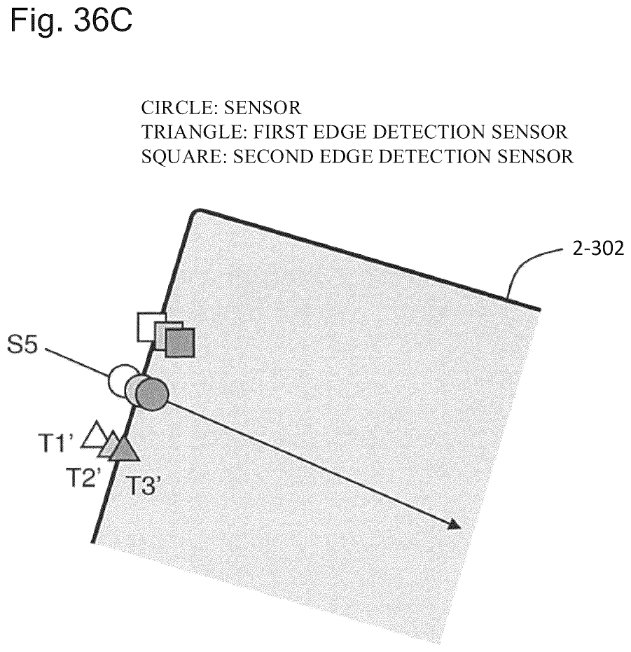

FIGS. 36A to 36C are conceptual diagrams for description of a method of calculating the rotation angle of the top ring 2-302 based on edge detection timings. FIGS. 36A to 36C illustrate a case in which a sensor 2-676 passes on the two trajectories S2 and S5. In these diagrams, a circle represents the position of the sensor 2-676, a triangle represents the position of the first edge detection sensor 2-680, and a square represents the position of the second edge detection sensor 2-680. Note that the first and second edge detection sensors 2-680 are preferably installed near the sensor 2-676 as illustrated.

As for the trajectory S2 in FIG. 36B, at a time point T1 (illustrated in white), the sensor 2-676 (circle) passes through an edge of the top ring 2-302. At this time, the first and second edge detection sensors 2-680 (white triangle and square) has not yet passed through the edge of the top ring 2-302. At a time point T2 (illustrated in light gray) after the time point T1, the first edge detection sensor 2-680 (triangle) passes through the edge of the top ring 2-302. At this timing, a signal is output from the first edge detection sensor 2-680 and the head angle sensor 2-902 identifies an edge detection timing T2 of the first edge detection sensor 2-680. Thereafter, at a time point T3 (illustrated in dark gray), the second edge detection sensor 2-680 (square) passes through the edge of the top ring 2-302 this time. Similarly, at this timing, a signal is output from the second edge detection sensor 2-680 and the head angle sensor 2-902 identifies an edge detection timing T3 of the second edge detection sensor 2-680. The head angle sensor 2-902 calculates a time difference ΔT(S2)=T3-T2 between the two identified edge detection timings.

Next, referring to the trajectory S5 in FIG. 36C, the angle between the trajectory S5 and the top ring 2-302 is different from the angle between the trajectory S2 and the top ring 2-302 in FIG. 36B. Thus, in the case of the trajectory S5, first at a time point T1′ (illustrated in white), the second edge detection sensor 2-680 (square) passes through an edge of the top ring 2-302. Thereafter, the sensor 2-676 (circle) and the first edge detection sensor 2-680 (triangle) pass through the edge of the top ring 2-302 at a time point T2′ (illustrated in light gray) and a time point T3′ (illustrated in dark gray), respectively. The head angle sensor 2-902 identifies the edge detection timings T1′ and T3′ based on signals from the two edge detection sensors 2-680 and calculates a time difference ΔT(S5)=T3′−T1′ between the identified edge detection timings.

In this manner, the head angle sensor 2-902 calculates a time difference ΔT between edge detection timings for each of the trajectories S1, S2, S3, . . . . As understood from the above description related to FIGS. 36B and 36C, the time differences ΔT(S1), Δ(S2), ΔT(S3), . . . between edge detection timings have mutually different values in accordance with the angle between the trajectory of the sensor 2-676 and the top ring 2-302. Accordingly, the time difference ΔT between edge detection timings indicates the relative angle between the top ring 2-302 and the polishing table 2-350 when the sensor 2-676 crosses the edge of the top ring 2-302. Thus, the head angle sensor 2-902 can specify, based on the time difference ΔT between edge detection timings, the rotation angle of the top ring 2-302 relative to the polishing table 2-350 at a timing at which the sensor 2-676 crosses the edge of the top ring 2-302. For example, the correlation relation (for example, correspondence table) between the time difference ΔT between edge detection timings and the rotation angle of the top ring 2-302 relative to the polishing table 2-350 may be stored in a memory of the control device 2-900 in advance. By referring to the correspondence table, the head angle sensor 2-902 can acquire the rotation angle of the top ring 2-302 relative to the polishing table 2-350 based on the calculated time difference ΔT between edge detection timings.

Note that although the above description is made on an example in which the edge 2-681 of the top ring 2-302 is detected, it should be understood that, in a case where the edge 2-682 of the substrate 2-WF held by the top ring 2-302 is detected, as well, the rotation angle of the top ring 2-302 relative to the polishing table 2-350 can be specified by applying the same method.

After the sensor 2-676 passes through an edge of the top ring 2-302 (or the substrate 2-WF), the head angle sensor 2-902 specifies the rotation angle of the top ring 2-302 by using the rotation speed of the top ring 2-302. For example, the head angle sensor 2-902 can calculate the rotation angle of the top ring 2-302 at an optional time point by adding the product of the rotation number of the top ring 2-302 and an elapsed time after the edge passing to the rotation angle of the top ring 2-302 (in other words, initial rotation angle at the edge passing) determined based on the time difference ΔT between edge detection timings as described above. The rotation number of the top ring 2-302 may be a rotation number instruction value (setting value) instructed to the head rotation motor 2-804 or may be a rotation number measured value acquired through the encoders 2-808. The measurement position specifier 2-904 specifies the measurement positions of the sensor 2-676 based on the rotation angle of the top ring 2-302 calculated in this manner and the rotation angle of the polishing table 2-350 specified by a signal from the encoder 2-808 corresponding to the table rotation motor 2-802. Note that the swing angle of the top ring 2-302 may be additionally used as in the embodiment in FIG. 32.

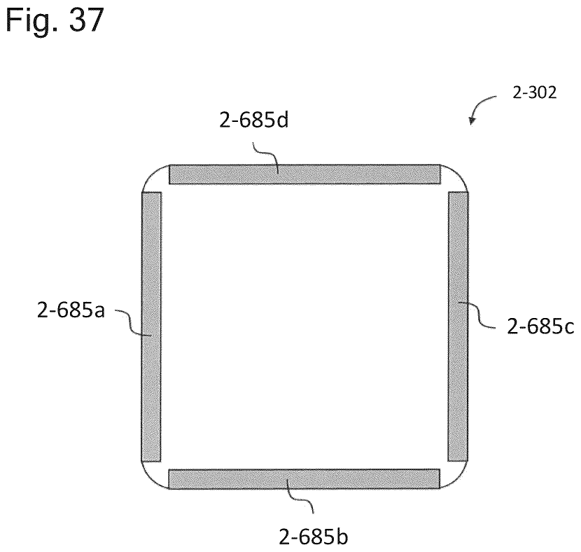

FIG. 37 is a diagram illustrating another embodiment of the top ring 2-302 including metal frames. In this embodiment, the top ring 2-302 includes a metal frame made of frame pieces 2-685a, 2-685b, 2-685c, and 2-685d provided on the respective sides of the rectangular outer shape. The frame pieces 2-685a, 2-685b, 2-685c, and 2-685d have different thicknesses, respectively, or are made of different kinds of metals, respectively. Due to the difference in thickness or metal kind, different signals (for example, signals with different signal levels) are output when the edge detection sensor (eddy current sensor) 2-680 crosses the frame pieces 2-685a, 2-685b, 2-685c, and 2-685d. Thus, by using this, it is possible to distinguish which of the four sides of the top ring 2-302 the edge detection sensor 2-680 crosses, thereby specifying the rotation angle of the top ring 2-302 without an uncertainty of an angle of 90°.

In the embodiments in FIGS. 32, 33, and 34, the profile producer 2-906 produces, based on the measurement positions of the sensor 2-676 specified by the measurement position specifier 2-904, a polishing profile (for example, film thickness profile) indicating in-substrate surface distribution of the measurement value (for example, film thickness) of the sensor 2-676. For example, the film thickness profile may be produced as a set of a plurality of pieces of data constituted by a plurality of measurement values of the film thickness of the substrate 2-WF and coordinate positions on the substrate 2-WF corresponding to the respective measurement values.

The polishing profile (for example, film thickness profile) of the substrate 2-WF changes depending on the shape and polishing conditions of the substrate 2-WF, unique features of the polishing apparatus 2-300, or the like. For example, the film thickness of a circular substrate such as a semiconductor wafer may have distribution only in the radial direction of the substrate and may be even in the circumferential direction (in other words, depends on only the distance from the center of the substrate but does not depend on the angle about the center of the substrate). For example, the film thickness of a rectangular substrate often depends not only on the distance from the center of the substrate but also on the angle about the center of the substrate. The film thickness of a circular substrate may have dependency on the angle about the center of the substrate, depending on polishing conditions and the like.

In a case where the film thickness of a substrate changes depending on the angle about the center of the substrate, the film thickness profiles along the trajectories S1, S2, S3, . . . illustrated in FIG. 31 are mutually different. Thus, to obtain an accurate film thickness profile within the entire surface of the substrate, it is essential to correctly understand a trajectory that the sensor 2-676 passes through on the substrate when performing measurement. According to the polishing apparatus 2-300 of the present disclosure, it is possible to sense the rotation angle of the top ring 2-302. Thus, it is possible to correctly specify the measurement positions of the sensor 2-676 within the substrate surface (identify through which trajectory the sensor 2-676 has passed), and the profile producer 2-906 can produce an accurate polishing profile (for example, film thickness profile) within the entire surface of the substrate based on the measurement value of the sensor 2-676.

The pressure controller 2-908 is configured to control, in each region of the substrate 2-WF based on the polishing profile obtained from the profile producer 2-906, pressing force that presses the substrate 2-WF against the polishing pad 2-352, and control pressing force with which the retainer members 2-3 press the polishing pad 2-352. More specifically, the pressure controller 2-908 independently controls the pressures of the center chamber 2-5, the ripple chamber 2-6, the middle chamber 2-7, the outer chamber 2-8, the edge chamber 2-9, and the retainer member pressurization chamber 2-10 (refer to FIG. 26) of the top ring 2-302. For example, in a case where the film thickness of a region facing the center chamber 2-5 within the surface of the substrate 2-WF is thicker than that of the other region, the pressure controller 2-908 controls the pressure of the center chamber 2-5 to be higher than that of the other chambers. Accordingly, the region of the substrate 2-WF facing the center chamber 2-5 is pressed against the polishing pad 2-352 with higher pressing force and the amount of polishing in the region increases.

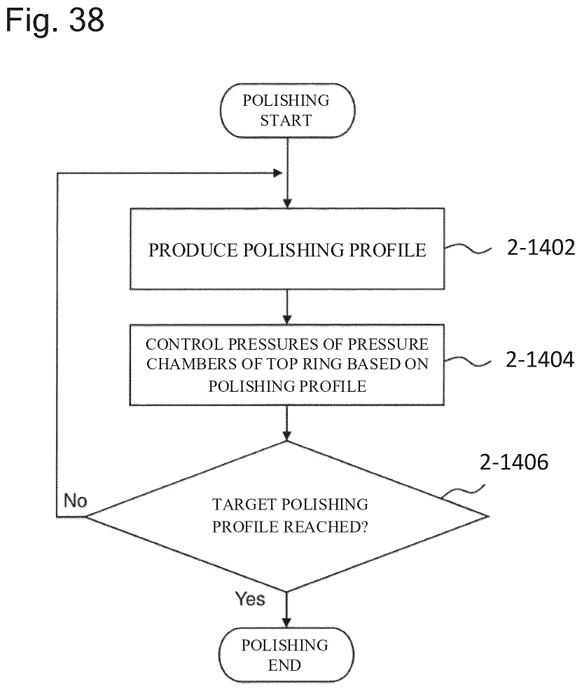

FIG. 38 illustrates an exemplary process of control of the polishing apparatus 2-300 by the control device 2-900. At step 2-1402 after the polishing apparatus 2-300 starts polishing, the profile producer 2-906 produces a polishing profile (for example, film thickness profile) based on measurement values from the sensor 2-676 and the measurement positions of the sensor 2-676 specified by the measurement position specifier 2-904. As described above, since the measurement positions of the sensor 2-676 in the substrate surface are correctly specified through sensing of the rotation angle of the top ring 2-302, an accurate polishing profile within the entire surface of the substrate can be produced.

At step 2-1404, the pressure controller 2-908 compares the produced polishing profile with a target polishing profile and controls the pressures of the center chamber 2-5, the ripple chamber 2-6, the middle chamber 2-7, the outer chamber 2-8, the edge chamber 2-9, and the retainer member pressurization chamber 2-10 of the top ring 2-302 based on the result of the comparison. The target polishing profile may be stored in the memory of the control device 2-900 in advance as a desirable polishing profile that the substrate should have after polishing is completed. For example, the pressure controller 2-908 calculates the difference between the polishing profile acquired from the profile producer 2-906 and the target polishing profile in each of regions of the substrate 2-WF corresponding to the center chamber 2-5, the ripple chamber 2-6, the middle chamber 2-7, the outer chamber 2-8, the edge chamber 2-9, and the retainer member pressurization chamber 2-10, respectively. Then, the pressure controller 2-908 controls the pressures of the center chamber 2-5, the ripple chamber 2-6, the middle chamber 2-7, the outer chamber 2-8, the edge chamber 2-9, and the retainer member pressurization chamber 2-10 so that the chambers have pressures in accordance with the difference between the polishing profile and the target polishing profile in the respective regions of the substrate 2-WF.

At step 2-1406, the control device 2-900 determines whether the current polishing profile bas reached the target polishing profile. In a case where the current polishing profile has reached the target polishing profile, the control device 2-900 ends polishing. In a case where the current polishing profile has not yet reached the target polishing profile, the control device 2-900 repeats steps 2-1402 to 2-1406 again.

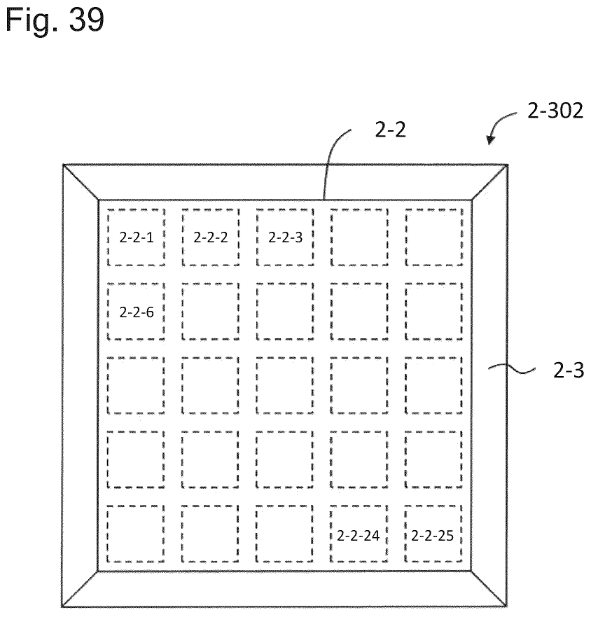

Note that, in the above-described embodiment in FIG. 26, the top ring body 2-2 includes the five concentric pressure chambers of the center chamber 2-5, the ripple chamber 2-6, the middle chamber 2-7, the outer chamber 2-8, and the edge chamber 2-9, but the number, shapes, dispositions of pressure chambers are not limited to those of the five pressure chambers. FIG. 39 is a plan view illustrating the configuration of the top ring 2-302 according to another embodiment when viewed from the polishing table 2-350 side. In the embodiment in FIG. 39, the top ring body 2-2 includes 25 pressure chambers 2-2-1, 2-2-2, . . . , 2-2-25 arranged in a lattice shape of five rows and five columns. The pressure controller 2-908 may be configured to individually control the pressures of the pressure chambers 2-2-1, 2-2-2, . . . , 2-2-25 in accordance with the difference between the polishing profile and the target polishing profile in each region of the substrate 2-WF.

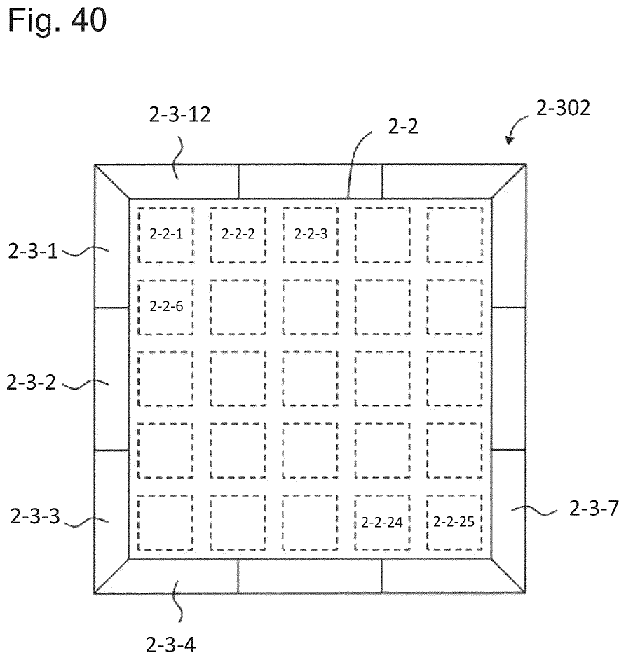

In the above-described embodiment in FIG. 26, the top ring 2-302 includes four retainer members 2-3 provided outside the respective sides (one on each side) of the rectangular top ring body 2-2. The pressure controller 2-908 may be configured to individually control the pressure of the retainer member pressurization chamber 2-10 corresponding to each retainer member 2-3 in accordance with the difference between the polishing profile and the target polishing profile in each region of the substrate 2-WF. Moreover, the retainer member 2-3 on each side may be divided into a plurality of partitions. FIG. 40 is a plan view illustrating the configuration of the top ring 2-302 in such a form when viewed from the polishing table 2-350 side. In the embodiment in FIG. 40, a retainer member on each side is divided into three partitions, and the top ring 2-302 includes a total of 12 retainer members 2-3-1, 2-3-2, . . . , 2-3-12, and 12 independent retainer member pressurization chambers 2-10 corresponding to the respective retainer members 2-3. The pressure controller 2-908 may be configured to individually control the pressures of the 12 retainer member pressurization chambers 2-10 in accordance with the difference between the polishing profile and the target polishing profile in each region of the substrate 2-WF.

The pressures of the retainer member pressurization chambers 2-10 may be controlled to the same constant pressure instead of being individually controlled. Moreover, the pressures of the retainer member pressurization chambers 2-10 are preferably controlled to a pressure higher than a predetermined lower limit pressure to prevent the substrate 2-WF from jumping off the top ring 2-302 during polishing.

Note that the pressure chambers of the center chamber 2-5, the ripple chamber 2-6, the middle chamber 2-7, the outer chamber 2-8, the edge chamber 2-9, and the retainer member pressurization chamber 2-10 of the top ring 2-302 may be replaced with a plurality of piezoelectric elements configured to press the substrate 2-WF and the retainer members 2-3 against the polishing pad 2-352 in respective regions.

The present embodiment described above can be written in forms below.

[Aspect 2-1] According to Aspect 2-1, a polishing apparatus is provided that includes: a polishing table having a polishing surface; a polishing head for holding a polishing target object such that the polishing target object faces the polishing surface; a table rotation motor for rotating the polishing table; a head rotation motor for rotating the polishing head; a table angle sensor configured to sense a rotation angle of the polishing table; a head angle sensor configured to sense a rotation angle of the polishing head; a sensor provided on the polishing table and configured to measure a state of the polishing target object when the sensor passes by the polishing target object due to rotation of the polishing table and the polishing head; and a measurement position specifier configured to specify a measurement position of the sensor on the polishing target object based on the rotation angle of the polishing table and the rotation angle of the polishing head.

[Aspect 2-2] According to Aspect 2-2, in the polishing apparatus in Aspect 2-1, the table angle sensor is an encoder provided on the table rotation motor, and the head angle sensor is an encoder provided on the head rotation motor.

[Aspect 2-3] According to Aspect 2-3, the polishing apparatus in Aspect 2-1 further includes: a marker installed on the polishing head; and a measurer configured to measure a three-dimensional position of the marker, and the head angle sensor is configured to sense the rotation angle of the polishing head based on the three-dimensional position of the marker measured by the measurer.

[Aspect 2-4] According to Aspect 2-4, the polishing apparatus in Aspect 2-1 further includes at least two edge detection sensors provided on the polishing table and each configured to detect an edge of the polishing head or an edge of the polishing target object, and the head angle sensor is configured to sense the rotation angle of the polishing head based on a time difference between a timing of detection of the edge by a first edge detection sensor among the at least two edge detection sensors and a timing of detection of the edge by a second edge detection sensor among the at least two edge detection sensors.

[Aspect 2-5] According to Aspect 2-5, in the polishing apparatus in Aspect 2-4, the head angle sensor is configured to sense, based on the time difference, the rotation angle of the polishing head relative to the polishing table at a timing at which the sensor passes by an edge of the polishing head or the polishing target object along with rotation of the polishing table and the polishing head.

[Aspect 2-6] According to Aspect 2-6, in the polishing apparatus in Aspect 2-4 or 2-5, the polishing head includes a metal frame disposed along an outer periphery of the polishing head or the polishing target object, and the at least two edge detection sensors are each configured to output a signal indicating proximity to the metal frame.

[Aspect 2-7] According to Aspect 2-7, in the polishing apparatus in Aspect 2-6, the metal frame has different thicknesses or is made of different kinds of metals on different parts of the outer periphery of the polishing head or the polishing target object.

[Aspect 2-8] According to Aspect 2-8, in the polishing apparatus in Aspect 2-7, the metal frame is rectangular, with sides having different thicknesses or made of different kinds of metals.

[Aspect 2-9] According to Aspect 2-9, in the polishing apparatus in any one of Aspects 2-6 to 2-8, the at least two edge detection sensors are eddy current sensors.

[Aspect 2-10] According to Aspect 2-10, the polishing apparatus in any one of Aspects 2-1 to 2-9 further includes a swing motor for swinging the polishing head, and the measurement position specifier is configured to specify the measurement position of the sensor on the polishing target object based on the rotation angle of the polishing table, the rotation angle of the polishing head, and a swing angle of the polishing head.

[Aspect 2-11] According to Aspect 2-11, the polishing apparatus in any one of Aspects 2-1 to 2-10 further includes a profile producer configured to produce a polishing profile based on the state of the polishing target object measured by the sensor and the measurement position of the sensor on the polishing target object specified by the measurement position specifier, the polishing profile indicating positional distribution related to the state of the polishing target object.

[Aspect 2-12] According to Aspect 2-12, in the polishing apparatus in Aspect 2-11, the state of the polishing target object is a film thickness of the polishing target object.

[Aspect 2-13] According to Aspect 2-13, in the polishing apparatus in Aspect 2-11 or 2-12, the polishing head includes a pressing mechanism configured to press the polishing target object against the polishing surface in each of a plurality of regions, and the polishing apparatus further includes a pressure controller configured to compare the polishing profile produced by the profile producer with a target polishing profile and control pressing force of the pressing mechanism in each of the plurality of regions based on a result of the comparison.

[Aspect 2-14] According to Aspect 2-14, in the polishing apparatus in Aspect 2-13, the pressing mechanism includes a plurality of fluid pressurization chambers or piezoelectric elements that press respective regions of the polishing target object.

[Aspect 2-15] According to Aspect 2-15, in the polishing apparatus in Aspect 2-13 or 2-14, the polishing head includes a retainer disposed to surround an outer periphery of the polishing target object, the retainer being configured to press the polishing surface in each of a plurality of partitions divided along the outer periphery, and the pressure controller is further configured to control pressing force of the retainer for each of the plurality of partitions based on the result of the comparison.

[Aspect 2-16] According to Aspect 2-16, in the polishing apparatus in Aspect 2-15, the retainer includes a plurality of fluid pressurization chambers or piezoelectric elements corresponding to the plurality of respective partitions.

[Aspect 2-17] According to Aspect 2-17, a polishing method is provided that includes: a step of rotating a polishing table with a polishing surface; a step of rotating a polishing head for holding a polishing target object such that the polishing target object faces the polishing surface; a step of sensing a rotation angle of the polishing table; a step of sensing a rotation angle of the polishing head; a step of measuring, by using a sensor provided on the polishing table, a state of the polishing target object when the sensor passes by the polishing target object due to rotation of the polishing table and the polishing head; and a step of specifying a measurement position of the sensor on the polishing target object based on the rotation angle of the polishing table and the rotation angle of the polishing head.

Although the embodiments of the present invention have been described above based on some examples, the described embodiments are for the purpose of facilitating the understanding of the present invention and are not intended to limit the present invention. The present invention may be modified and improved without departing from the spirit thereof, and the invention includes equivalents thereof. In addition, the elements described in the claims and the specification can be arbitrarily combined or omitted within a range in which the above-mentioned problems are at least partially solved, or within a range in which at least a part of the advantages is achieved.

This application claims priority under the Paris Convention to Japanese Patent Application No. 2022-039240 filed on Mar. 14, 2022 and Japanese Patent Application No. 2022-052168 filed on Mar. 28, 2022. The entire disclosures of Japanese Patent Applications No. 2022-039240 and No. 2022-052168 including the specification, claims, drawings and summary are incorporated herein by reference in their entirety. The entire disclosures of Japanese Patent Laid Open No. 2017-163047 (PTL-1) and Japanese Patent Laid Open No. 2020-19115 (PTL-2), Japanese Patent No. 5340795 (PTL-3), and Japanese Patent Laid Open No. 2014-176950 including the specification, claims, drawings and summary is incorporated herein by reference in their entirety.

### REFERENCE SIGNS LIST

1-2, 1-2002 . . . top ring body
1-3, 1-1003, 1-2003 . . . retainer member
1-4, 1-2004 . . . elastic film
1-6, 1-2006 . . . gas introduction chamber
1-12, 1-1012, 1-2012 . . . flow path
1-71 . . . first arm
1-72 . . . second arm
1-73, 1-1073, 1-3073 . . . table
1-75 . . . third arm
1-100 . . . loader
1-200A . . . first conveyer
1-200B . . . second conveyer
1-202 . . . conveyance roller
1-204 . . . roller shaft
1-220 . . . stopper
1-230 . . . pusher
1-300, 1-300A . . . grinding module
1-302, 1-1302, 1-2302, 1-2302A, 1-2302B . . . top ring
1-352a . . . polishing surface
1-400 . . . polishing module
1-500 . . . drying module
1-600 . . . unloader
1-710 . . . first head
1-712 . . . first pressing pad
1-712S . . . first pad surface
1-720 . . . second head
1-722 . . . second pressing pad
1-722S . . . second pad surface
1-750, 1-751 . . . measurement device
1-751A . . . first detection head
1-751B . . . second detection head
1-800 . . . inverter
1-900, 1-901 . . . control device
1-950 . . . processor
1-951 . . . conveyance controller
1-952 . . . measurement controller
1-953 . . . first grinding controller
1-954 . . . second grinding controller
1-955 . . . polishing controller
1-959 . . . memory
1-1000, 1-1001 . . . substrate polishing apparatus
1-1005 . . . adsorption plate
1-2007 . . . rigid body plate
1-3000 . . . grinding-polishing module
1-Ax1, 1-Ax3, 1-Ax4, 1-Ax5 . . . rotational axis
1-G . . . grinding member
1-G1 . . . first grinding member
1-G2 . . . second grinding member
1-L1 . . . maximum diameter of first grinding member
1-L2 . . . maximum diameter of second grinding member
1-L3 . . . maximum diameter of processing surface
1-PM . . . polishing member
1-PS . . . processing surface
1-T1A, 1-T1B, 1-T2A, 1-T2B, 1-T3 . . . polishing tape
1-WF . . . substrate
1-WF1, 1-WF2 . . . convex part
2-300 polishing apparatus
2-302 top ring
2-350 polishing table
2-352 polishing pad
2-360 swing arm
2-676 sensor
2-680 edge detection sensor
2-683, 2-684 metal frame
2-802 table rotation motor
2-804 head rotation motor
2-806 swing motor
2-808 encoder
2-900 control device
2-902 head angle sensor
2-904 measurement position specifier
2-906 profile producer
2-908 pressure controller
2-920 laser measurement device
2-925 marker
2-WF substrate

1. A substrate polishing apparatus configured to perform polishing processing on a processing surface of a substrate, the substrate polishing apparatus comprising:
a grinding module comprising a first grinding member and a second grinding member with a maximum diameter larger than a maximum diameter of the first grinding member;
a polishing module including a polishing member; and
a control device configured to control the grinding module and the polishing module,
wherein the control device
controls the grinding module to perform first grinding on part of the processing surface by the first grinding member and second grinding on the processing surface by the second grinding member, and
controls the polishing module to perform polishing on the processing surface on which the first grinding and the second grinding have been performed.

2. The substrate polishing apparatus according to claim 1, wherein the control device performs the second grinding simultaneously with or after the first grinding.

3. The substrate polishing apparatus according to claim 1, further comprising a measurement device configured to perform measurement of the shape of the processing surface.

4. The substrate polishing apparatus according to claim 3, wherein the measurement device performs first measurement of the shape of the processing surface before the first grinding or while the first grinding is being performed.

5. The substrate polishing apparatus according to claim 4, wherein in the first measurement, at least one of thickness distribution of the substrate and thickness distribution of a film formed on the processing surface is obtained based on analysis of measurement data obtained by receiving light from the substrate, the light from the substrate being based on light that the measurement device emits to the processing surface.

6. The substrate polishing apparatus according to claim 4, wherein the control device sets the part of the processing surface on which the first grinding is to be performed based on the first measurement.

7. The substrate polishing apparatus according to claim 4, wherein the control device determines whether to perform the first grinding based on first shape data and first target data, the first shape data indicating the shape of the processing surface obtained by the first measurement, the first target data indicating a shape targeted in the first grinding.

8. The substrate polishing apparatus according to claim 4, wherein the control device sets whether to perform the first grinding or the second grinding based on the first measurement.

9. The substrate polishing apparatus according to claim 3, wherein
the measurement device performs second measurement of the shape of the processing surface in the second grinding, and
the control device determines whether to end the second grinding based on the second measurement.

10. The substrate polishing apparatus according to claim 9, wherein the control device determines whether to end the second grinding based on second shape data and second target data, the second shape data indicating the shape of the processing surface obtained by the second measurement, the second target data indicating a shape targeted in the second grinding.

11. The substrate polishing apparatus according to claim 1, wherein the processing surface is entirely ground in the second grinding.

12. The substrate polishing apparatus according to claim 1, wherein the maximum diameter of the second grinding member is smaller than a maximum diameter of the processing surface.

13. The substrate polishing apparatus according to claim 1, wherein the first grinding member and the second grinding member are grinding members of the same kind.

14. The substrate polishing apparatus according to claim 13, wherein the first grinding member and the second grinding member are polishing tapes.

15. The substrate polishing apparatus according to claim 1, wherein the polishing member is polishing pad and the polishing is CMP polishing.

16. The substrate polishing apparatus according to claim 1, wherein the grinding module comprises a substrate supporter configured to support the substrate in the first grinding and the second grinding such that the substrate is disposed with the processing surface facing upward in the vertical direction.

17. The substrate polishing apparatus according to claim 1, further comprising an inverter, wherein the control device controls the inverter to invert the substrate before the polishing after the first grinding or the second grinding ends.

18. The substrate polishing apparatus according to claim 1, wherein the substrate is a rectangular substrate.

19. A substrate polishing method of performing polishing processing on a processing surface of a substrate, the substrate polishing method comprising:
performing first grinding on part of the processing surface by a first grinding member;
performing second grinding on the processing surface by a second grinding member with a maximum diameter larger than a maximum diameter of the first grinding member; and
performing polishing by a polishing member on the processing surface on which the first grinding and the second grinding have been performed.

20-36 (canceled)
